(19) United States
(12) Patent Application Publication
(10) Pub. No.: US 2014/0212814 A1
(43) Pub. Date: Jul. 31, 2014

(54) ACTINIC-RAY- OR RADIATION-SENSITIVE RESIN COMPOSITION, ACTINIC-RAY- OR RADIATION-SENSITIVE FILM THEREFROM, METHOD OF FORMING PATTERN USING THE COMPOSITION, PROCESS FOR MANUFACTURING ELECTRONIC DEVICE AND ELECTRONIC DEVICE

(71) Applicant: FUJIFILM Corporation, Tokyo (JP)

(72) Inventors: Junichi ITO, Shizuoka (JP); Akinori SHIBUYA, Shizuoka (JP); Tomoki MATSUDA, Shizuoka (JP); Yoko TOKUGAWA, Shizuoka (JP); Toshiaki FUKUHARA, Shizuoka (JP); Naohiro TANGO, Shizuoka (JP); Kaoru IWATO, Shizuoka (JP); Masahiro YOSHIDOME, Shizuoka (JP); Shinichi SUGIYAMA, Shizuoka (JP); Shohei KATAOKA, Shizuoka (JP)

(73) Assignee: FUJIFILM CORPORATION, Tokyo (JP)

(21) Appl. No.: 14/229,190

(22) Filed: Mar. 28, 2014

Related U.S. Application Data
(63) Continuation of application No. PCT/JP2012/075880, filed on Sep. 28, 2012.

(30) Foreign Application Priority Data
Sep. 30, 2011 (JP) 2011-215882

(51) Int. Cl. G03F 7/027

(52) U.S. Cl. CPC G03F 7/027
USPC 430/286.1; 549/43; 430/325; 430/311; 549/16; 560/17; 560/10

(57) ABSTRACT

Provided is an actinic-ray- or radiation-sensitive resin composition, including any of compounds of general formula (1) below that when exposed to actinic rays or radiation, is decomposed to thereby generate an acid and a resin that when acted on by an acid, is decomposed to thereby increase its solubility in an alkali developer.

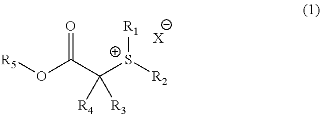

### CROSS-REFERENCE TO RELATED APPLICATIONS

This application is a Continuation Application of PCT Application No. PCT/JP2012/075880, filed Sep. 28, 2012 and based upon and claims the benefit of priority from prior Japanese Patent Application No. 2011-215882, filed Sep. 30, 2011, the entire contents of which are incorporated herein by reference.

### BACKGROUND OF THE INVENTION

1. Field of the Invention

The present invention relates to an actinic-ray- or radiation-sensitive resin composition that when exposed to actinic rays or radiation, makes a reaction to thereby change its properties, and relates to an actinic-ray- or radiation-sensitive film therefrom, a method of forming a pattern using the composition, a process for manufacturing an electronic device and an electronic device. More particularly, the present invention relates to an actinic-ray- or radiation-sensitive resin composition for use in not only a semiconductor production process for an IC or the like, a circuit board production for a liquid crystal, a thermal head or the like and other photofabrication processes but also a lithographic printing plate and an acid-hardenable composition, and further relates to an actinic-ray- or radiation-sensitive film therefrom, a method of forming a pattern using the composition, a process for manufacturing an electronic device and an electronic device.

2. Description of the Related Art

A resist composition of chemical amplification type is a pattern forming material that is capable of, upon exposure to far ultraviolet or other radiation, generating an acid in exposed areas and, by a reaction catalyzed by the acid, changing the solubility in a developer between the areas having been exposed to actinic radiation and the nonexposed areas to thereby attain pattern formation on a substrate.

When a KrF excimer laser is used as an exposure light source, a resin whose fundamental skeleton is formed of a poly(hydroxystyrene) exhibiting a low absorption mainly in the region of 248 nm is employed as a major component of a resist composition. Accordingly, there can be attained a high sensitivity, high resolution and favorable pattern formation. Thus, a system superior to the conventional naphthoquinone diazide/novolak resin system is realized.

In contrast, when use is made of a light source of a further shorter wavelength, for example, an exposure light source of an ArF excimer laser (193 nm), as the compounds containing aromatic groups inherently exhibit a sharp absorption in the region of 193 nm, the above-mentioned chemical amplification system has not been satisfactory. Consequently, resists for ArF excimer laser containing a resin with an alicyclic hydrocarbon structure have been developed.

However, discovering an appropriate combination of used resin, photoacid generator, basic compound, additive, solvent, etc. from the viewpoint of comprehensive performance as a resist is extremely difficult, and the current situation is that any combination is still unsatisfactory. For example, there is a demand for the development of a resist excelling in exposure latitude and pattern roughness characteristic, such as line width roughness (LWR), and exhibiting less change of performance over time.

In this current situation, various compounds have been developed as the photoacid generator being a main constituent of the chemically amplified resist composition. For example, patent references 1 to 3 describe sulfonium salt photoacid generators. Non-patent reference 1 describes the photochemical reaction of phenacylsulfonium salts.

The photoacid generator is excited by the absorption of light, and generates an acid by the decomposition thereof. Hence, generally, the higher the absorbancy index to exposure wavelength, the higher the acid generating efficiency. On the other hand, there is a problem that when the absorption to exposure wavelength is extremely high, light is absorbed in an upper layer portion of a film so that light cannot be satisfactorily transmitted to an inferior layer portion of the film to thereby lower the acid generating efficiency. Therefore, an ideal photoacid generator is one having the properties of exhibiting a low absorbancy index to exposure wavelength and efficiently leading any absorbed light to the acid generation. Discovering a structure ensuring this is very difficult.

Moreover, the high acid generating efficiency means that the photoacid generator is easily decomposed. Hence, the high acid generating efficiency is often in a trade-off relationship with storage stability. Therefore, it is also a very difficult task to simultaneously satisfy the high acid generating efficiency and the storage stability.

### PRIOR ART LITERATURE

### Patent Reference

[Patent reference 1] Jpn. Pat. Appln. KOKAI Publication No. (hereinafter referred to as JP-A-) 2002-351077,
[Patent reference 2] JP-A-2002-255930, and
[Patent reference 3] JP-A-2004-117688.

### Non-Patent Reference

[Non-patent reference 1] Journal of Organic Chemistry, 1970, vol. 35, p. 2532-2538.

### BRIEF SUMMARY OF THE INVENTION

In view of the above background art, it is an object of the present invention to provide an actinic-ray- or radiation-sensitive resin composition excelling in exposure latitude and pattern roughness characteristic, such as LWR, and exhibiting less change of performance over time. It is further objects of the present invention to provide an actinic-ray- or radiation-sensitive film therefrom, a method of forming a pattern using the composition, a process for manufacturing an electronic device and an electronic device.

The inventors have conducted extensive and intensive studies with a view toward attaining the above objects. As a result, the present invention has been completed.

The present invention has the following features.

[1] An actinic-ray- or radiation-sensitive resin composition comprising any of compounds of general formula (1) below that when exposed to actinic rays or radiation, is decomposed to thereby generate an acid and a resin that when acted on by an acid, is decomposed to thereby increase its solubility in an alkali developer,

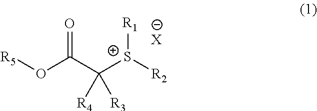

in which

each of R₁ and R₂ independently represents an aryl group, provided that R₁ and R₂ may be connected to each other;

each of R₃ and R₄ independently represents a hydrogen atom, an alkyl group, a cycloalkyl group, an alkenyl group or an aryl group, provided that R₃ and R₄ may be connected to each other;

R₅ represents an alkyl group, a cycloalkyl group, an alkenyl group, an aryl group, an aralkyl group or an alkylcarbonyl group, provided that R₅ may be connected to R₃ or R₄; and

X⁻ represents a nonnucleophilic anion.

[2] The actinic-ray- or radiation-sensitive resin composition according to item [1], wherein X⁻in general formula (1) is expressed by general formula (2) below,

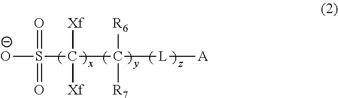

in which

each of Xf's independently represents a fluorine atom or an alkyl group substituted with at least one fluorine atom;

each of R₆ and R₇ independently represents a hydrogen atom, a fluorine atom, an alkyl group or an alkyl group substituted with at least one fluorine atom, provided that two or more R₆s, and R₇s may be identical to or different from each other;

L represents a bivalent connecting group, provided that two or more L's may be identical to or different from each other;

A represents an organic group containing a cyclic structure; and

x is an integer of 1 to 20, y an integer of 0 to 10, and z an integer of 0 to 10.

[3] The actinic-ray- or radiation-sensitive resin composition according to item [1] or [2], wherein at least either R₃ or R₄ in general formula (1) is an alkyl group or an aryl group.

[4] The actinic-ray- or radiation-sensitive resin composition according to any of items [1] to [3], wherein in general formula (1), an alkyl group, a cycloalkyl group, an alkoxy group, a hydroxyl group, a fluorine atom, a cyano group, an amino group, an alkylamino group, a dialkylamino group or an alkoxycarbonylamino group is introduced in at least one of the aryl groups represented by R₁ and R₂.

[5] The actinic-ray- or radiation-sensitive resin composition according to any of items [1] to [4], further comprising a low-molecular compound containing a nitrogen atom and a group cleaved by the action of an acid, or a basic compound.

[6] An actinic-ray- or radiation-sensitive film formed from the actinic-ray- or radiation-sensitive resin composition according to any of items [1] to [5].

[7] A method of forming a pattern, comprising:

exposing the actinic-ray- or radiation-sensitive film of item [6] to light, and

developing the exposed film.

[8] The method according to item [7], wherein the exposure is performed through an immersion liquid.

[9] A process for manufacturing an electronic device, comprising the method of item [7] or [8].

[10] An electronic device manufactured by the process of item [9].

[11] Compounds of general formula (1) below,

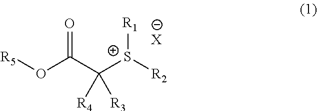

in which

each of R₁ and R₂ independently represents an aryl group, provided that R₁ and R₂ may be connected to each other;

each of R₃ and R₄ independently represents a hydrogen atom, an alkyl group, a cycloalkyl group, an alkenyl group or an aryl group, provided that R₃ and R₄ may be connected to each other;

R₅ represents an alkyl group, a cycloalkyl group, an alkenyl group, an aryl group, an aralkyl group or an alkylcarbonyl group, provided that R₅ may be connected to R₃ or R₄; and

X⁻ represents a nonnucleophilic anion.

The present invention has made it feasible to provide a resist pattern excelling in exposure latitude and pattern roughness characteristic, such as LWR, and exhibiting less change of performance over time. The actinic-ray- or radiation-sensitive resin composition of the present invention can be appropriately used in, for example, an ArF liquid-immersion exposure process.

The pattern forming method in which use is made of the composition of the present invention can be appropriately used as a lithography process in the manufacturing of various electronic devices, such as a semiconductor element and a recording medium.

### DETAILED DESCRIPTION OF THE INVENTION

With respect to the expression of group (atomic group) used in this specification, the expression even when there is no mention of “substituted and unsubstituted” encompasses groups not only having no substituent but also having substituents. For example, the expression “alkyl groups” encompasses not only alkyls having no substituent (unsubstituted alkyls) but also alkyls having substituents (substituted alkyls).

In this specification, the term “actinic rays” or “radiation” means, for example, brightline spectra from a mercury lamp, far ultraviolet represented by an excimer laser, extreme ultraviolet (EUV light), X-rays, electron beams (EB) and the like. Further, in the present invention, the term “light” means actinic rays or radiation.

The term “exposure to light” used in this specification, unless otherwise specified, means not only irradiation with light, such as light from a mercury lamp, far ultraviolet represented by an excimer laser, X-rays or EUV light, but also lithography using particle beams, such as electron beams and ion beams.

The actinic-ray- or radiation-sensitive resin composition of the present invention comprises any of compounds (hereinafter also referred to as “compounds (A)” or “photoacid generators (A)”) of general formula (1) below that when exposed to actinic rays or radiation, generates an acid and a resin that when acted on by an acid, is decomposed to thereby increase its solubility in an alkali developer.

A light-sensitive resist film excelling in exposure latitude and pattern roughness characteristic, such as LWR, and exhibiting less change of performance over time can be obtained by the incorporation of the compound (A) in the actinic-ray- or radiation-sensitive resin composition of the present invention. The reason therefor has not been elucidated. However, it is presumed that in the compound (A), after the excitation by light absorption, the C—S⁺ bond is cleaved at high efficiency, so that the amount of acid generated upon exposure is large to thereby realize the uniform distribution of an acid in the light-sensitive resist film, contributing to improvement of LWR. Moreover, it is presumed that two of three substituents on S⁺ in the compound (A) are aryl groups, so that the effect of decreasing any cleavage reaction by the withdrawal of an aliphatic proton and the effect of inhibiting any nucleophilic attack onto S⁺ due to steric bulkiness can be exerted. Thus, it is presumed that any change of performance by the decomposition of the photoacid generator upon aging of the resist can be suppressed.

The actinic-ray- or radiation-sensitive resin composition of the present invention is, for example, a positive composition, typically a positive resist composition.

The individual components of this composition will be described below.

[1] Compounds (A) of General Formula (1)

As mentioned above, the actinic-ray- or radiation-sensitive resin composition of the present invention comprises any of compounds (A) of general formula (1) below. The compound (A) is a compound that when exposed to actinic rays or radiation, generates an acid.

The compounds (A) will be described in detail below.

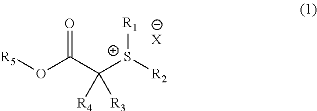

In general formula (1),

each of R₁ and R₂ independently represents an optionally substituted aryl group, provided that R₁ and R₂ may be connected to each other.

Each of R₃ and R₄ independently represents a hydrogen atom, an optionally substituted alkyl group, an optionally substituted cycloalkyl group, an optionally substituted alkenyl group or an optionally substituted aryl group, provided that R₃ and R₄ may be connected to each other.

R₅ represents an optionally substituted alkyl group, an optionally substituted cycloalkyl group, an optionally substituted alkenyl group, an optionally substituted aryl group, an optionally substituted aralkyl group or an optionally substituted alkylcarbonyl group, provided that R₅ may be connected to R₃ or R₄.

X⁻ represents a nonnucleophilic anion.

General formula (1) will be described in detail below.

Each of the aryl groups represented by R₁ and R₂ is preferably, for example, one having 6 to 20 carbon atoms. As such, there can be mentioned, for example, a phenyl group, a naphthyl group, an azulenyl group, an acenaphthylenyl group, a phenanthrenyl group, a penalenyl group, a phenanthracenyl group, a fluorenyl group, an anthracenyl group, a pyrenyl group, a benzopyrenyl group or the like.

Substituents may be introduced in the aryl groups represented by R₁ and R₂. The position at which a substituent can be introduced and the number of substituents are not particularly limited. As introducible substituents, there can be mentioned, for example, a halogen atom (e.g., fluorine, chlorine or iodine);

an alkyl group or cycloalkyl group (a linear, branched or cyclic alkyl group preferably having 1 to 48 carbon atoms, more preferably 1 to 24 carbon atoms, such as methyl, ethyl, propyl, isopropyl, butyl, t-butyl, pentyl, hexyl, heptyl, octyl, 2-ethylhexyl, dodecyl, hexadecyl, cyclopropyl, cyclopentyl, cyclohexyl, 1-norbornyl or 1-adamantyl);

an alkenyl group (alkenyl group preferably having 2 to 48 carbon atoms, more preferably 2 to 18 carbon atoms, for example, vinyl, allyl or 3-buten-1-yl);

an aryl group (aryl group preferably having 6 to 48 carbon atoms, more preferably 6 to 24 carbon atoms, for example, phenyl or naphthyl);

a heterocyclic group (heterocyclic group preferably having 1 to 32 carbon atoms, more preferably, 1 to 18 carbon atoms, for example, 2-thienyl, 4-pyridyl, 2-furyl, 2-pyrimidinyl, 1-pyridyl, 2-benzothiazolyl, 1-imidazolyl, 1-pyrazolyl or benzotriazol-1-yl);

a silyl group (silyl group preferably having 3 to 38 carbon atoms, more preferably 3 to 18 carbon atoms, for example, trimethylsilyl, triethylsilyl, tributylsilyl, t-butyldimethylsilyl or t-hexyldimethylsilyl);

a hydroxyl group; a cyano group; a nitro group;

an alkoxy group (alkoxy group preferably having 1 to 48 carbon atoms, more preferably 1 to 24 carbon atoms, for example, methoxy, ethoxy, 1-butoxy, 2-butoxy, isopropoxy, t-butoxy, dodecyloxy or a cycloalkyloxy group, such as cyclopentyloxy or cyclohexyloxy);

an aryloxy group (aryloxy group preferably having 6 to 48 carbon atoms, more preferably 6 to 24 carbon atoms, for example, phenoxy or 1-naphthoxy);

a heterocyclic oxy group (heterocyclic oxy group preferably having 1 to 32 carbon atoms, more preferably 1 to 18 carbon atoms, for example, 1-phenyltetrazol-5-oxy or 2-tetrahydropyranyloxy);

a silyloxy group (silyloxy group preferably having 1 to 32 carbon atoms, more preferably 1 to 18 carbon atoms, for example, trimethylsilyloxy, t-butyldimethylsilyloxy or diphenylmethylsilyloxy);

an acyloxy group (acyloxy group preferably having 2 to 48 carbon atoms, more preferably 2 to 24 carbon atoms, for example, acetoxy, pivaloyloxy, benzoyloxy or dodecanoyloxy);

an alkoxycarbonyloxy group (alkoxycarbonyloxy group preferably having 2 to 48 carbon atoms, more preferably 2 to 24 carbon atoms, for example, ethoxycarbonyloxy, t-butoxycarbonyloxy or a cycloalkyloxycarbonyloxy group, such as cyclohexyloxycarbonyloxy);

an aryloxycarbonyloxy group (aryloxycarbonyloxy group preferably having 7 to 32 carbon atoms, more preferably 7 to 24 carbon atoms, for example, phenoxycarbonyloxy);

a carbamoyloxy group (carbamoyloxy group preferably having 1 to 48 carbon atoms, more preferably 1 to 24 carbon atoms, for example, N,N-dimethylcarbamoyloxy, N-butylcarbamoyloxy, N-phenylcarbamoyloxy or N-ethyl-N-phenylcarbamoyloxy);

a sulfamoyloxy group (sulfamoyloxy group preferably having 1 to 32 carbon atoms, more preferably 1 to 24 carbon atoms, for example, N,N-diethylsulfamoyloxy or N-propylsulfamoyloxy);

an alkylsulfonyloxy group (alkylsulfonyloxy group preferably having 1 to 38 carbon atoms, more preferably 1 to 24 carbon atoms, for example, methylsulfonyloxy, hexadecylsulfonyloxy or cyclohexylsulfonyloxy);

an arylsulfonyloxy group (arylsulfonyloxy group preferably having 6 to 32 carbon atoms, more preferably 6 to 24 carbon atoms, for example, phenylsulfonyloxy);

an acyl group (acyl group preferably having 1 to 48 carbon atoms, more preferably 1 to 24 carbon atoms, for example, formyl, acetyl, pivaloyl, benzoyl, tetradecanoyl or cyclohexanoyl);

an alkoxycarbonyl group (alkoxycarbonyl group preferably having 2 to 48 carbon atoms, more preferably 2 to 24 carbon atoms, for example, methoxycarbonyl, ethoxycarbonyl, octadecyloxycarbonyl, cyclohexyloxycarbonyl or 2,6-di-tert-butyl-4-methylcyclohexyloxycarbonyl);

an aryloxycarbonyl group (aryloxycarbonyl group preferably having 7 to 32 carbon atoms, more preferably 7 to 24 carbon atoms, for example, phenoxycarbonyl);

a carbamoyl group (carbamoyl group preferably having 1 to 48 carbon atoms, more preferably 1 to 24 carbon atoms, for example, carbamoyl, N,N-diethylcarbamoyl, N-ethyl-N-octylcarbamoyl, N,N-dibutylcarbamoyl, N-propylcarbamoyl, N-phenylcarbamoyl, N-methyl-N-phenylcarbamoyl or N,N-dicyclohexylcarbamoyl);

an amino group (amino group preferably having up to 32 carbon atoms, more preferably up to 24 carbon atoms, for example, amino, methylamino, N,N-dibutylamino, tetradecylamino, 2-ethylhexylamino or cyclohexylamino);

an anilino group (anilino group preferably having 6 to 32 carbon atoms, more preferably 6 to 24 carbon atoms, for example, anilino or N-methylanilino);

a heterocyclic amino group (heterocyclic amino group preferably having 1 to 32 carbon atoms, more preferably 1 to 18 carbon atoms, for example, 4-pyridylamino);

a carbonamido group (carbonamido group preferably having 2 to 48 carbon atoms, more preferably 2 to 24 carbon atoms, for example, acetamido, benzamido, tetradecanamido, pivaloylamido or cyclohexanamido);

a ureido group (ureido group preferably having 1 to 32 carbon atoms, more preferably 1 to 24 carbon atoms, for example, ureido, N,N-dimethylureido or N-phenylureido);

an imido group (imido group preferably having up to 36 carbon atoms, more preferably up to 24 carbon atoms, for example, N-succinimido or N-phthalimido);

an alkoxycarbonylamino group (alkoxycarbonylamino group preferably having 2 to 48 carbon atoms, more preferably 2 to 24 carbon atoms, for example, methoxycarbonylamino, ethoxycarbonylamino, t-butoxycarbonylamino, octadecyloxycarbonylamino or cyclohexyloxycarbonylamino);

an aryloxycarbonylamino group (aryloxycarbonylamino group preferably having 7 to 32 carbon atoms, more preferably 7 to 24 carbon atoms, for example, phenoxycarbonylamino);

a sulfonamido group (sulfonamido group preferably having 1 to 48 carbon atoms, more preferably 1 to 24 carbon atoms, for example, methanesulfonamido, butanesulfonamido, benzenesulfonamido, hexadecanesulfonamido or cyclohexanesulfonamido);

a sulfamoylamino group (sulfamoylamino group preferably having 1 to 48 carbon atoms, more preferably 1 to 24 carbon atoms, for example, N,N-dipropylsulfamoylamino or N-ethyl-N-dodecylsulfamoylamino);

an azo group (azo group preferably having 1 to 32 carbon atoms, more preferably 1 to 24 carbon atoms, for example, phenylazo or 3-pyrazolylazo);

an alkylthio group (alkylthio group preferably having 1 to 48 carbon atoms, more preferably 1 to 24 carbon atoms, for example, methylthio, ethylthio, octylthio or cyclohexylthio);

an arylthio group (arylthio group preferably having 6 to 48 carbon atoms, more preferably 6 to 24 carbon atoms, for example, phenylthio);

a heterocyclic thio group (heterocyclic thio group preferably having 1 to 32 carbon atoms, more preferably 1 to 18 carbon atoms, for example, 2-benzothiazolylthio, 2-pyridylthio or 1-phenyltetrazolylthio);

an alkylsulfinyl group (alkylsulfinyl group preferably having 1 to 32 carbon atoms, more preferably 1 to 24 carbon atoms, for example, dodecanesulfinyl);

an arylsulfinyl group (arylsulfinyl group preferably having 6 to 32 carbon atoms, more preferably 6 to 24 carbon atoms, for example, phenylsulfinyl);

an alkylsulfonyl group (alkylsulfonyl group preferably having 1 to 48 carbon atoms, more preferably 1 to 24 carbon atoms, for example, methylsulfonyl, ethylsulfonyl, propylsulfonyl, butylsulfonyl, isopropylsulfonyl, 2-ethylhexylsulfonyl, hexadecylsulfonyl, octylsulfonyl or cyclohexylsulfonyl);

an arylsulfonyl group (arylsulfonyl group preferably having 6 to 48 carbon atoms, more preferably 6 to 24 carbon atoms, for example, phenylsulfonyl or 1-naphthylsulfonyl);

a sulfamoyl group (sulfamoyl group preferably having up to 32 carbon atoms, more preferably up to 24 carbon atoms, for example, sulfamoyl, N,N-dipropylsulfamoyl, N-ethyl-N-dodecylsulfamoyl, N-ethyl-N-phenylsulfamoyl or N-cyclohexylsulfamoyl);

a sulfo group;

a phosphonyl group (phosphonyl group preferably having 1 to 32 carbon atoms, more preferably 1 to 24 carbon atoms, for example, phenoxyphosphonyl, octyloxyphosphonyl or phenylphosphonyl); and

a phosphinoylamino group (phosphinoylamino group preferably having 1 to 32 carbon atoms, more preferably 1 to 24 carbon atoms, for example, diethoxyphosphinoylamino or dioctyloxyphosphinoylamino).

Preferably, the substituents that may be introduced in the aryl groups represented by R₁ and R₂ are a linear or branched alkyl group or cycloalkyl group (for example, methyl, ethyl, propyl, isopropyl, butyl, t-butyl, pentyl, hexyl, heptyl, octyl, 2-ethylhexyl, dodecyl, hexadecyl, cyclopropyl, cyclopentyl, cyclohexyl, 1-norbornyl or 1-adamantyl); a hydroxyl group; an alkoxy group (alkoxy group preferably having 1 to 48 carbon atoms, more preferably 1 to 24 carbon atoms, for example, methoxy, ethoxy, 1-butoxy, 2-butoxy, isopropoxy, t-butoxy, dodecyloxy or a cycloalkyloxy group, such as cyclopentyloxy or cyclohexyloxy); an amino group (amino group preferably having up to 32 carbon atoms, more preferably up to 24 carbon atoms, for example, amino, methylamino, N,N-dibutylamino, tetradecylamino, 2-ethylhexylamino or cyclohexylamino); and an alkoxycarbonylamino group (alkoxycarbonylamino group preferably having 2 to 48 carbon atoms, more preferably 2 to 24 carbon atoms, for example, methoxycarbonylamino, ethoxycarbonylamino, t-butoxycarbonylamino, octadecyloxycarbonylamino or cyclohexyloxycarbonylamino).

More preferably, the substituents that may be introduced in the aryl groups represented by R₁ and R₂ are a linear or branched alkyl group or cycloalkyl group (for example, methyl, ethyl, propyl, isopropyl, butyl, t-butyl, pentyl, hexyl, heptyl, octyl, 2-ethylhexyl, dodecyl, hexadecyl, cyclopropyl, cyclopentyl, cyclohexyl, 1-norbornyl or 1-adamantyl); a hydroxyl group; an alkoxy group (alkoxy group preferably having 1 to 48 carbon atoms, more preferably 1 to 24 carbon atoms, for example, methoxy, ethoxy, 1-butoxy, 2-butoxy, isopropoxy, t-butoxy, dodecyloxy or a cycloalkyloxy group, such as cyclopentyloxy or cyclohexyloxy); and an alkoxycarbonylamino group (alkoxycarbonylamino group preferably having 2 to 48 carbon atoms, more preferably 2 to 24 carbon atoms, for example, methoxycarbonylamino, ethoxycarbonylamino, t-butoxycarbonylamino, octadecyloxycarbonylamino or cyclohexyloxycarbonylamino).

Further more preferably, the substituents that may be introduced in the aryl groups represented by R₁ and R₂ are a linear or branched alkyl group or cycloalkyl group (for example, methyl, ethyl, propyl, isopropyl, butyl, t-butyl, pentyl, hexyl, heptyl, octyl, 2-ethylhexyl, dodecyl, hexadecyl, cyclopropyl, cyclopentyl, cyclohexyl, 1-norbornyl or 1-adamantyl); and an alkoxy group (alkoxy group preferably having 1 to 48 carbon atoms, more preferably 1 to 24 carbon atoms, for example, methoxy, ethoxy, 1-butoxy, 2-butoxy, isopropoxy, t-butoxy, dodecyloxy or a cycloalkyloxy group, such as cyclopentyloxy or cyclohexyloxy).

As mentioned above, R₁ and R₂ may be connected to each other. Preferably, R₁ and R₂ are connected to each other through, for example, a single bond or a bivalent connecting group. As the bivalent connecting group, there can be mentioned, for example, a substituted or unsubstituted alkylene group, —O—, —S—, —CO—, —N(R)— (in the formula, R is a hydrogen atom, an alkyl group, an alkylcarbonyl group or an alkyloxycarbonyl group), a bivalent connecting group comprised of a combination of two or more of these or the like.

As mentioned above, each of R₃ and R₄ represents a hydrogen atom, an optionally substituted alkyl group, an optionally substituted cycloalkyl group, an optionally substituted alkenyl group or an optionally substituted aryl group, provided that R₃ and R₄ may be connected to each other.

Each of the alkyl groups represented by R₃ and R₄ is preferably a linear or branched alkyl group having 1 to 20 carbon atoms. The alkyl group in its chain may contain an oxygen atom, a sulfur atom or a nitrogen atom. For example, there can be mentioned a linear alkyl group, such as a methyl group, an ethyl group, an n-propyl group, an n-butyl group, an n-pentyl group, an n-hexyl group, an n-octyl group, an n-dodecyl group, an n-tetradecyl group or an n-octadecyl group, and a branched alkyl group, such as an isopropyl group, an isobutyl group, a t-butyl group, a neopentyl group or a 2-ethylhexyl group. As substituted alkyl groups, there can be mentioned a cyanomethyl group, a 2,2,2-trifluoroethyl group, a methoxycarbonylmethyl group, an ethoxycarbonylmethyl group and the like.

Each of the cycloalkyl groups represented by R₃ and R₄ is preferably one having 3 to 20 carbon atoms. The cycloalkyl group in its ring may contain an oxygen atom. As examples thereof, there can be mentioned a cyclopropyl group, a cyclopentyl group, a cyclohexyl group, a norbornyl group, an adamantyl group and the like.

Each of the aryl groups represented by R₃ and R₄ is preferably one having 6 to 14 carbon atoms. For example, there can be mentioned a phenyl group, a naphthyl group and the like.

Each of the alkenyl groups represented by R₃ and R₄ is preferably one having 2 to 20 carbon atoms. For example, there can be mentioned groups resulting from the introduction of a double bond at an arbitrary position of any of the above alkyl groups represented by R₃ and R₄.

As substituents that may be introduced in these groups, there can be mentioned, for example, those set forth above as being introducible in the aryl groups represented by R₁ and R₂.

The ring structure that can be formed by the mutual linkage of R₃ and R₄ is preferably a 5- or 6-membered ring, most preferably a 6-membered ring.

Preferably, each of R₃ and R₄ is a hydrogen atom, an alkyl group, a cycloalkyl group, an alkenyl group or an aryl group, which R₃ and R₄ may be connected to each other.

More preferably, each of R₃ and R₄ is a hydrogen atom, an alkyl group, a cycloalkyl group or an aryl group, which R₃ and R₄ may be connected to each other.

Further more preferably, each of R₃ and R₄ is a hydrogen atom or an alkyl group, which R₃ and R₄ may be connected to each other.

As mentioned above, R₅ represents an optionally substituted alkyl group, an optionally substituted cycloalkyl group, an optionally substituted alkenyl group, an optionally substituted aryl group, an optionally substituted aralkyl group or an optionally substituted alkylcarbonyl group, provided that R₅ may be connected to R₃ or R₄.

Particular examples of the alkyl groups, cycloalkyl groups, alkenyl groups, aryl groups and alkyl groups in alkylcarbonyl groups, represented by R₅ are the same as set forth above in connection with the alkyl groups, cycloalkyl groups, alkenyl groups and aryl groups, represented by R₃ and R₄. Substituents introducible in such groups are also the same.

The aralkyl group represented by R₅ is preferably, for example, one having 7 to 20 carbon atoms. For example, there can be mentioned a benzyl group, a phenethyl group or the like. As substituents introducible in the aralkyl group, there can be mentioned, for example, those set forth above in connection with the aryl groups represented by R₁ and R₂.

Moreover, a group cleaved under the action of an acid, for example, a tertiary alkyl group such as a t-butyl group, may be contained in each of the groups represented by R₅. As the group cleaved under the action of an acid, there can be mentioned, for example, any of the groups of the formulae —C(R₁₁)(R₁₂)(R₁₃), —C(R₁₁)(R₁₂)(OR₁₄) and —C(Rₐ)(R_{b})(OR₁₄). In the formulae, each of R₁₁ to R₁₄ independently represents an alkyl group, a cycloalkyl group, an aryl group, an aralkyl group or an alkenyl group. R₁₁ and R₁₂ may be bonded to each other to thereby form a ring. Each of Rₐ and R_{b} independently represents a hydrogen atom, an alkyl group, a cycloalkyl group, an aryl group, an aralkyl group or an alkenyl group.

In one aspect of the present invention, R₅ is preferably an alkyl group, a cycloalkyl group, an alkenyl group or an aralkyl group; more preferably an alkyl group, a cycloalkyl group or an aralkyl group; and further more preferably an alkyl group or a cycloalkyl group. The carbon atom bonded to oxygen atom may be any of a primary carbon, a secondary carbon and a tertiary carbon.

As mentioned above, R₅ may be connected to R₃ or R₄. For example, a 5- to 7-membered lactone structure is preferably formed by the connection. Another cyclic structure may be condensed with the lactone structure in a fashion to form a bicyclo structure or spiro structure.

As the nonnucleophilic anion represented by X⁻, there can be mentioned, for example, a sulfonate anion, a carboxylate anion, a sulfonylimide anion, a bis(alkylsulfonyl)imide anion, a tris(alkylsulfonyl)methyl anion or the like. The nonnucleophilic anion means an anion whose capability of inducing a nucleophilic reaction is extremely low and is an anion capable of inhibiting any temporal decomposition by intramolecular nucleophilic reaction. This would realize an enhancement of the temporal stability of the resist.

As the sulfonate anion, there can be mentioned, for example, an alkyl sulfonate anion, an aryl sulfonate anion, a camphor sulfonate anion or the like.

As the carboxylate anion, there can be mentioned, for example, an alkyl carboxylate anion, an aryl carboxylate anion, an aralkyl carboxylate anion or the like.

The alkyl group in the alkyl sulfonate anion is preferably an alkyl group having 1 to 30 carbon atoms, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group or the like.

As a preferred aromatic group in the aryl sulfonate anion, there can be mentioned an aryl group having 6 to 14 carbon atoms, for example, a phenyl group, a tolyl group, a naphthyl group or the like.

Substituents may be introduced in the alkyl group and aryl group in the alkyl sulfonate anion and aryl sulfonate anion.

As the substituents, there can be mentioned, for example, a halogen atom, an alkyl group, an alkoxy group, an alkylthio group and the like.

The halogen atom is, for example, a chlorine atom, a bromine atom, a fluorine atom, an iodine atom or the like.

The alkyl group is preferably, for example, an alkyl group having 1 to 15 carbon atoms. As the alkyl group, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group or the like.

The alkoxy group is preferably, for example, an alkoxy group having 1 to 5 carbon atoms, such as a methoxy group, an ethoxy group, a propoxy group, a butoxy group or the like.

The alkylthio group is preferably, for example, an alkylthio group having 1 to 15 carbon atoms. As the alkylthio group, there can be mentioned, for example, a methylthio group, an ethylthio group, a propylthio group, an isopropylthio group, an n-butylthio group, an isobutylthio group, a sec-butylthio group, a pentylthio group, a neopentylthio group, a hexylthio group, a heptylthio group, an octylthio group, a nonylthio group, a decylthio group, an undecylthio group, a dodecylthio group, a tridecylthio group, a tetradecylthio group, a pentadecylthio group, a hexadecylthio group, a heptadecylthio group, an octadecylthio group, a nonadecylthio group, an eicosylthio group or the like. These alkyl, alkoxy and alkylthio groups may further be substituted with halogen atoms (preferably a fluorine atom).

The alkyl group in the alkyl carboxylate anion can be the same as mentioned above with respect to the alkyl sulfonate anion.

The aryl group in the aryl carboxylate anion can be the same as mentioned above with respect to the aryl sulfonate anion.

As a preferred aralkyl group in the aralkyl carboxylate anion, there can be mentioned an aralkyl group having 6 to 12 carbon atoms, for example, a benzyl group, a phenethyl group, a naphthylmethyl group, a naphthylethyl group, a naphthylbutyl group or the like.

Substituents may be introduced in the alkyl group, aryl group and aralkyl group in the above alkyl carboxylate anion, aryl carboxylate anion and aralkyl carboxylate anion. As the substituents, there can be mentioned, for example, the same halogen atoms, alkyl groups, alkoxy groups, alkylthio groups, etc., as mentioned above with respect to the aryl sulfonate anion.

As the sulfonylimide anion, there can be mentioned, for example, a saccharin anion.

The alkyl group in the bis(alkylsulfonyl)imide anion and tris(alkylsulfonyl)methyl anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. A substituent may be introduced in this alkyl group. As the substituent, there can be mentioned a halogen atom, an alkyl group substituted with a halogen atom, an alkoxy group, an alkylthio group or the like. An alkyl group substituted with a fluorine atom is preferred.

As other nonnucleophilic anions, there can be mentioned, for example, phosphorus fluoride, boron fluoride, antimony fluoride and the like.

The nonnucleophilic anion represented by X⁻ is preferably selected from among an alkanesulfonate anion substituted at its α-position of sulfonic acid with a fluorine atom, an aryl sulfonate anion substituted with a fluorine atom or a group containing a fluorine atom, a bis(alkylsulfonyl)imide anion whose alkyl group is substituted with a fluorine atom and a tris(alkylsulfonyl)methide anion whose alkyl group is substituted with a fluorine atom. Most preferably, the nonnucleophilic anion represented by X⁻ is a perfluoroalkanesulfonate anion having 1 to 8 carbon atoms, such as a nonafluorobutanesulfonate anion or a perfluorooctanesulfonate anion.

In one aspect of the present invention, it is preferred for the nonnucleophilic anion represented by X⁻ to be expressed by general formula (2) below. If so, it is presumed that the volume of generated acid is large, so that the diffusion of the acid is inhibited to thereby promote an enhancement of exposure latitude.

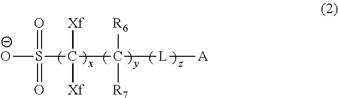

In general formula (2),

each of Xf's independently represents a fluorine atom or an alkyl group substituted with at least one fluorine atom.

Each of R₆ and R₇ independently represents a hydrogen atom, a fluorine atom, an alkyl group or an alkyl group substituted with at least one fluorine atom. Two or more R₆s, and R₇s may be identical to or different from each other.

L represents a bivalent connecting group. Two or more L's may be identical to or different from each other.

A represents an organic group with a cyclic structure.

In the formula, x is an integer of 1 to 20; y is an integer of 0 to 10; and z is an integer of 0 to 10.

The anions of general formula (2) will be described in detail below.

As mentioned above, Xf represents a fluorine atom or an alkyl group substituted with at least one fluorine atom. The alkyl group in the alkyl group substituted with at least one fluorine atom preferably has 1 to 10 carbon atoms, more preferably 1 to 4 carbon atoms. The alkyl group substituted with at least one fluorine atom, represented by Xf is preferably a perfluoroalkyl group.

Xf is preferably a fluorine atom or a perfluoroalkyl group having 1 to 4 carbon atoms. In particular, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, a fluorine atom and CF₃ are preferred. It is especially preferred for both Xf's to be a fluorine atom.

As mentioned above, each of R₆ and R₇ represents a hydrogen atom, a fluorine atom, an alkyl group or an alkyl group substituted with at least one fluorine atom. The alkyl group preferably has 1 to 4 carbon atoms. More preferably, each of R₆ and R₇ is a perfluoroalkyl group having 1 to 4 carbon atoms. As particular examples of the alkyl groups substituted with at least one fluorine atom, represented by R₆ and R₇, there can be mentioned CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, CF₃ is preferred.

L represents a bivalent connecting group. As the bivalent connecting group, there can be mentioned —COO—, —OCO—, —CO—, —O—, —S—, —SO—, —SO₂—, —N(Ri)— (in which Ri represents a hydrogen atom or an alkyl), an alkylene group (preferably 1 to 6 carbon atoms), a cycloalkylene group (preferably 3 to 10 carbon atoms), an alkenylene group (preferably 2 to 6 carbon atoms), a bivalent connecting group comprised of a combination of two or more of these, or the like. L is preferably —COO—, —OCO—, —CO—, —SO₂—, —CON(Ri)—, —SO₂N(Ri)—, —CON(Ri)— alkylene-, —N(Ri)CO-alkylene-, —COO-alkylene- or —OCO-alkylene-, more preferably —COO—, —OCO—, —SO₂—, —CON(Ri)— or —SO₂N(Ri)—. Two or more L's may be identical to or different from each other.

Specific examples and preferred examples of the alkyl groups represented by Ri are the same as those set forth above in connection with R₁ to R₅.

The organic group with a cyclic structure, represented by A is not particularly limited as long as a cyclic structure is contained. For example, there can be mentioned an alicyclic group, an aryl group, a heterocyclic group (not only an aromatic heterocycle but also a nonaromatic heterocycle, including, for example, tetrahydropyran ring and lactone ring structures), or the like.

The alicyclic group may be monocyclic or polycyclic. As preferred alicyclic groups, there can be mentioned a monocycloalkyl group, such as a cyclopentyl group, a cyclohexyl group or a cyclooctyl group, and a polycycloalkyl group, such as a norbornyl group, a norbornenyl group, a tricyclodecanyl group (for example, a tricyclo[5.2.1.0(2,6)]decanyl group), a tetracyclodecanyl group, a tetracyclododecanyl group or an adamantyl group. Also, preferred use is made of a nitrogen-atom-containing alicyclic group, such as a piperidine group, a decahydroquinoline group or a decahydroisoquinoline group. Of these, alicyclic groups with a bulky structure having at least 7 carbon atoms, selected from among a norbornyl group, a tricyclodecanyl group, a tetracyclodecanyl group, a tetracyclododecanyl group, an adamantyl group, a decahydroquinoline group and a decahydroisoquinoline group, are preferred from the viewpoint of inhibiting any in-film diffusion in the PEB (post-exposure bake) operation, thereby attaining an enhancement of exposure latitude.

As the aryl groups, there can be mentioned a benzene ring, a naphthalene ring, a phenanthrene ring and an anthracene ring. Of these, naphthalene ensuring a low absorbance from the viewpoint of the light absorbance at 193 nm is preferred.

As the heterocyclic groups, there can be mentioned a furan ring, a thiophene ring, a benzofuran ring, a benzothiophene ring, a dibenzofuran ring, a dibenzothiophene ring and a pyridine ring. Of these, a furan ring, a thiophene ring and a pyridine ring are preferred.

Substituents may be introduced in the above cyclic organic groups. As the substituents, there can be mentioned an alkyl group (any of linear, branched and cyclic forms, preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamido group, a sulfonic ester group and the like.

The carbon as a constituent of the organic group with a cyclic structure (carbon contributing to ring formation) may be a carbonyl carbon.

In the formula, x is preferably in the range of 1 to 8, more preferably 1 to 4 and most preferably 1; y is preferably in the range of 0 to 4, more preferably 0 or 1 and most preferably 0; and z is preferably in the range of 0 to 8, more preferably 0 to 4 and most preferably 1.

As an example, expressed as a sulfonic acid structure with hydrogen added, of one preferred form of the sulfonate anion structure in the compound (A), there can be mentioned any of those of general formula (2a) below. In the formula, Xf, R₆, R₇, L, A, y and z are as defined above in connection with general formula (2).

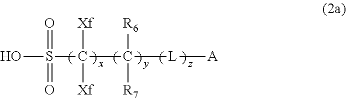

In another aspect of the present invention, the nonnucleophilic anion represented by X⁻ may be a disulfonylimidate anion.

It is preferred for the disulfonylimidate anion to be a bis(alkylsulfonyl)imide anion.

The alkyl group in the bis(alkylsulfonyl)imide anion is preferably an alkyl group having 1 to 5 carbon atoms.

In the bis(alkylsulfonyl)imide anion, two alkyl groups may be connected to each other to thereby form an alkylene group (preferably 2 to 4 carbon atoms), which may form a ring in cooperation with the imide group and two sulfonyl groups. The ring structure that may be formed in the bis(alkylsulfonyl)imide anion is preferably a 5- to 7-membered ring, more preferably a 6-membered ring.

As substituents that can be introduced in the above alkyl group and the alkylene group formed by the mutual connection of two alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group and the like. A fluorine atom and an alkyl group substituted with a fluorine atom are preferred.

From the viewpoint of acid strength, it is preferred for the pKa value of generated acid to be −1 or below. This would realize an enhancement of sensitivity.

The compound (A) may be a compound with a plurality of structures of general formula (1). For example, the compound (A) may be a compound with a structure in which R₅ in general formula (1) is bonded to R₅ in another general formula (1) via a single bond or a connecting group.

Preferred particular examples of the compounds (A) of general formula (1) above are shown below, which in no way limit the scope of the present invention.

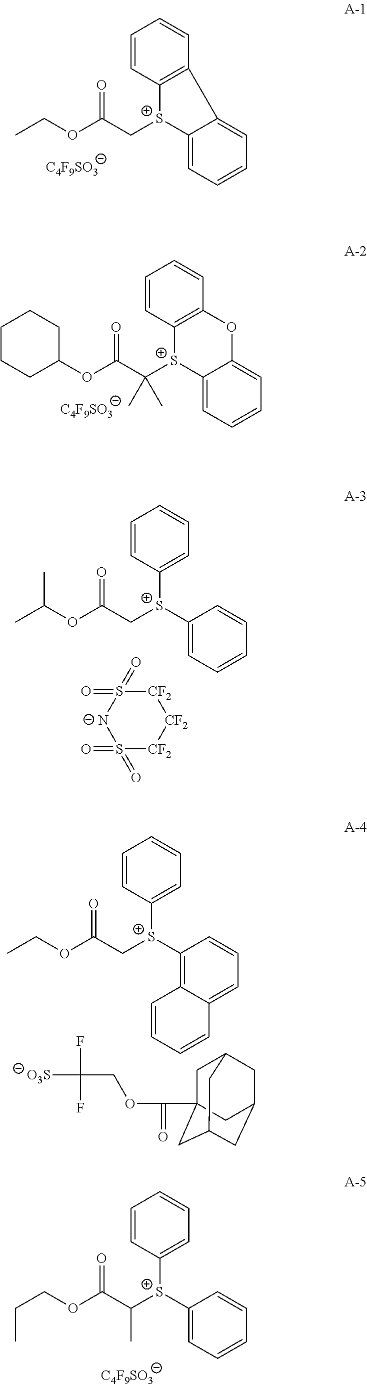

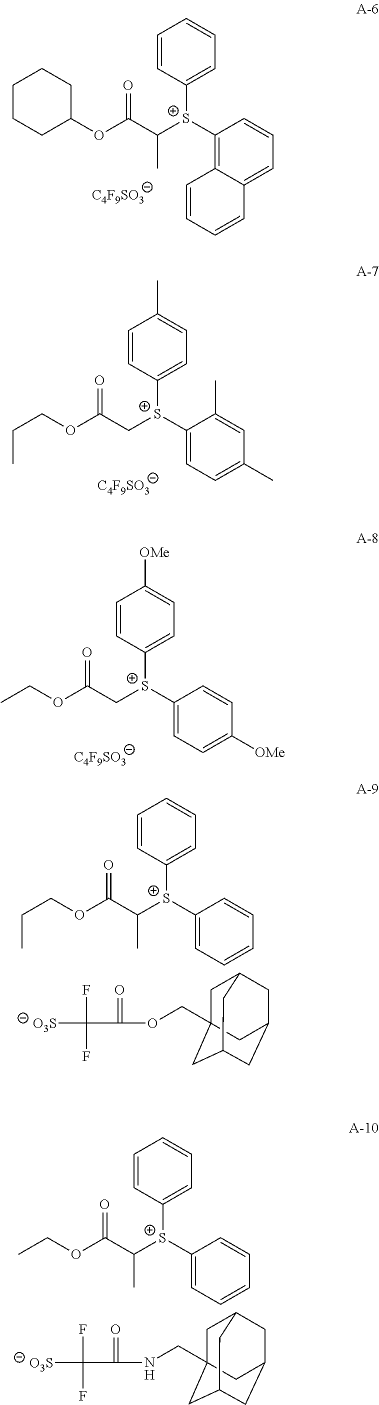

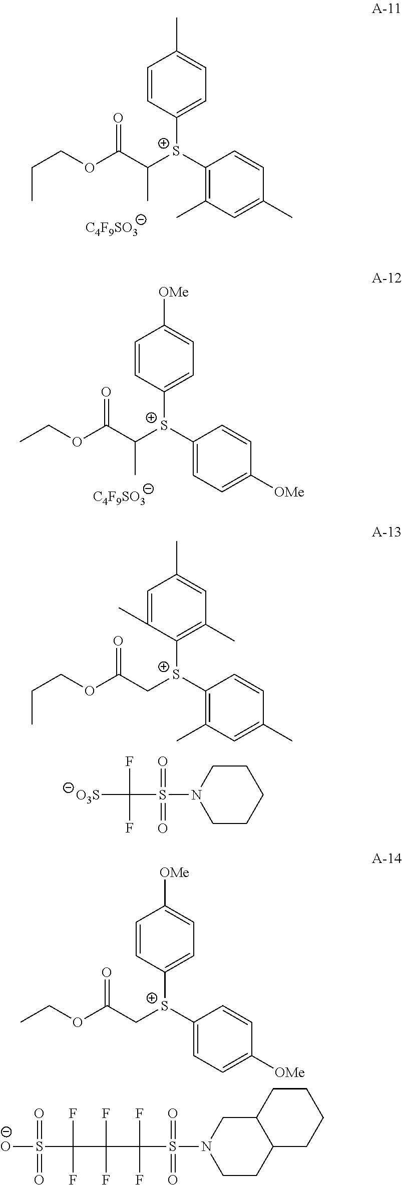

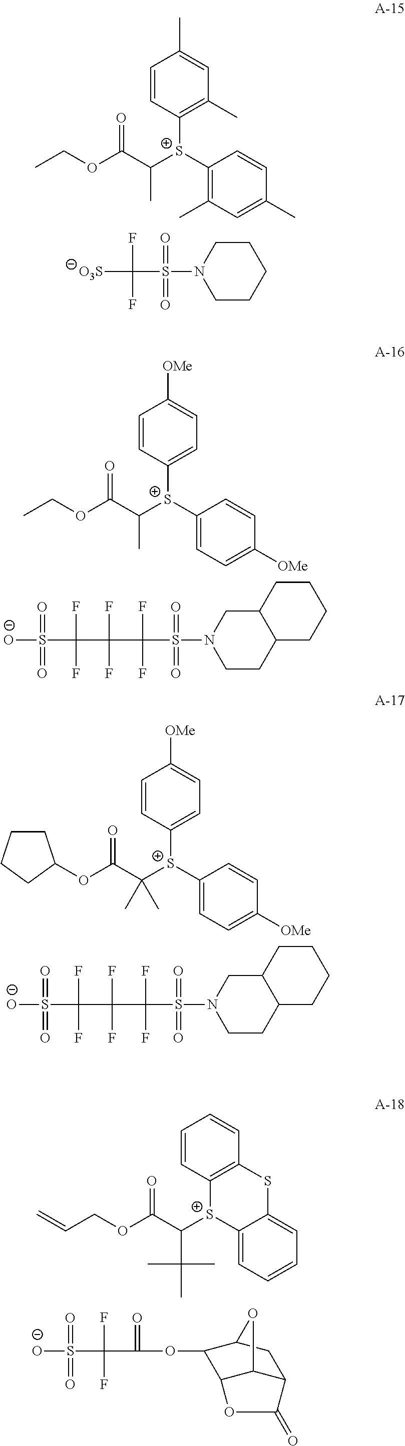

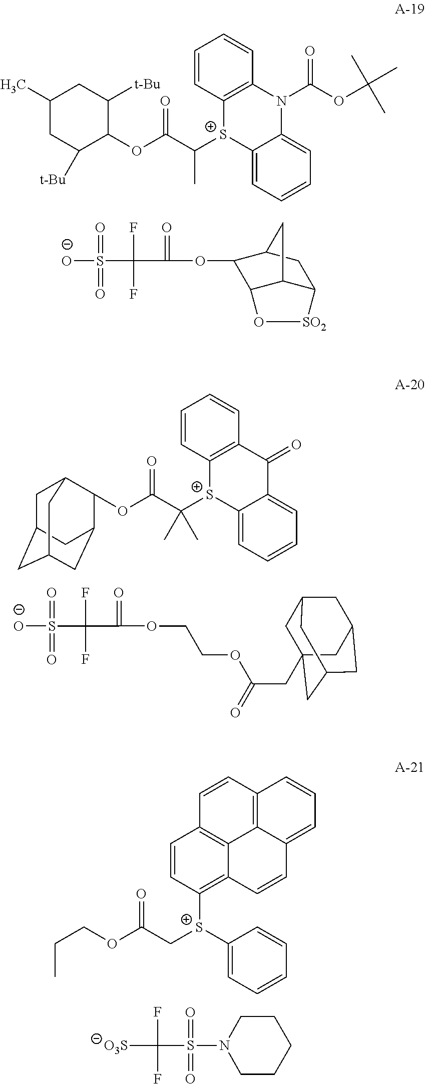

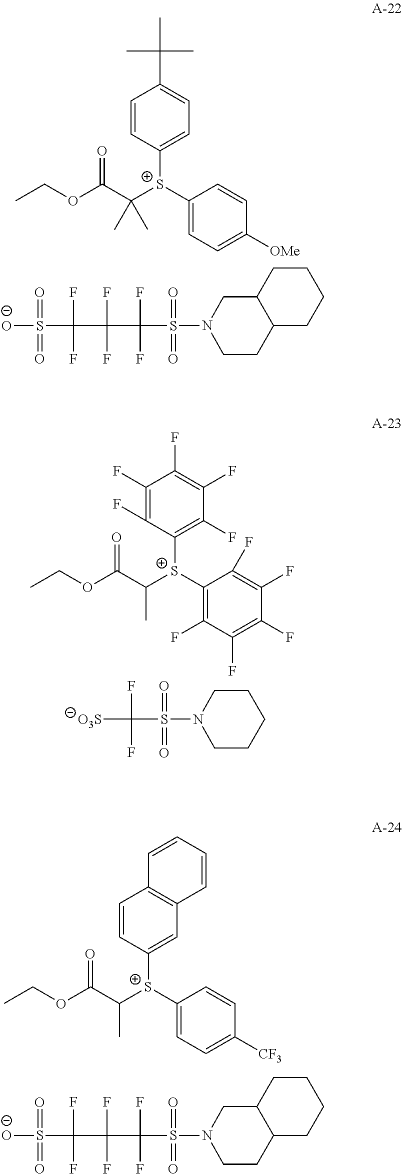

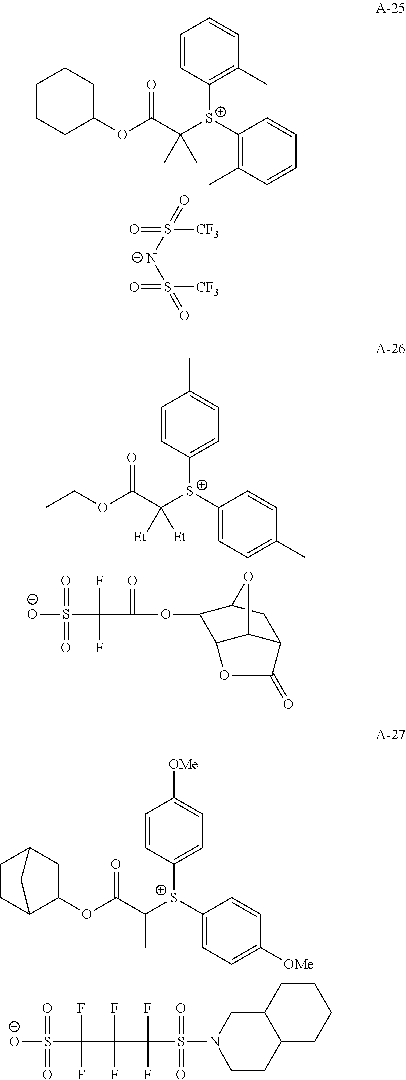

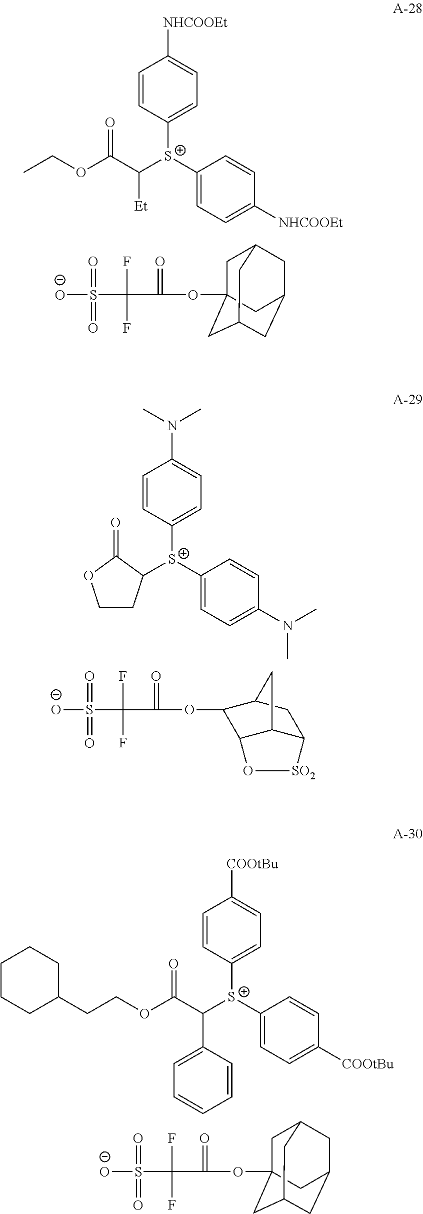

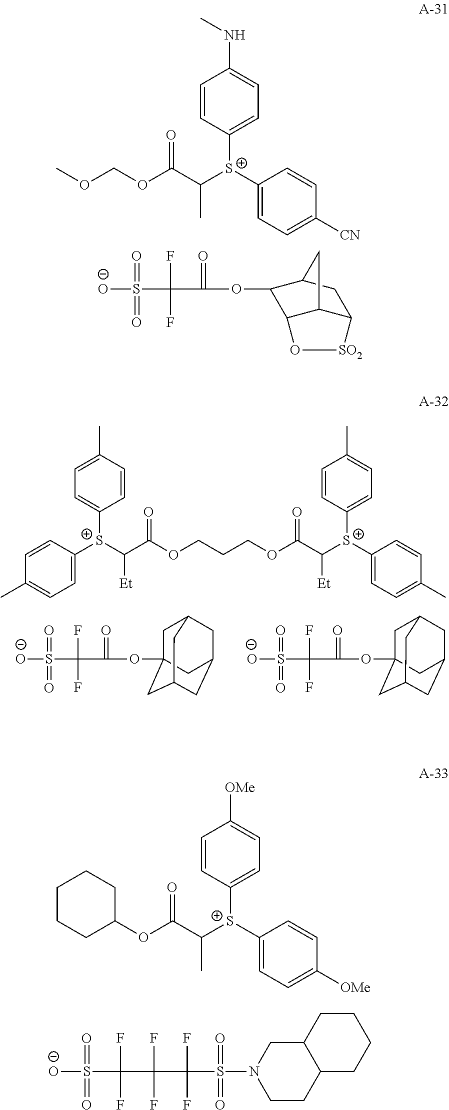

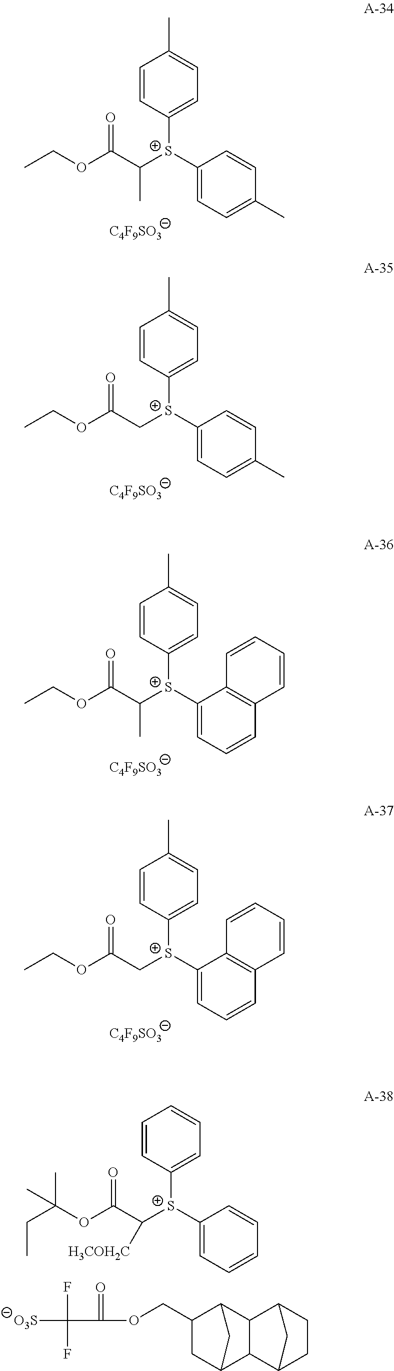

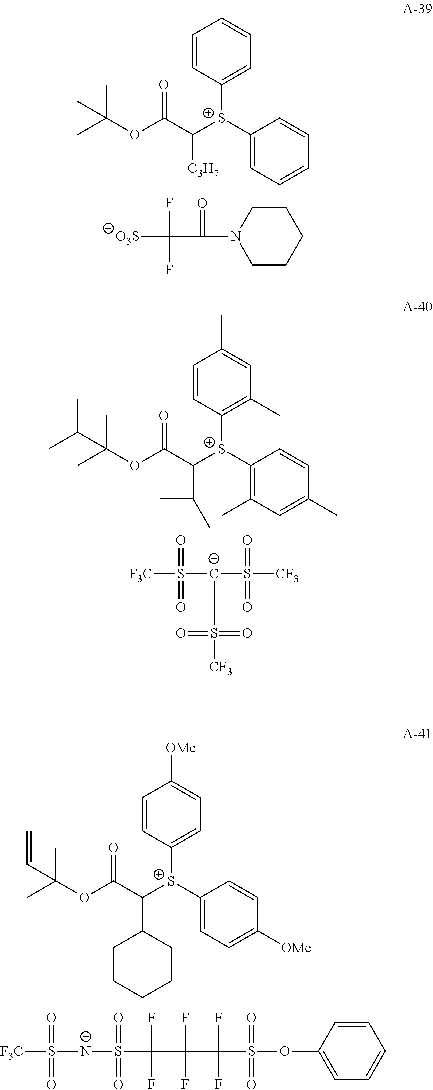

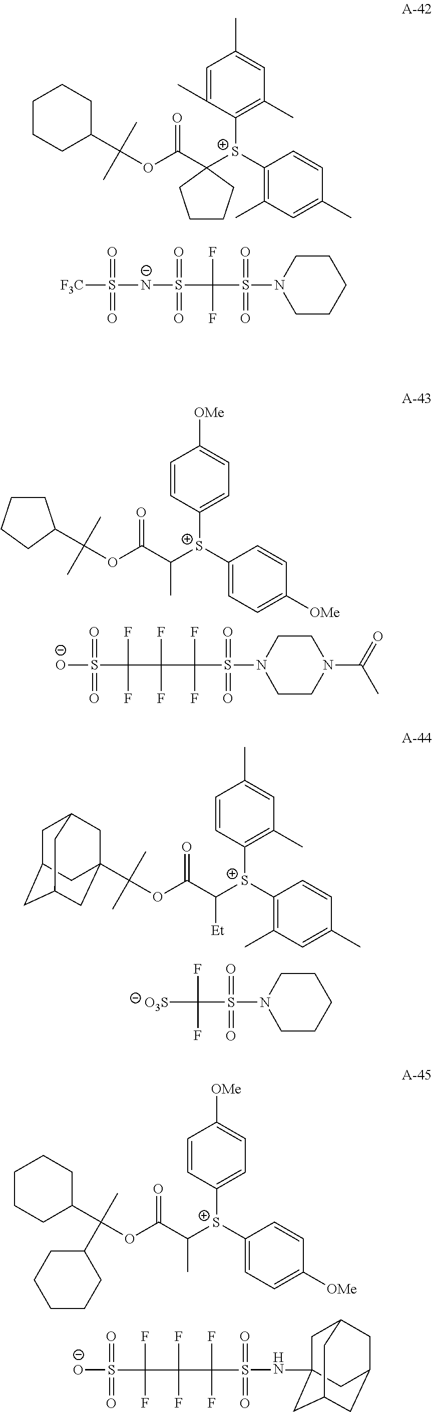

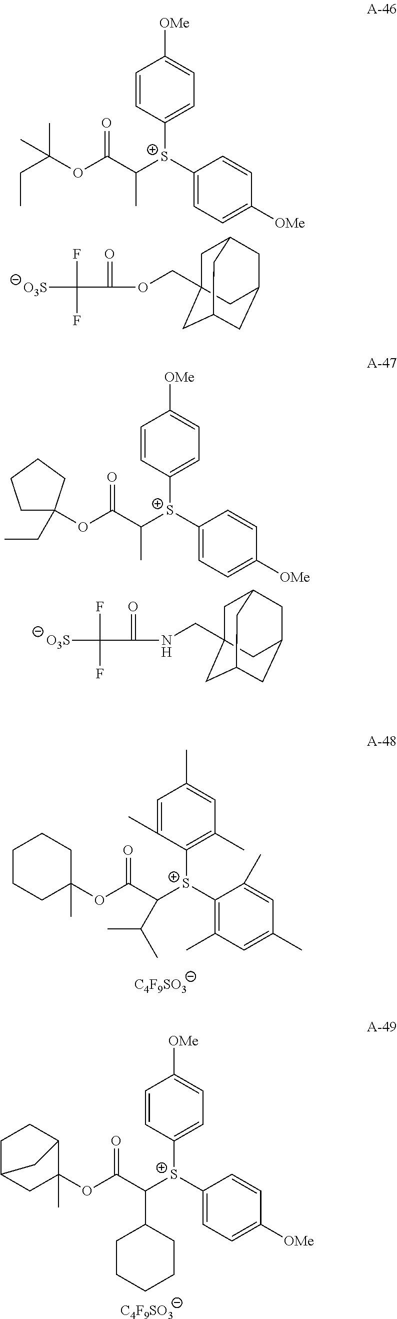

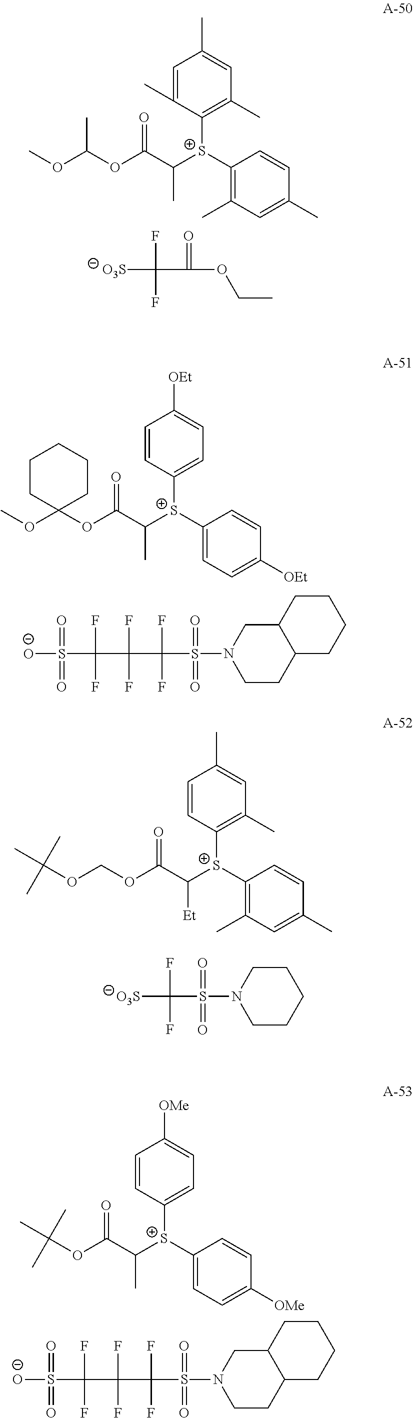

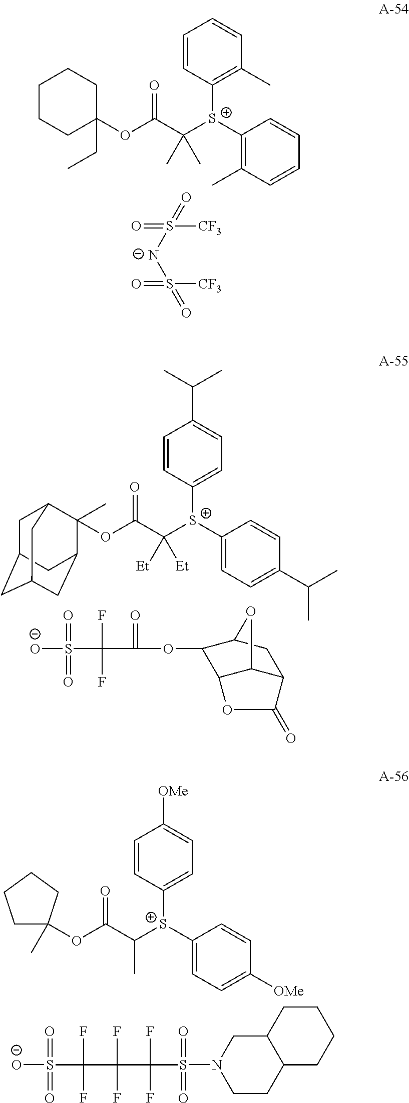

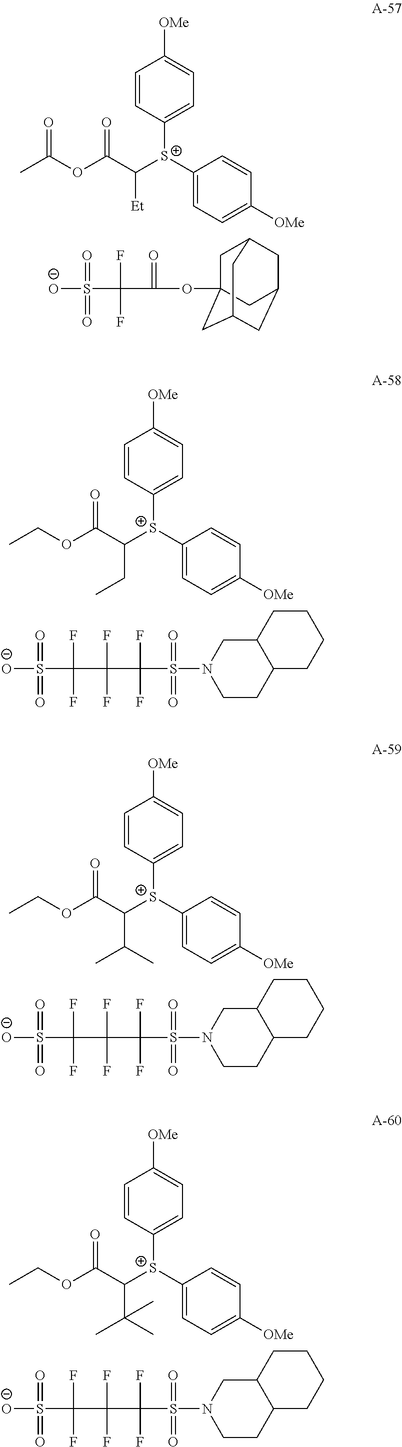

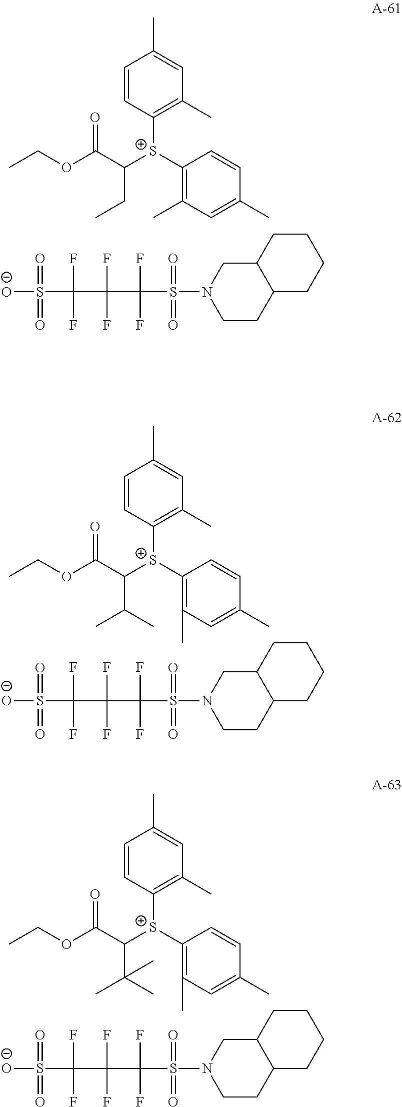

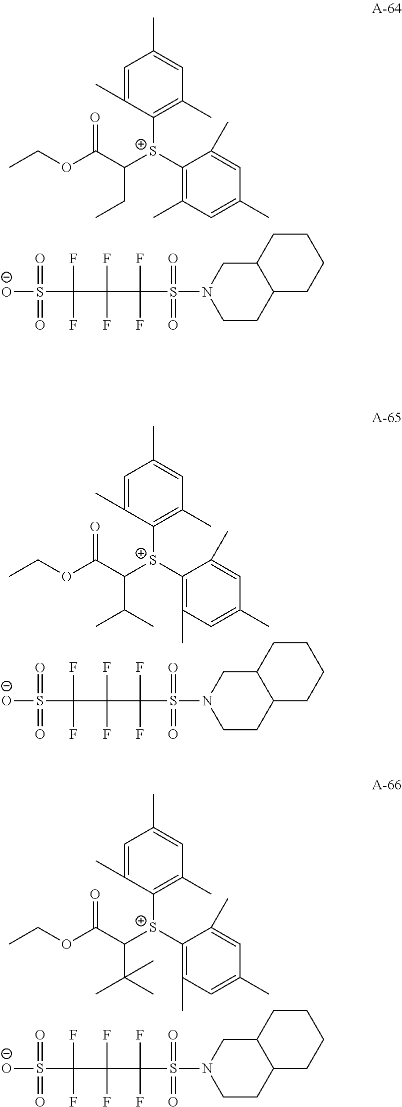

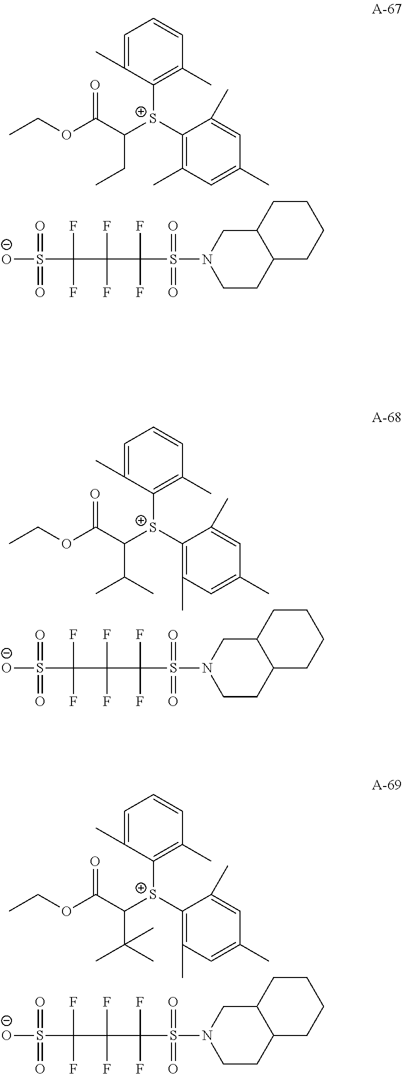

The method of synthesizing the compound (A) will be described below.

The sulfonate anions in general formula (1) or salts thereof can be used in the synthesis of the compounds (A) of general formula (1). The sulfonate anions in general formula (1) or salts (for example, onium salts or metal salts) thereof that can be employed in the synthesis of the compounds (A) can be synthesized by using a common sulfonic-esterification reaction or sulfonamidation reaction. For example, these can be synthesized by a method in which one sulfonyl halide moiety of a bissulfonyl halide compound is caused to selectively react with, for example, an amine, an alcohol, an amide compound or the like to thereby form a sulfonamido bond, a sulfonic ester bond or a sulfonimide bond, and thereafter the other sulfonyl halide moiety is hydrolyzed, or alternatively by a method in which the ring of a cyclic sulfonic anhydride is opened by an amine, an alcohol or an amide compound.

As salts of the sulfonate anions in general formula (1), there can be mentioned sulfonic acid metal salts, sulfonic acid onium salts and the like. As metals in the sulfonic acid metal salts, there can be mentioned Na⁺, Li⁺, K⁺ and the like. As onium cations in the sulfonic acid onium salts, there can be mentioned an ammonium cation, a sulfonium cation, an iodonium cation, a phosphonium cation, a diazonium cation and the like.

The compounds (A) can be synthesized by a method comprising a salt exchange between sulfonate anions in general formula (1) above and photoactive onium salts, such as a sulfonium salt corresponding to a sulfonium cation in general formula (1) above.

In the actinic-ray- or radiation-sensitive resin composition of the present invention, one type of compound (A) may be used alone, two or more types thereof may be used in combination. The content of compound (A) in the composition of the present invention, based on the total solids of the composition, is preferably in the range of 0.1 to 40 mass %, more preferably 0.5 to 30 mass % and further more preferably 5 to 25 mass %.

The compound (A) may be used in combination with an acid generator (hereinafter also referred to as a compound (A′)) other than the compounds (A).

The compound (A′) is not particularly limited. As preferred compounds (A′), there can be mentioned the compounds of general formulae (ZI′), (ZII′) and (ZIII′) below.

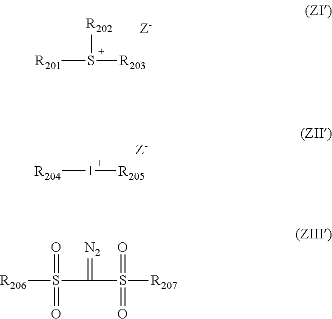

In general formula (ZI′),

each of R₂₀₁, R₂₀₂ and R₂₀₃ independently represents an organic group.

The number of carbon atoms of the organic group represented by R₂₀₁, R₂₀₂ and R₂₀₃ is generally in the range of 1 to 30, preferably 1 to 20.

Two of R₂₀₁ to R₂₀₃ may be bonded with each other to thereby form a ring structure, and the ring within the same may contain an oxygen atom, a sulfur atom, an ester bond, an amido bond or a carbonyl group. As the group formed by bonding of two of R₂₀₁ to R₂₀₃, there can be mentioned an alkylene group (for example, a butylene group or a pentylene group).

As the organic groups represented by R₂₀₁, R₂₀₂ and R₂₀₃, there can be mentioned, for example, groups corresponding to the compound (ZI′-1) to be described hereinbelow.

Appropriate use may be made of compounds with two or more of the structures of general formula (ZI′). For example, use may be made of compounds having a structure wherein at least one of R₂₀₁ to R₂₀₃ of a compound of general formula (ZI′) is bonded via a single bond or a connecting group to at least one of R₂₀₁ to R₂₀₃ of another compound of general formula (ZI′).

Z⁻ represents a nonnucleophilic anion. The nonnucleophilic anion means an anion whose capability of inducing a nucleophilic reaction is extremely low.

As the nonnucleophilic anion represented by Z⁻, there can be mentioned, for example, a sulfonate anion (for example, an aliphatic sulfonate anion, an aromatic sulfonate anion, a camphor sulfonate anion or the like), a carboxylate anion (for example, an aliphatic carboxylate anion, an aromatic carboxylate anion, an aralkyl carboxylate anion or the like), a sulfonylimido anion, a bis(alkylsulfonyl)imido anion, a tris(alkylsulfonyl)methide anion or the like.

The aliphatic moiety of the aliphatic sulfonate anion and the aliphatic carboxylate anion may be an alkyl group or a cycloalkyl group, being preferably a linear or branched alkyl group having 1 to 30 carbon atoms or a cycloalkyl group having 3 to 30 carbon atoms.

As a preferred aromatic group of the aromatic sulfonate anion and the aromatic carboxylate anion, there can be mentioned an aryl group having 6 to 14 carbon atoms, for example, a phenyl group, a tolyl group, a naphthyl group or the like.

The alkyl group, cycloalkyl group and aryl group mentioned above may have a substituent. As the substituent, there can be mentioned, for example, a nitro group, a halogen atom (e.g., a fluorine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) or the like. The aryl group or ring structure of these groups may further have an alkyl group (preferably having 1 to 15 carbon atoms) as its substituent.

As a preferred aralkyl group of the aralkyl carboxylate anion, there can be mentioned an aralkyl group having 7 to 12 carbon atoms, for example, a benzyl group, a phenethyl group, a naphthylmethyl group, a naphthylethyl group, a naphthylbutyl group or the like.

As the sulfonylimido anion, there can be mentioned, for example, a saccharin anion.

The alkyl group of the bis(alkylsulfonyl)imido anion and tris(alkylsulfonyl)methide anion is preferably an alkyl group having 1 to 5 carbon atoms.

In the bis(alkylsulfonyl)imide anion, two alkyl groups may be connected to each other to thereby form an alkylene group (preferably 2 to 4 carbon atoms), which may form a ring in cooperation with the imide group and two sulfonyl groups.

As substituents that can be introduced in the above alkyl group and the alkylene group formed by the mutual connection of two alkyl groups in the bis(alkylsulfonyl)imide anion, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group and the like. A fluorine atom and an alkyl group substituted with a fluorine atom are preferred.

As the other nonnucleophilic anions, there can be mentioned, for example, phosphorus fluoride (for example, PF₆⁻), boron fluoride (for example, BF₄⁻), antimony fluoride (for example, SbF₆⁻) and the like.

The nonnucleophilic anion represented by Z⁻ is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion (still more preferably having 4 to 8 carbon atoms) or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

From the viewpoint of acid strength, it is preferred for the pKa value of generated acid to be −1 or less so as to ensure a sensitivity enhancement.

As more preferred (ZI′) components, there can be mentioned the following compounds (ZI′-1).

The compounds (ZI′-1) are arylsulfonium compounds of general formula (ZI′) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. While it is also appropriate that the R₂₀₁ to R₂₀₃ are partially an aryl group and the remainder is an alkyl group or a cycloalkyl group, it is more preferred for all of the R₂₀₁ to R₂₀₃ to be aryl groups.

As the arylsulfonium compounds, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, there can be mentioned, for example, a pyrrole residue, a furan residue, a thiophene residue, an indole residue, a benzofuran residue, a benzothiophene residue or the like. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

The aryl group, alkyl group or cycloalkyl group represented by R₂₀₁ to R₂₀₃ may have as its substituent an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be contained in any one of the three R₂₀₁ to R₂₀₃, or alternatively may be contained in all three of R₂₀₁ to R₂₀₃. When R₂₀₁ to R₂₀₃ represent an aryl group, the substituent preferably lies at the p-position of the aryl group.

Now, general formulae (ZII′) and (ZIII′) will be described.

In general formulae (ZII′) and (ZIII′),

each of R₂₀₄ to R₂₀₇ independently represents an aryl group, an alkyl group or a cycloalkyl group.

The examples of the aryl group, alkyl group and cycloalkyl group represented by R₂₀₄ to R₂₀₇ are the same as mentioned with respect to general formula (ZI′-1) above.

The aryl group, alkyl group and cycloalkyl group represented by R₂₀₄ to R₂₀₇ may have a substituent. As a possible substituent on the aryl group, alkyl group and cycloalkyl group, there can also be mentioned the same as in general formula (ZI′-1) above.

Z⁻ represents a nonnucleophilic anion. As such, there can be mentioned the same nonnucleophilic anions as mentioned with respect to the Z⁻ of general formula (ZI′).

As the acid generator (A′) which may be used in combination with the acid generator of the present invention, there can be further mentioned the compounds of formulae (ZIV′), (ZV′) and (ZVI′) below.

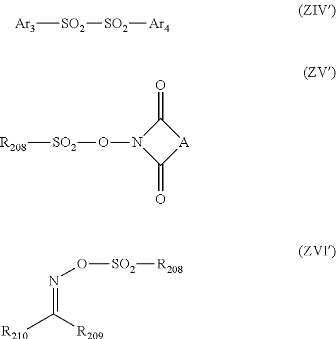

In general formulae (ZIV′) to (ZVI′),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Particular examples of the aryl groups represented by Ar₃, Ar₄, R₂₀₈, R₂₀₉ and R₂₁₀ are the same as those of the aryl groups represented by R₂₀₁, R₂₀₂, and R₂₀₃ of general formula (ZI′-1) mentioned above.

Particular examples of the alkyl groups and the cycloalkyl groups represented by R₂₀₈, R₂₀₉ and R₂₁₀ are the same as those of the alkyl groups and the cycloalkyl groups represented by R₂₀₁, R₂₀₂, and R₂₀₃ of general formula (ZI′-1) mentioned above.

As the alkylene group represented by A, there can be mentioned an alkylene group having 1 to 12 carbon atoms (for example, a methylene group, an ethylene group, a propylene group, an isopropylene group, a butylene group or an isobutylene group). As the alkenylene group represented by A, there can be mentioned an alkenylene group having 2 to 12 carbon atoms (for example, an ethynylene group, a propenylene group or a butenylene group). As the arylene group represented by A, there can be mentioned an arylene group having 6 to 10 carbon atoms (for example, a phenylene group, a tolylene group or a naphthylene group).

Especially preferred examples of the acid generators which may be used in combination with the acid generator of the present invention are as follows.

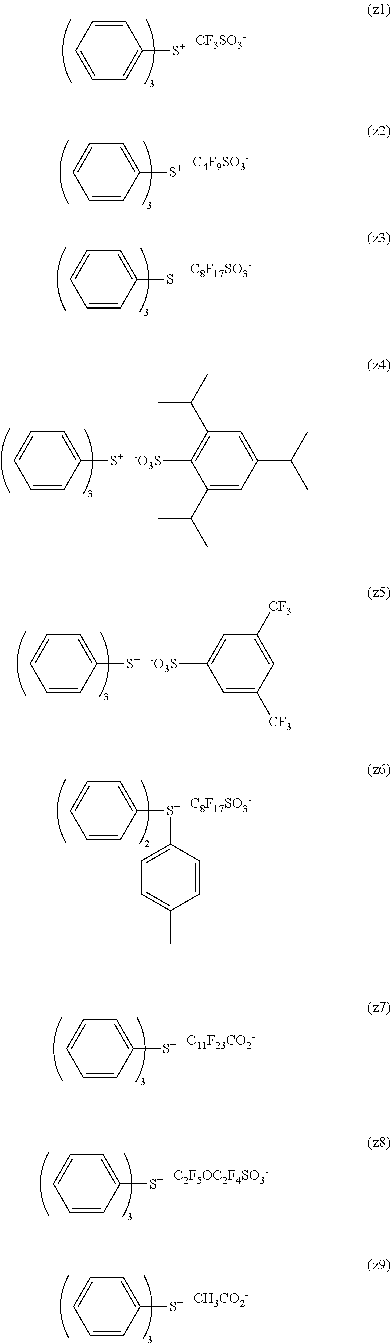

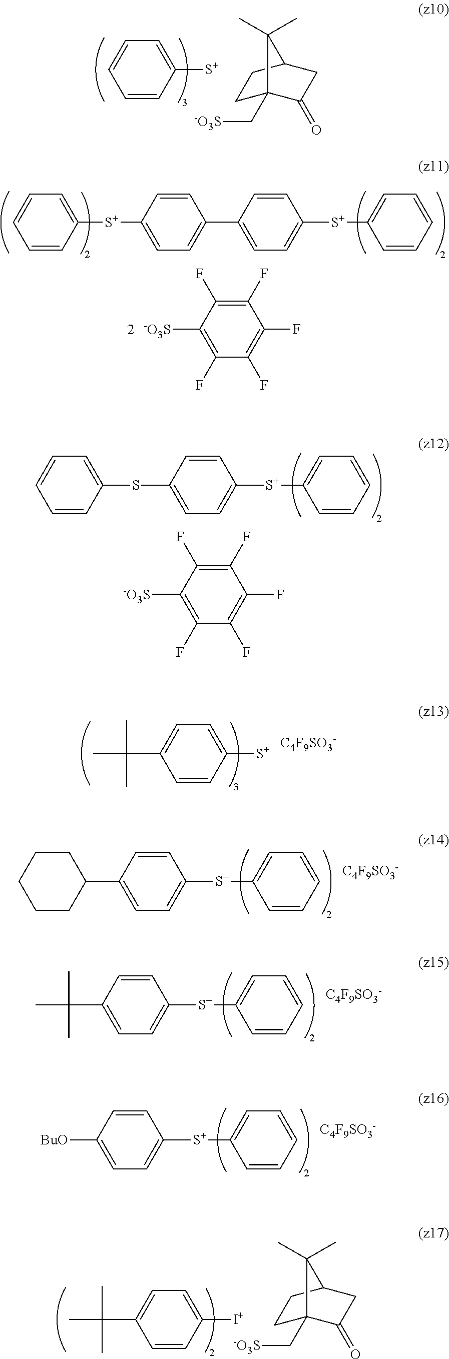

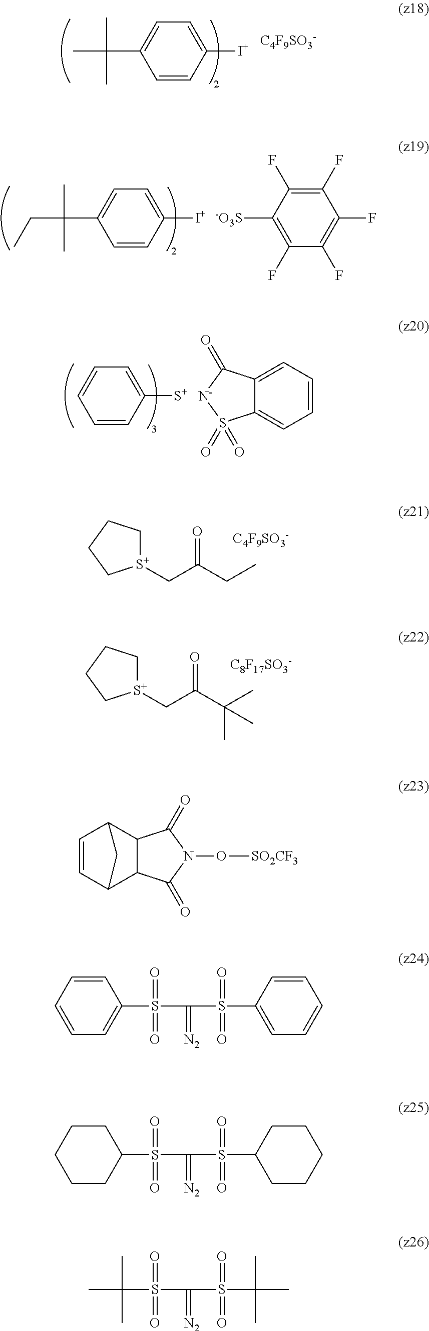

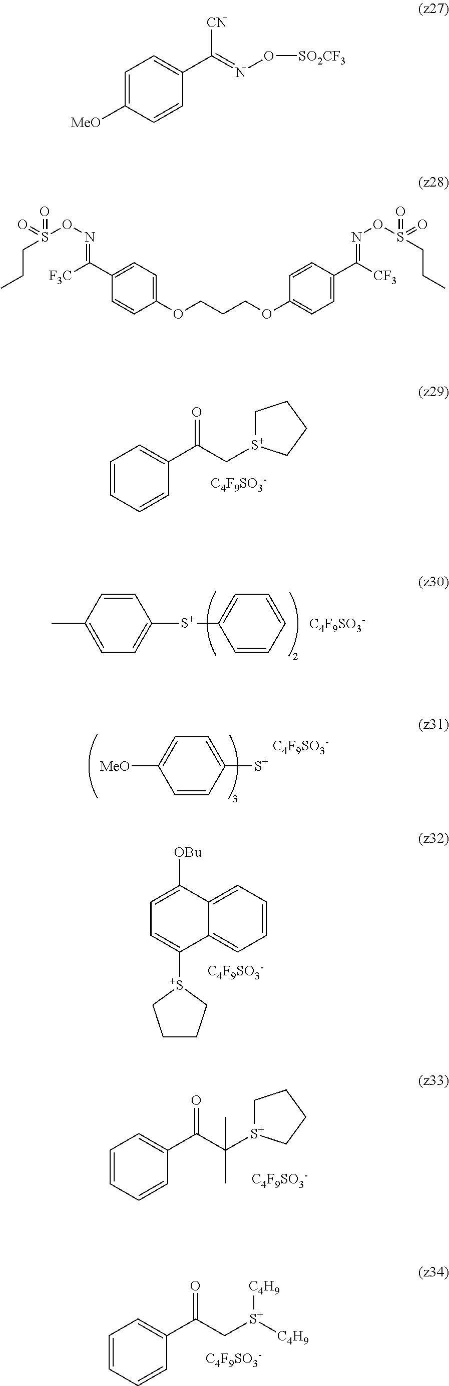

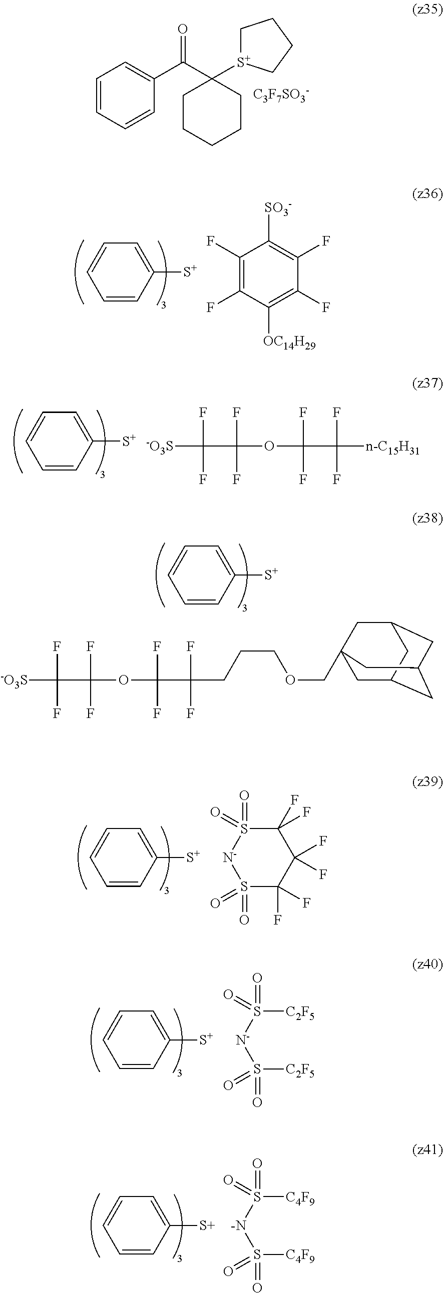

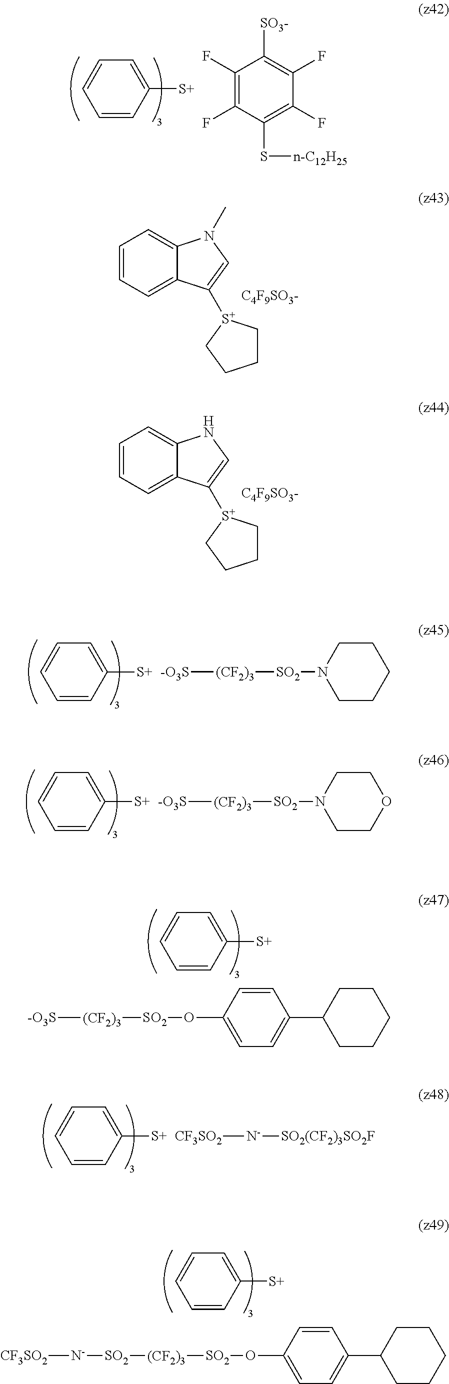

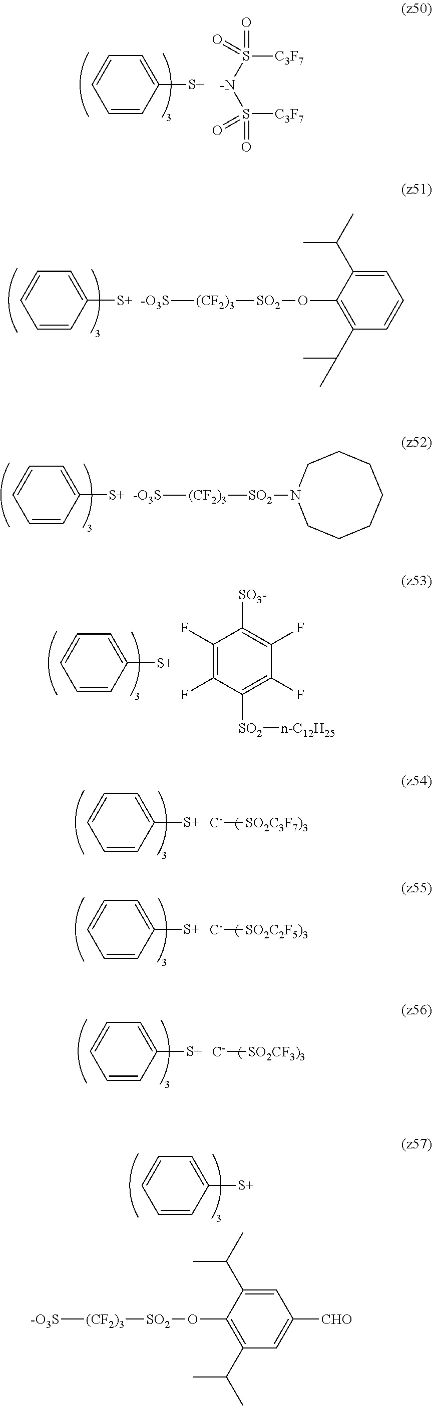

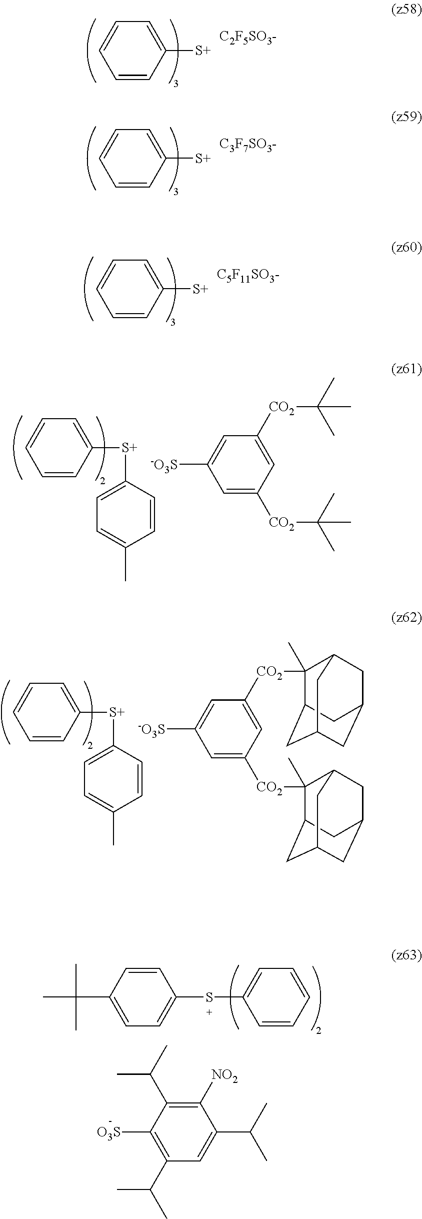

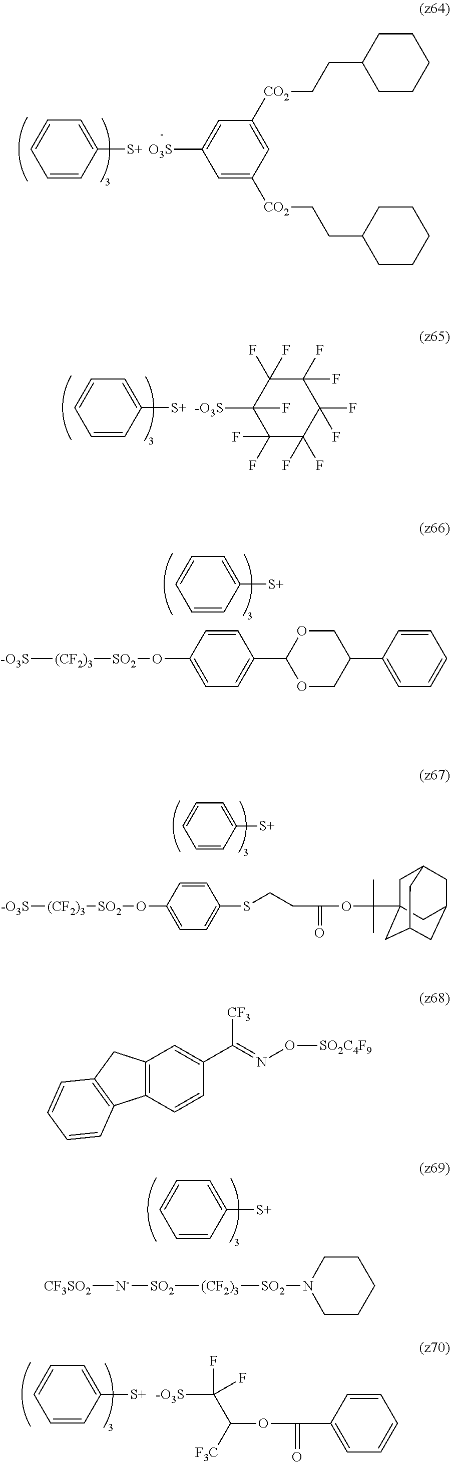

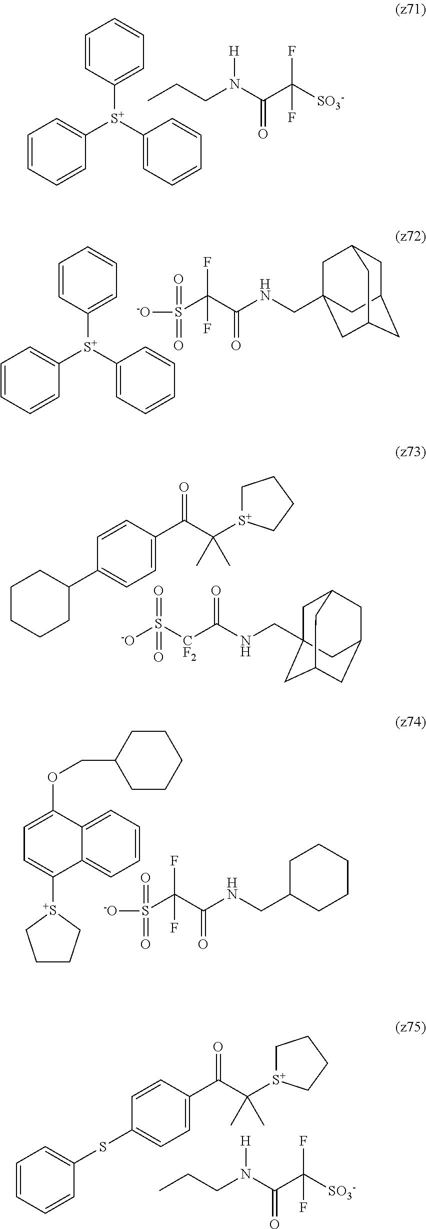

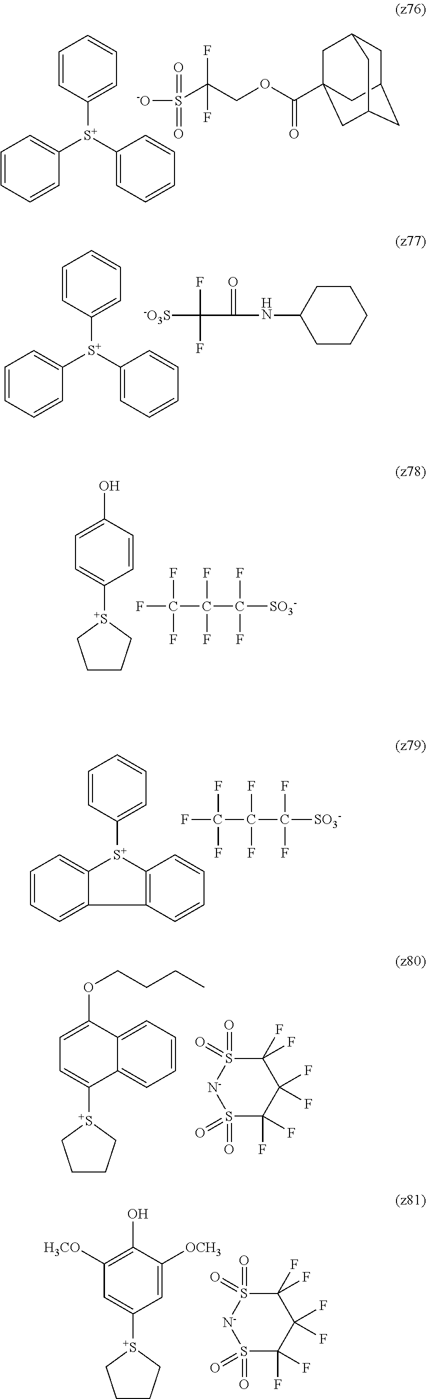

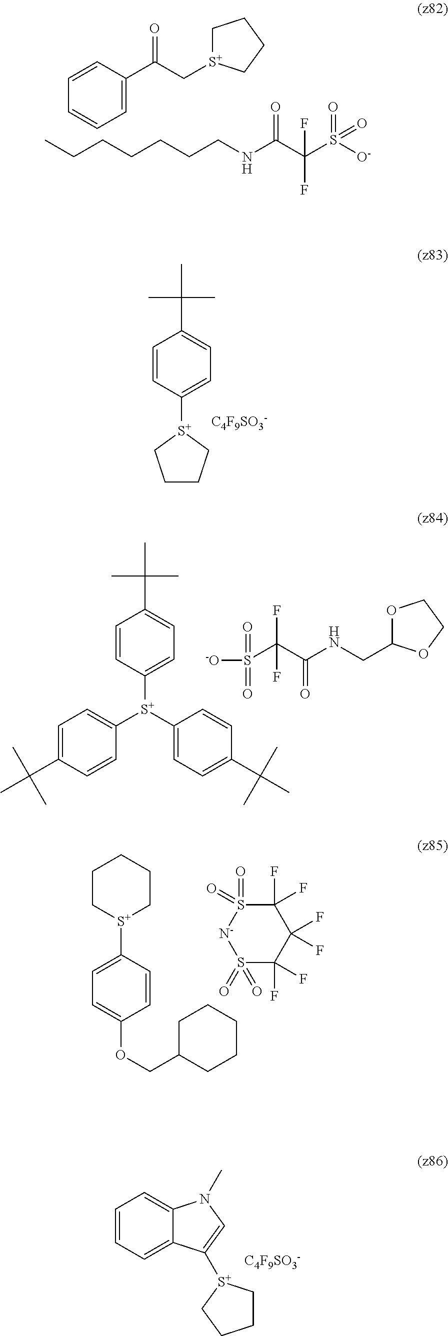

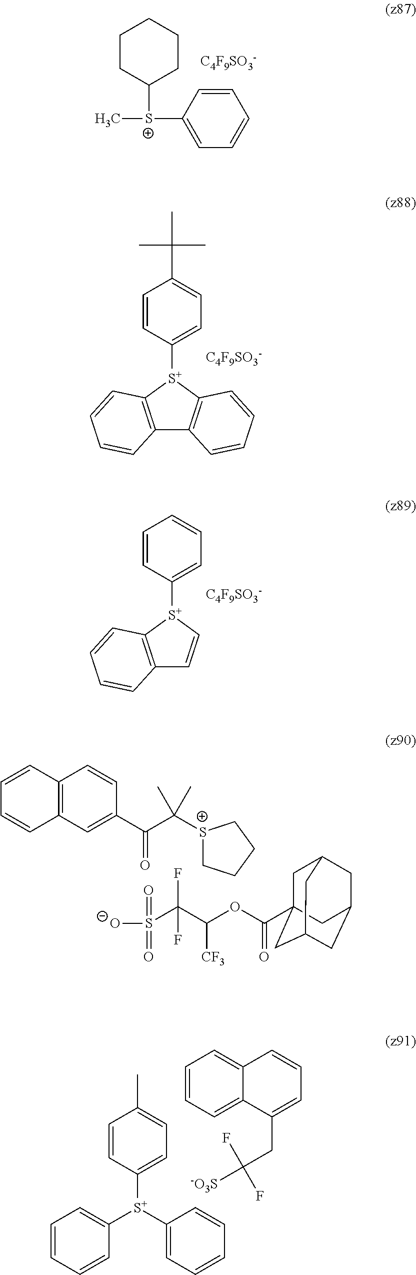

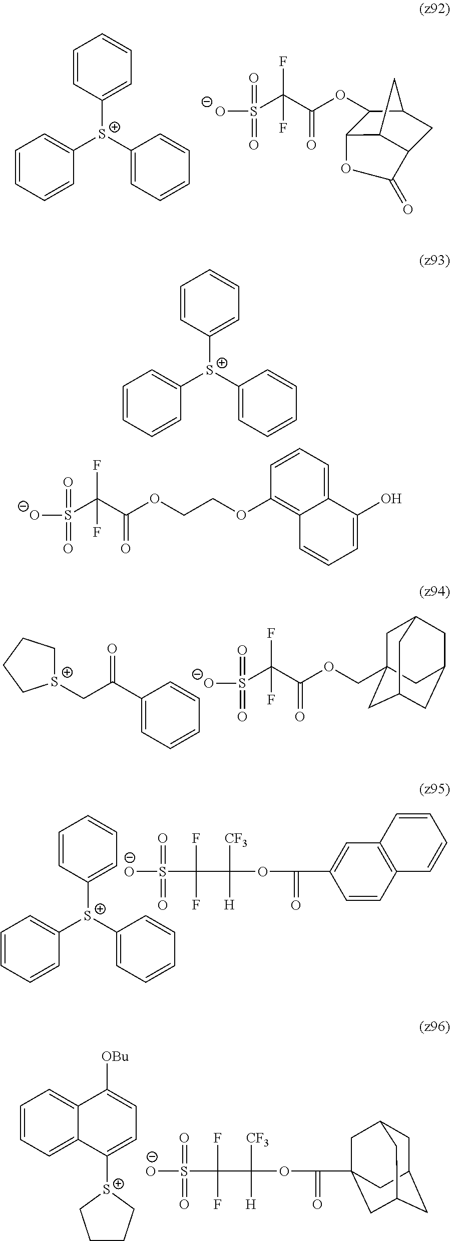

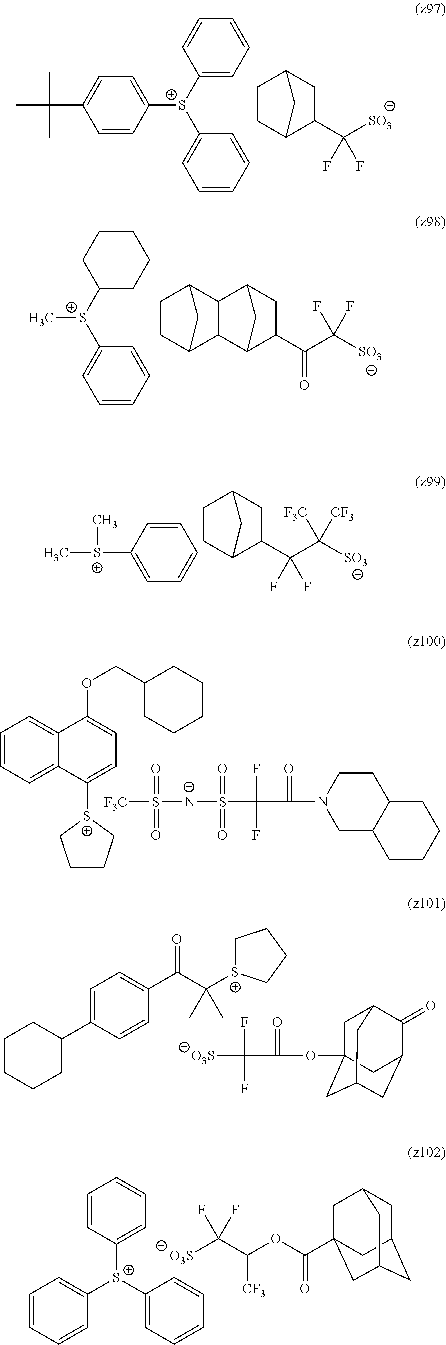

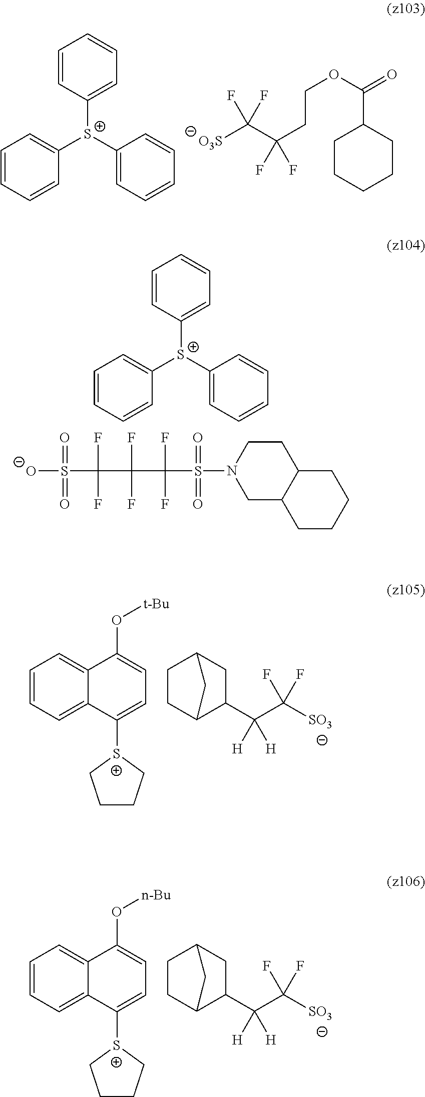

When the compound (A) is used in combination with the compound (A′), the mass ratio of used acid generators (compound (A)/compound (A′)) is preferably in the range of 99/1 to 20/80, more preferably 99/1 to 40/60 and further more preferably 99/1 to 50/50.

[2] Resin that when Acted on by an Acid, is Decomposed to Thereby Increase its Solubility in an Alkali Developer

The actinic-ray- or radiation-sensitive resin composition of the present invention comprises a resin that when acted on by an acid, is decomposed to thereby increase its solubility in an alkali developer (hereinafter also referred to as an “acid-decomposable resin” or “resin (B)”).

In the acid-decomposable resin, a group that is decomposed by the action of an acid to thereby produce an alkali-soluble group (hereinafter also referred to as “acid-decomposable group”) is introduced in the principal chain or side chain, or both the principal chain and the side chain, of the resin.

The resin (A) is preferably insoluble or hardly soluble in an alkali developer.

The acid-decomposable group preferably has a structure in which an alkali-soluble group is protected by a group removable by degradation upon the action of acid.

As the alkali-soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a carboxyl group, a fluoroalcohol group (preferably hexafluoroisopropanol) and a sulfonate group.

The acid-decomposable group is preferably a group as obtained by substituting the hydrogen atom of any of these alkali-soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded to each other to thereby form a ring structure.

Each of R₀₁ to R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit with an acid-decomposable group is preferably any of those of the following general formula (AI).

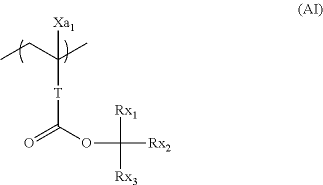

In general formula (AI),

Xa₁ represents a hydrogen atom, an optionally substituted methyl group, or a group represented by —CH₂—R₁₁. R₁₁ represents a hydroxyl group or a monovalent organic group. R₁₁ preferably represents an alkyl or an acyl group having 5 or less carbon atoms, more preferably an alkyl group having 3 or less carbon atoms, and further more preferably a methyl group. Xa₁ preferably represents a hydrogen atom, a methyl group, a trifluoromethyl group or a hydroxymethyl group.

T represents a single bond or a bivalent connecting group.

Each of Rx₁ to Rx₃ independently represents a linear or branched alkyl group or a mono- or polycyclic cycloalkyl group.

At least two of Rx₁ to Rx₃ may be bonded to each other to thereby form a monocyclic or polycyclic cycloalkyl group.

As the bivalent connecting group represented by T, there can be mentioned, for example, an alkylene group, a group of the formula —(COO—Rt)- or a group of the formula —(O—Rt)—. In the formulae, Rt represents an alkylene group or a cycloalkylene group.

T is preferably a single bond or a group of the formula —(COO—Rt)—. Rt is preferably an alkylene group having 1 to 5 carbon atoms, more preferably a —CH₂— group, —(CH₂)₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a monocyclic cycloalkyl group, such as a cyclopentyl group or a cyclohexyl group, or a polycyclic cycloalkyl group, such as a norbornyl group, a tetracyclodecanyl group, a tetracyclododecanyl group or an adamantyl group.

The cycloalkyl group formed by at least two of Rx₁ to Rx₃ is preferably a monocyclic cycloalkyl group, such as a cyclopentyl group or a cyclohexyl group, or a polycyclic cycloalkyl group, such as a norbornyl group, a tetracyclodecanyl group, a tetracyclododecanyl group or an adamantyl group. Monocyclic cycloalkyl groups having 5 or 6 carbon atoms are especially preferred.

One of the methylene groups constructing the ring of the above cycloalkyl group formed by the mutual bonding of two of Rx₁ to Rx₃ may be replaced by an oxygen atom.

In an especially preferred mode, Rx₁ is a methyl group or an ethyl group, and Rx₂ and Rx₃ are bonded to each other to thereby form any of the above-mentioned cycloalkyl groups.

One or more substituents may further be introduced in each of the groups above. As the substituents, there can be mentioned, for example, an alkyl group (preferably having 1 to 4 carbon atoms), a halogen atom, a hydroxy group, an alkoxy group (preferably having 1 to 4 carbon atoms), a carboxyl group, an alkoxycarbonyl group (preferably having 2 to 6 carbon atoms). Preferably, each of the substituents has 8 or less carbon atoms.

The content of the repeating unit containing a acid-decomposable group based on all the repeating units of the resin is preferably in the range of 20 to 70 mol %, and more preferably 30 to 60 mol %.

Preferred examples of the repeating unit containing a acid-decomposable group will be shown below, which however in no way limit the scope of the present invention.

In the specific examples, Rx and Xa1 each represents a hydrogen atom, CH₃, CF₃, or CH₂OH. Each of Rxa and Rxb represents an alkyl group having 1 to 4 carbon atoms. Z or each of Zs independently represents a substituent containing a polar group. P represents 0 or positive integer. Particular examples and preferred examples of the substituents Z are the same as those of the groups R₁₀ of general formula (II-1) to be described hereinafter.

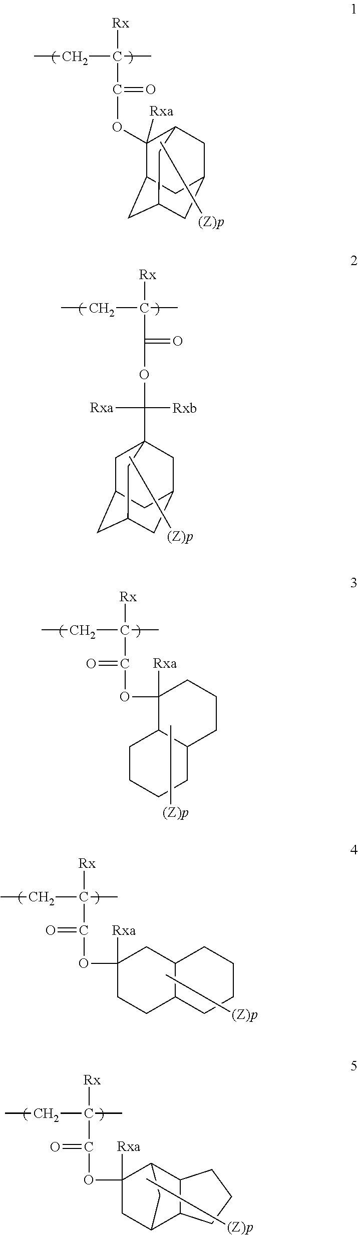

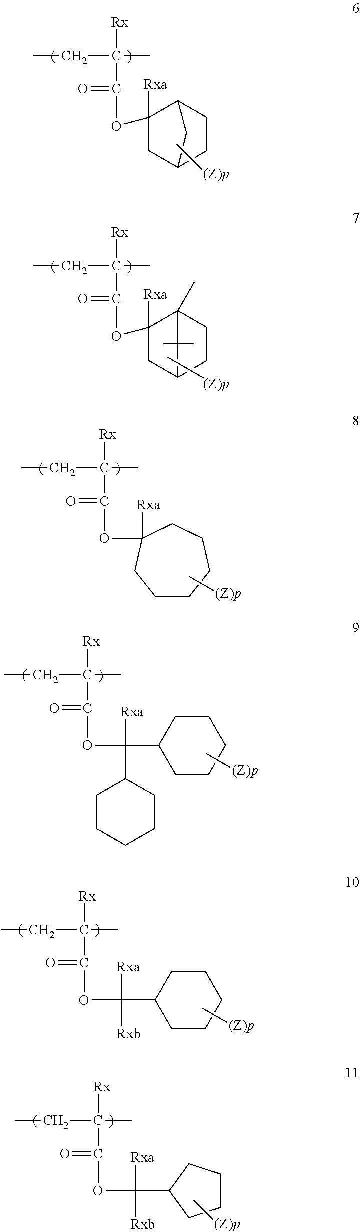

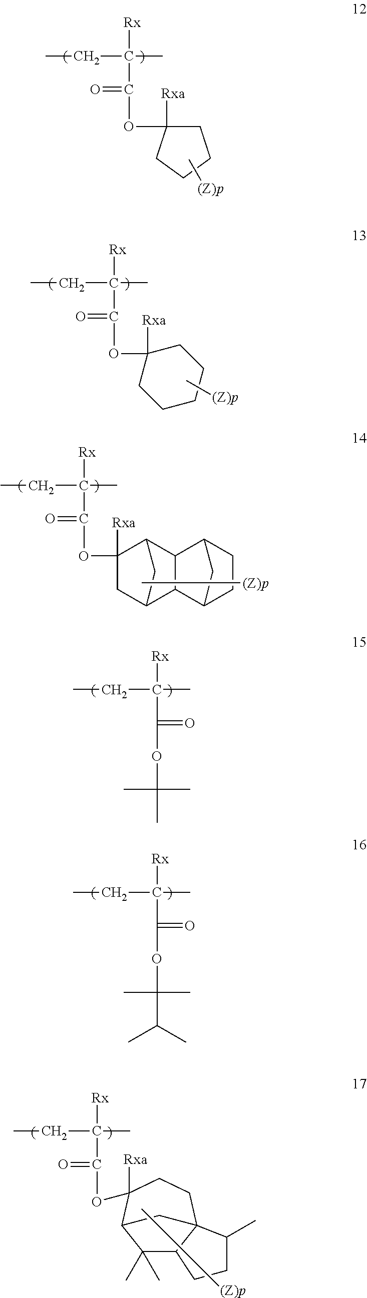

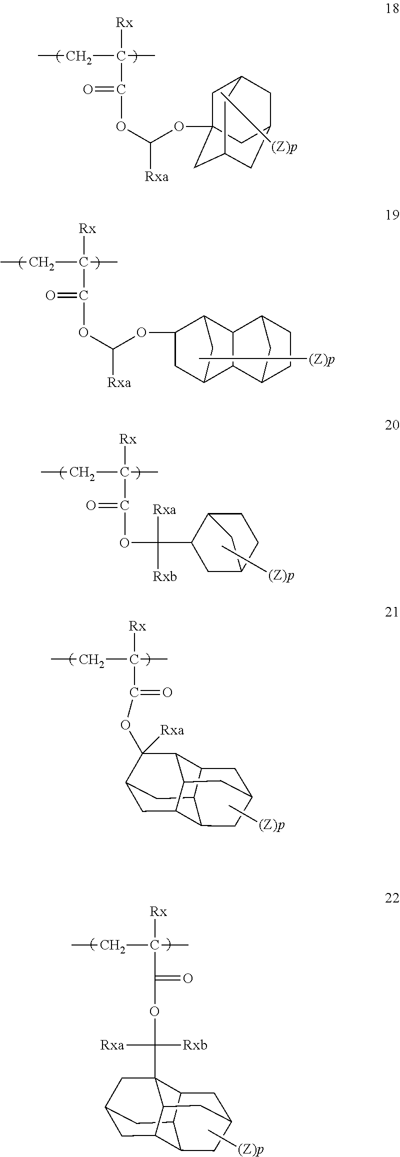

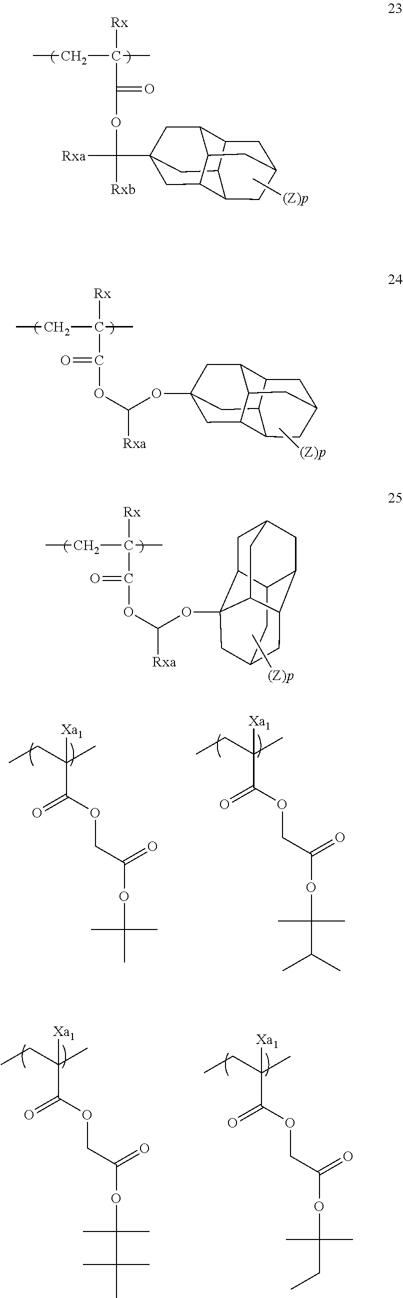

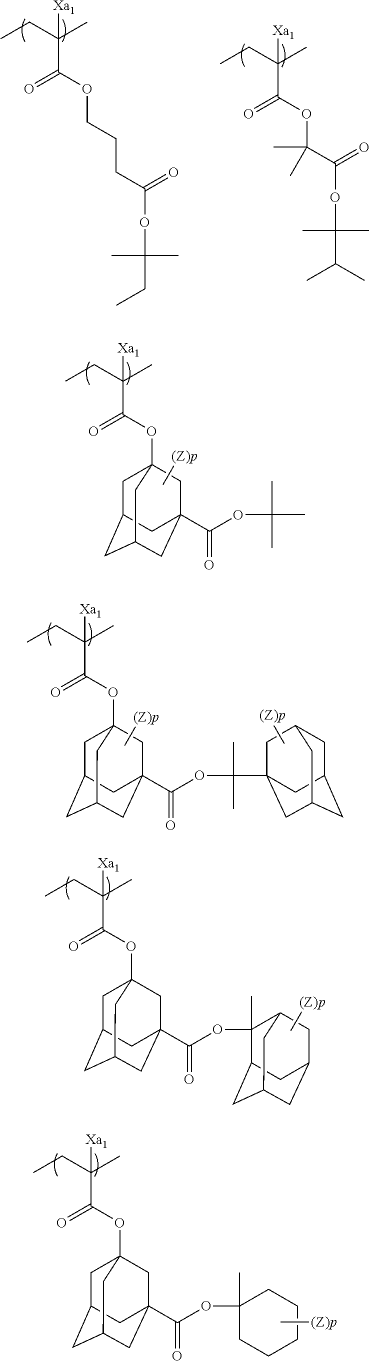

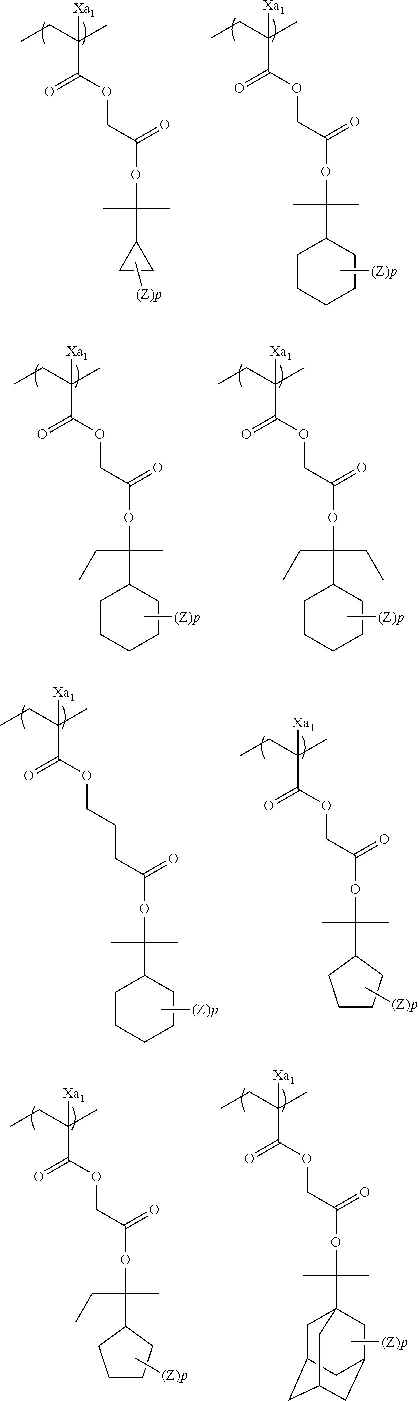

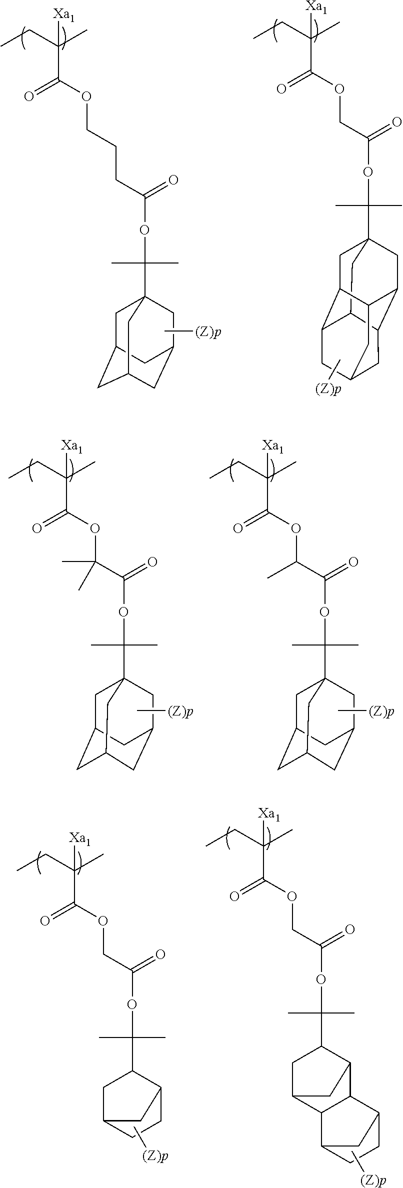

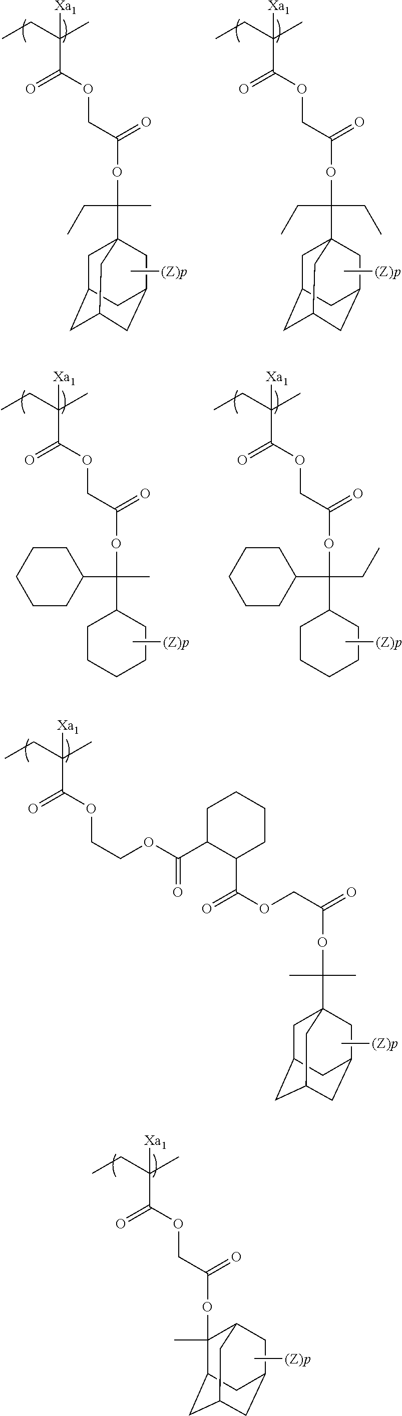

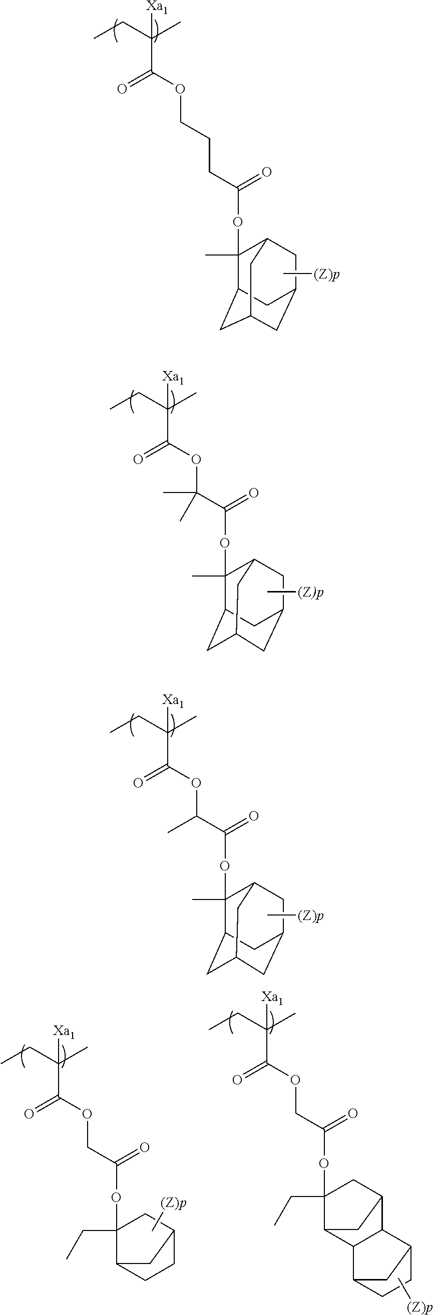

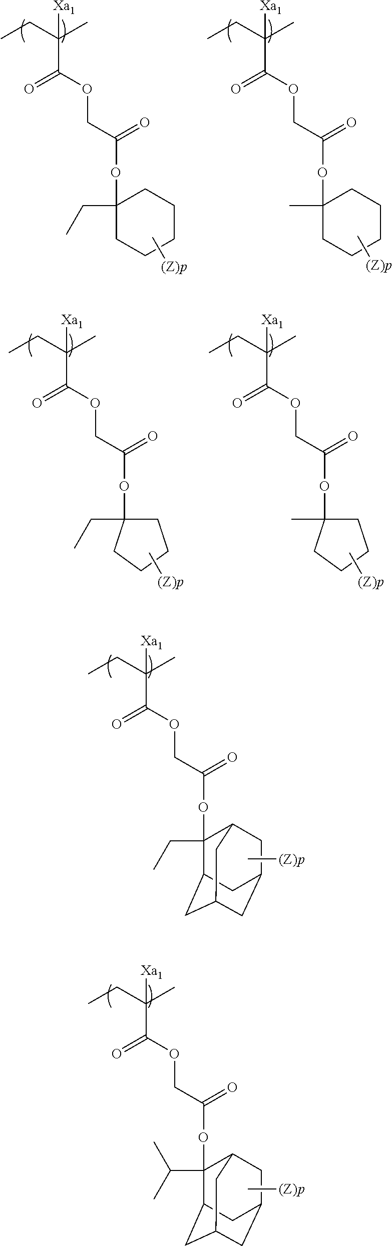

It is more preferred for the resin (B) to contain, as the repeating units of general formula (AI), any of the repeating units of general formula (I) below and/or any of the repeating units of general formula (II) below.

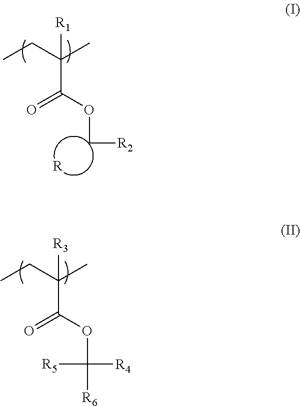

In formulae (I) and (II),

each of R₁ and R₃ independently represents a hydrogen atom, an optionally substituted methyl group or any of the groups of the formula —CH₂—R₁₁. R₁₁ represents a monovalent organic group.

Each of R₂, R₄, R₅ and R₆ independently represents an alkyl group or a cycloalkyl group.

R represents an atomic group required for forming an alicyclic structure in cooperation with a carbon atom.

R₁ and R₃ preferably represent a hydrogen atom, a methyl group, a trifluoromethyl group or a hydroxymethyl group. Particular examples and preferred examples of the monovalent organic group R₁₁ are the same as those of the groups R₁₁ of general formula (AI) as described above.

The alkyl group represented by R₂ may be linear or branched, and one or more substituents may be introduced therein.

The cycloalkyl group represented by R2 may be monocyclic or polycyclic, and a substituent may be introduced therein.

R₂ preferably represents an alkyl group, more preferably an alkyl group having 1 to 10 carbon atoms, further more preferably 1 to 5 carbon atoms. As examples thereof, there can be mentioned a methyl group and an ethyl group.

R represents an atomic group required for forming an alicyclic structure in cooperation with a carbon atom. The alicyclic structure formed by R in cooperation with the carbon atom is preferably an alicyclic structure of a single ring, and preferably has 3 to 7 carbon atoms, more preferably 5 or 6 carbon atoms.

R₃ preferably represents a hydrogen atom or a methyl group, more preferably a methyl group.

Each of the alkyl groups represented by R₄, R₅ and R₆ may be linear or branched, and one or more substituents may be introduced therein. The alkyl groups are preferably those each having 1 to 4 carbon atoms, such as a methyl group, an ethyl group, an n-propyl group, an isopropyl group, an n-butyl group, an isobutyl group and a t-butyl group.

Each of the cycloalkyl groups represented by R₄, R₅ and R₆ may be monocyclic or polycyclic, and a substituent may be introduced therein. The cycloalkyl groups are preferably a monocyclic cycloalkyl group, such as a cyclopentyl group or a cyclohexyl group, and a polycyclic cycloalkyl group, such as a norbornyl group, a tetracyclodecanyl group, a tetracyclododecanyl group or an adamantyl group.

It is preferred for the repeating units of general formula (I) to be those of general formula (AIII) below.

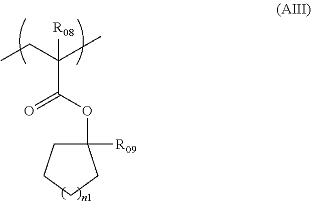

In the general formula,

each of R₀₈ and R₀₉ independently represents an alkyl group, and n1 is an integer of 1 to 6. This alkyl group is preferably one having 1 to 10 carbon atoms, in which a substituent may be introduced.

In the general formula, n1 is preferably an integer of 1 to 3, more preferably 1 or 2.

One of the methylene groups constructing the ring of the cycloalkyl group in general formula (AIII) above may be replaced by an oxygen atom.

As substituents introducible in these groups, there can be mentioned those set forth above as being introducible in the groups in general formula (AI).

The repeating units of general formula (II) are preferably those of general formula (II-1) below.

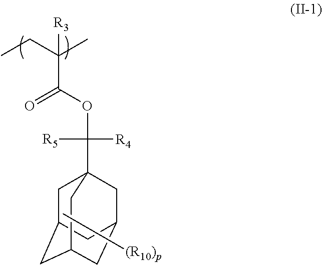

In general formula (II-1),

R₃ to R₅ have the same meaning as in general formula (II).

R₁₀ represents a substituent containing a polar group. As the substituent containing a polar group, there can be mentioned, for example, a hydroxyl group, a cyano group, an amino group, an alkylamido group or a sulfonamido group per se, or, containing at least one of these, a linear or branched alkyl group or cycloalkyl group. An alkyl group containing a hydroxyl group is preferred. A branched alkyl group containing a hydroxyl group is more preferred. An isopropyl group is especially preferred as the branched alkyl group.

In the formula, p is an integer of 0 to 15, preferably in the range of 0 to 2, and more preferably 0 or 1.

It is more preferred for the acid-decomposable resin to be a resin containing, as the repeating units of general formula (AI), any of the repeating units of general formula (I) and any of the repeating units of general formula (II). In another form, it is more preferred for the acid-decomposable resin to be a resin containing, as the repeating units of general formula (AI), at least two types selected from among the repeating units of general formula (I).

In the resin (B), the repeating unit with an acid-decomposable group may be contained alone, or two or more thereof may be contained in combination. When the resin (B) contains a plurality of acid-decomposable repeating units, the following combinations are preferred. In the following formulae, R each independently represents a hydrogen atom or a methyl group.

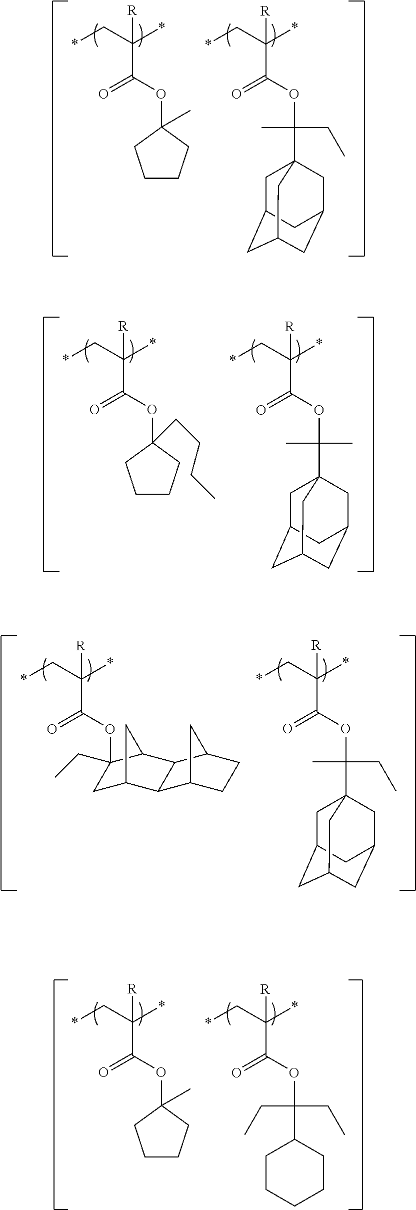

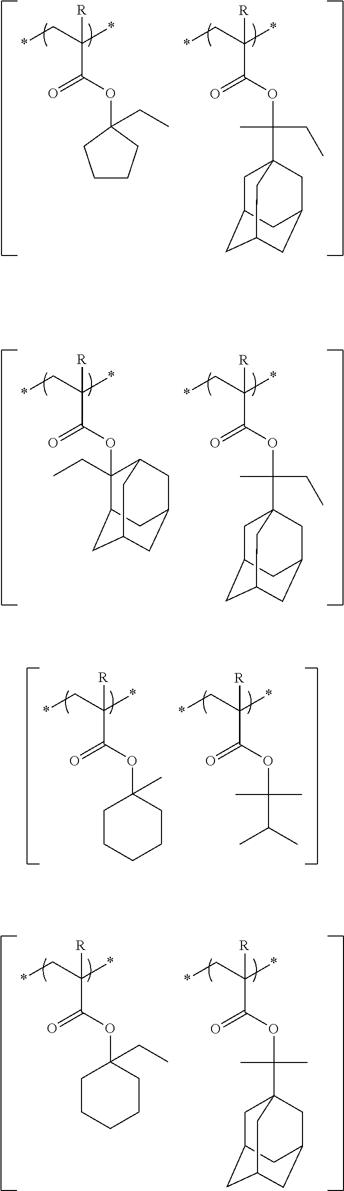

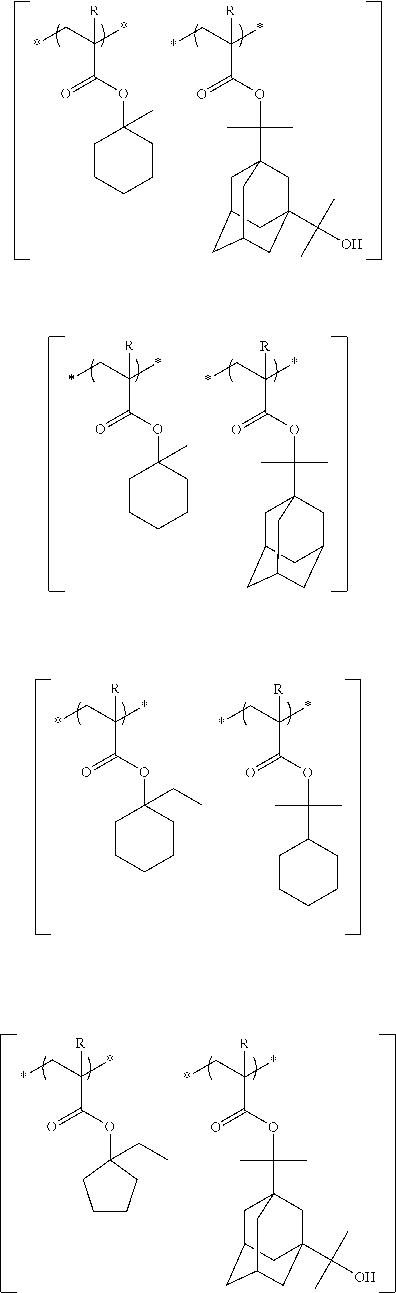

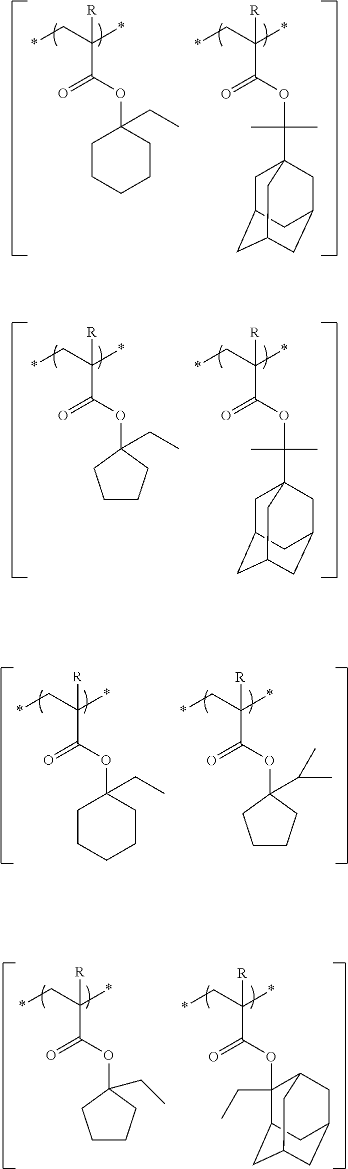

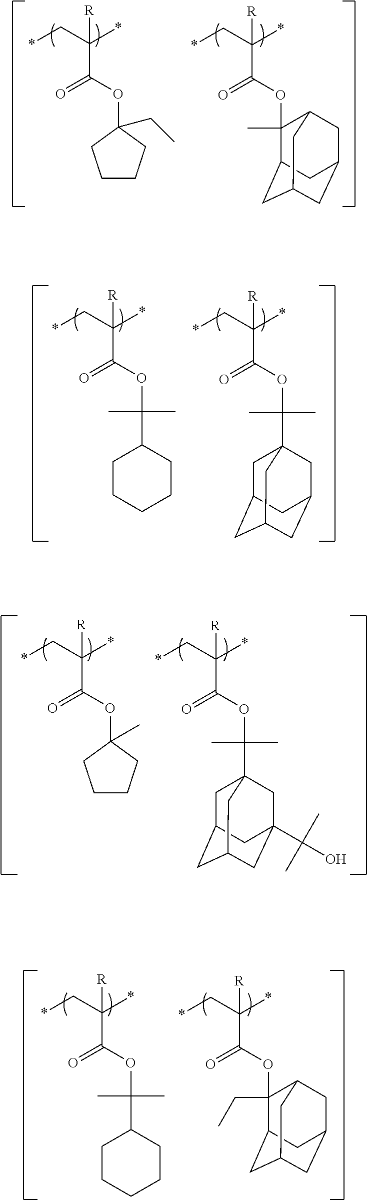

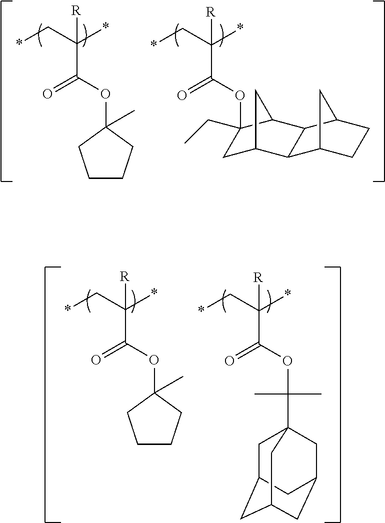

It is preferred for the resin (B) to contain a repeating unit with a lactone structure or a sultone (cyclosulfonic ester) structure.

Lactone and sultone groups are not particularly limited as long as lactone and sultone structures are contained respectively. A 5 to 7-membered ring lactone or sultone structure is preferred, and one resulting from the condensation of a 5 to 7-membered ring lactone or sultone structure with another cyclic structure effected in a fashion to form a bicyclo structure or spiro structure is also preferred. More preferably, the resin comprises a repeating unit with any of the lactone and sultone structures of general formulae (LC1-1) to (LC1-17) and (SL1-1) and (SL1-2) below. The lactone or sultone structure may be directly bonded to the principal chain of the resin. Preferred lactone and sultone structures are those of formulae (LC1-1), (LC1-4), (LC1-5) and (LC1-8). Lactone structure (LC1-4) is more preferred. Using these specified lactone and sultone structures enhances LWR and reduces development defects.

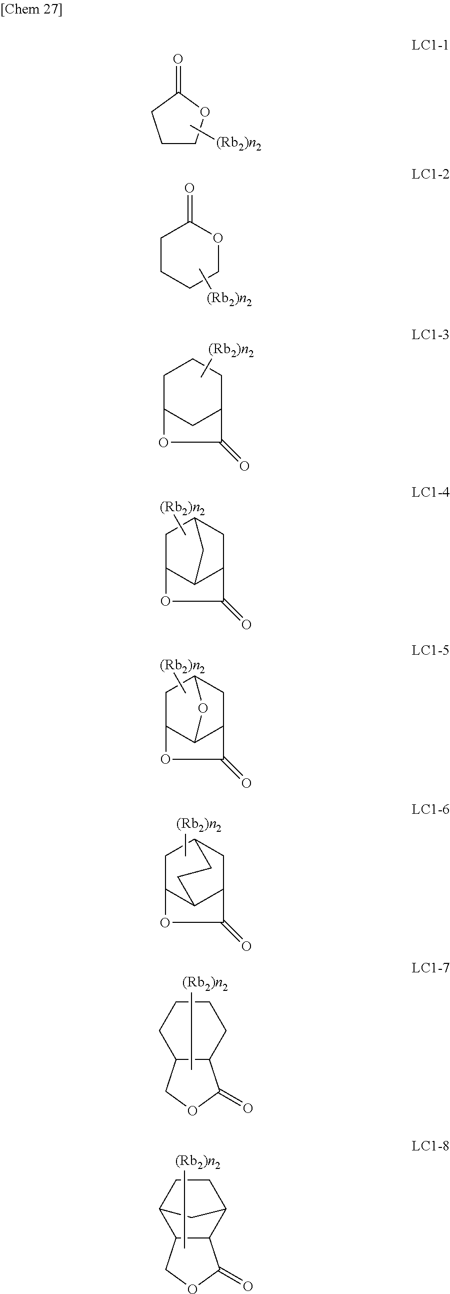

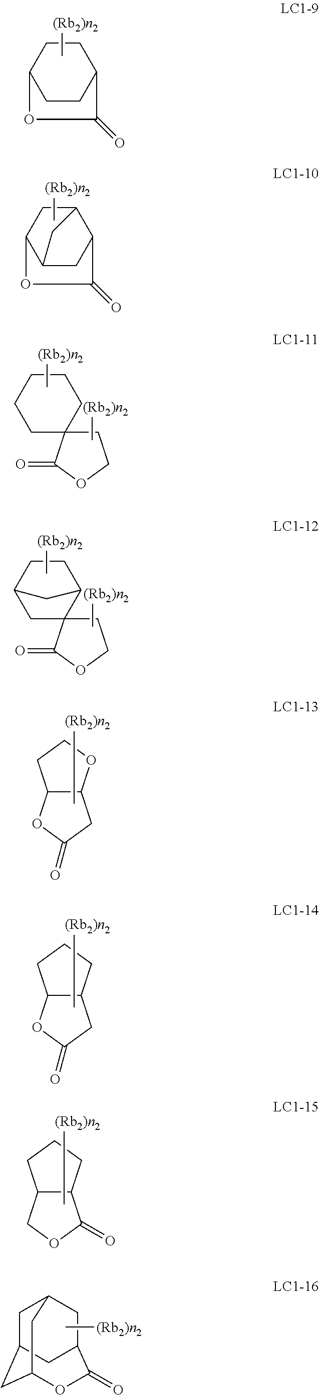

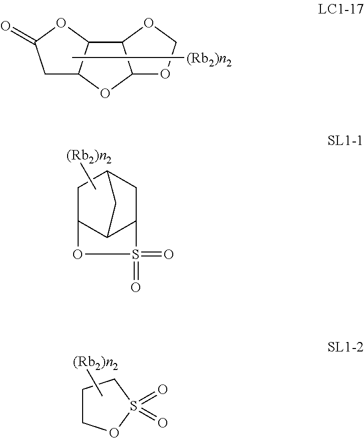

The presence of a substituent (Rb₂) on the portion of the lactone structure or a sultone structure is optional. As a preferred substituent (Rb₂), there can be mentioned an alkyl group having 2 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded to each other to thereby form a ring.

The resin (B) preferably contains a repeating unit having a lactone structure or a sultone structure represented by general formula (III) below.

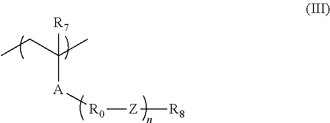

In formula (III),

A represents an ester bond (—COO—) or an amido bond (—CONH—).

Ro, each independently in the presence of two or more groups, represents an alkylene group, a cycloalkylene group or a combination thereof.

Z, each independently in the presence of two or more groups, represents a single bond, an ether bond, an ester bond, an amido bond, a urethane bond

(a group represented by

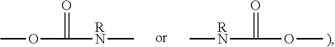

or a urea bond

(a group represented by

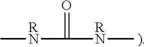

Each of R5 independently represents a hydrogen atom, an alkyl group, cycloalkyl group or an aryl group.

R₈ represents a monovalent organic group with a lactone structure or a sultone structure.

n represents the number of repetitions of the structure of the formula —R₀—Z— and is an integer of 0 to 2.

R₇ represents a hydrogen atom, a halogen atom or an alkyl group.

Each of the alkylene group and cycloalkylene group represented by R₀ may have a substituent.

Z preferably represents an ether bond or an ester bond, most preferably an ester bond.

The alkyl group represented by R₇ is preferably an alkyl group having 1 to 4 carbon atoms, more preferably a methyl group or an ethyl group and most preferably a methyl group. Each of the alkylene group and the cycloalkylene group represented by R₀ and the alkyl group represented by R₇ may be substituted. As substituents, there can be mentioned, for example, a halogen atom such as a fluorine atom, a chlorine atom or a bromine atom, a mercapto group, a hydroxyl group, an alkoxy group such as a methoxy group, an ethoxy group, an isopropoxy group, a t-butoxy group or a benzyloxy group, an acetoxy group such as an acetyloxy group or a propionyloxy and the like. R₇ is preferably a hydrogen atom, a methyl group, a trifluoromethyl group or a hydroxymethyl group.

The alkylene group represented by R₀ is preferably a chain alkylene group having 1 to 10 carbon atoms, more preferably 1 to 5 carbon atoms, for example, a methylene group, an ethylene group, a propylene group or the like. The cycloalkylene group is preferably a cycloalkylene group having 3 to 20 carbon atoms. As such, there can be mentioned, for example, cyclohexylene, cyclopentylene, norbornylene, adamantylene or the like. The chain alkylene groups are preferred from the viewpoint of the exertion of the effect of the present invention. A methylene group is most preferred.

The monovalent organic group with a lactone structure or a sultone structure represented by R₈ is not limited as long as the lactone structure or the sultone structure is contained. As particular examples thereof, there can be mentioned the lactone structures or the sultone structures of general formulae (LC1-1) to (LC1-17), (SL-1) and (SL-2) as described above. Of these, the structures of general formula (LC1-4) are most preferred. In general formulae (LC1-1) to (LC1-17), (SL-1) and (SL-2), n₂ is more preferably 2 or less.

R₈ preferably represents a monovalent organic group with an unsubstituted lactone structure or an unsubstituted sultone structure, or a monovalent organic group with a lactone structure or sultone structure substituted with a methyl group, a cyano group or an alkoxycarbonyl group. More preferably, R₈ represents a monovalent organic group having a lactone structure substituted with a cyano group (cyanolactone) or having a sultone structure substituted with a cyano group (cyanosultone).

Specific examples of the repeating units having a group with a lactone structure or a sultone structure represented by general formula (III) will be shown below, which however in no way limit the scope of the present invention.

In the specific examples, R represents a hydrogen atom, an optionally substituted alkyl group or a halogen atom. R is preferably a hydrogen atom, a methyl group, a hydroxymethyl group or an acetoxymethyl group.

In the specific examples, Me represents a methyl group.

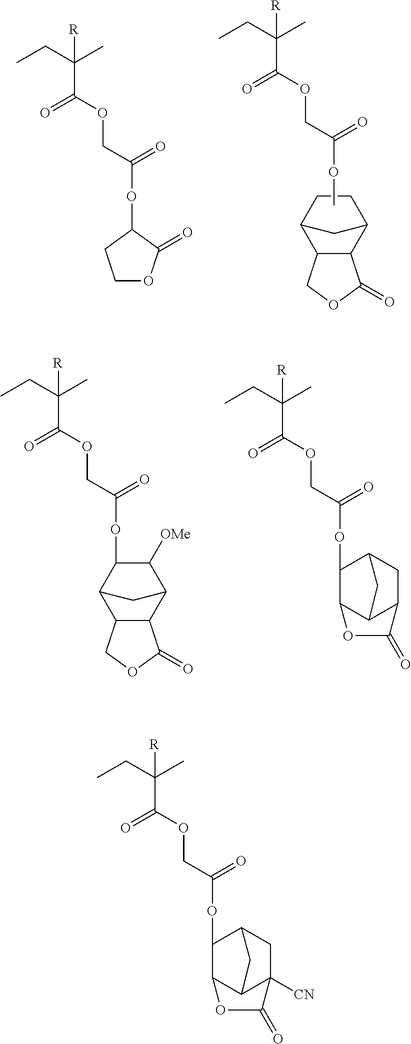

The repeating units having a lactone structure or a sultone structure are preferably those of general formula (III-1) or (III-1′) below.

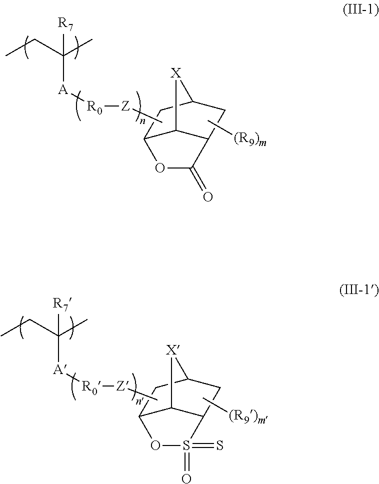

In general formulae (III-1) and (III-1′),

R₇, A, R₀, Z and n are as defined in general formula (III) above.

The meanings of R₇′, A′, R₀′, Z′ and n′ are respectively the same as those of R₇, A, R₀, Z and n in general formula (III) above.

R₉, when m≧2 each of Rb's independently, represents an alkyl group, a cycloalkyl group, an alkoxycarbonyl group, a cyano group, a hydroxyl group or an alkoxy group. When m≧2, two or more R₉'s may be bonded to each other to thereby form a ring.

R₉′, when m≧2 each of Rb's independently, represents an alkyl group, a cycloalkyl group, an alkoxycarbonyl group, a cyano group, a hydroxyl group or an alkoxy group. When m≧2, two or more R₉'s may be bonded to each other to thereby form a ring.

Each of X and X′ independently represents an alkylene group, an oxygen atom or a sulfur atom.

Each of m and m′ means the number of substituents, being independently an integer of 0 to 5, preferably 0 or 1.

The alkyl group represented by R₉ or R₉′ is preferably an alkyl group having 1 to 4 carbon atoms, more preferably a methyl group or an ethyl group, and most preferably a methyl group. As the cycloalkyl group, there can be mentioned, for example, a cyclopropyl group, a cyclobutyl group, a cyclopentyl group or a cyclohexyl group. As the alkoxycarbonyl group, there can be mentioned, for example, a methoxycarbonyl group, an ethoxycarbonyl group, an n-butoxycarbonyl group or a t-butoxycarbonyl group. As the alkoxy group, there can be mentioned, for example, a methoxy group, an ethoxy group, a propoxy group, isopropoxy group or a butoxy group. These groups may have one or more substituents. As such substituents, there can be mentioned, for example, a hydroxyl group; an alkoxy group such as a methoxy group or an ethoxy group; a cyano group; and a halogen atom such as a fluorine atom. More preferably, Each of R₉ and R₉′ is a methyl group, a cyano group or an alkoxycarbonyl group, further more preferably a cyano group.

As the alkylene group represented by X or X′, there can be mentioned, for example, a methylene group or an ethylene group. X or X′ is preferably an oxygen atom or a methylene group, more preferably a methylene group.

When m≧1 or m′≧1, it is preferred for the substitution with at least one R₉ or R₉′ to take place at the α- or β-position of the carbonyl group of the lactone. The substitution with R₉ at the α-position of the carbonyl group of the lactone is especially preferred.

Specific examples of the repeating units having a group with a lactone structure or a sultone structure represented by formula (III-1) or (III-1′) will be shown below, which however in no way limit the scope of the present invention. In the specific examples, R represents a hydrogen atom, an optionally substituted alkyl group or a halogen atom. R is preferably a hydrogen atom, a methyl group, a hydroxymethyl group or an acetoxymethyl group.

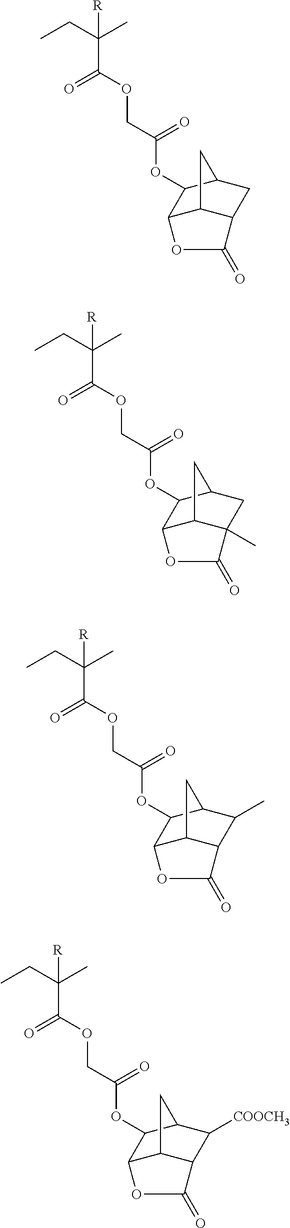

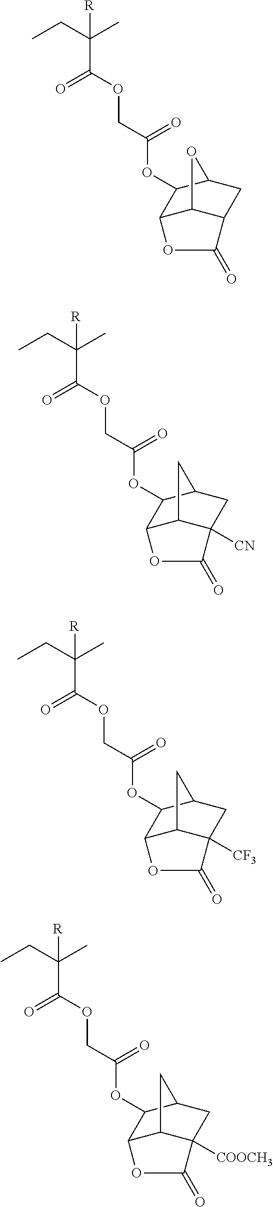

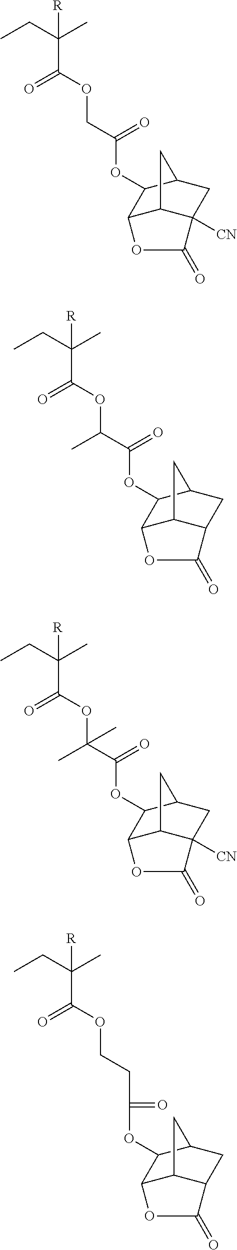

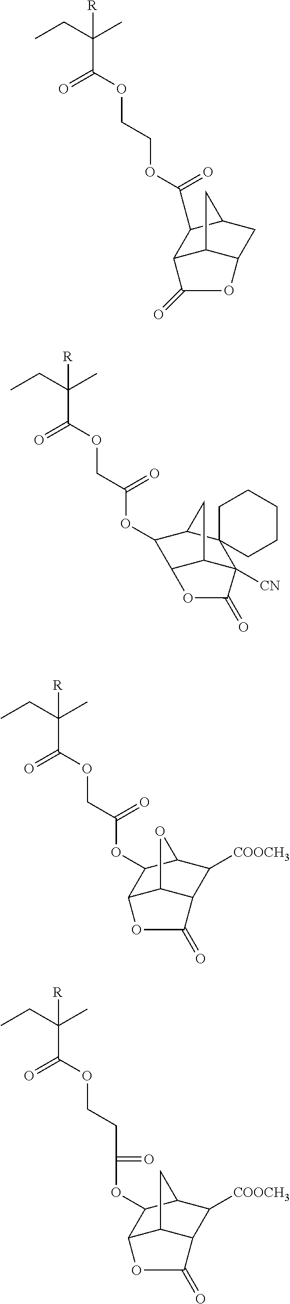

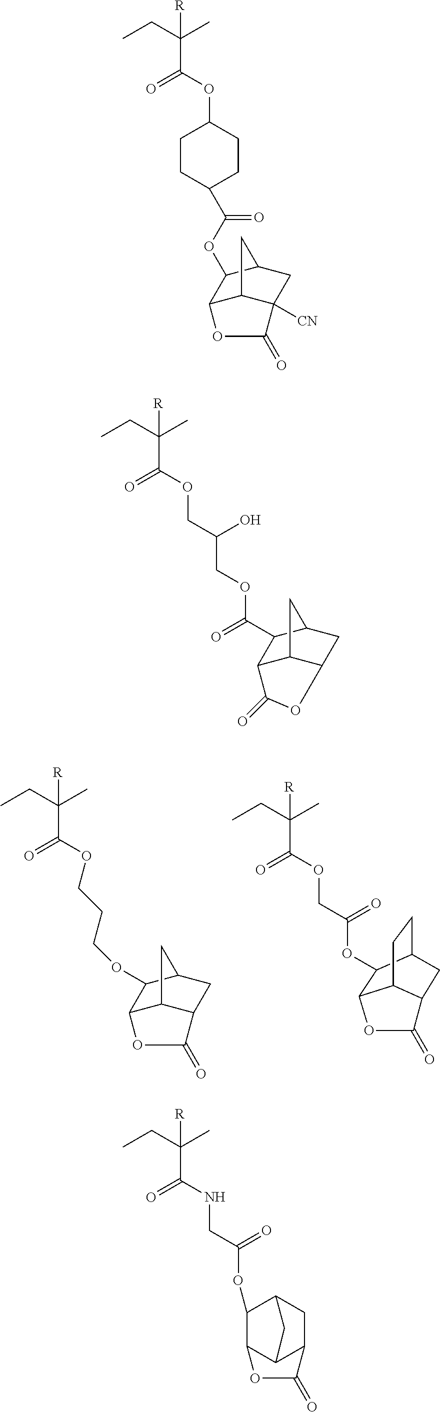

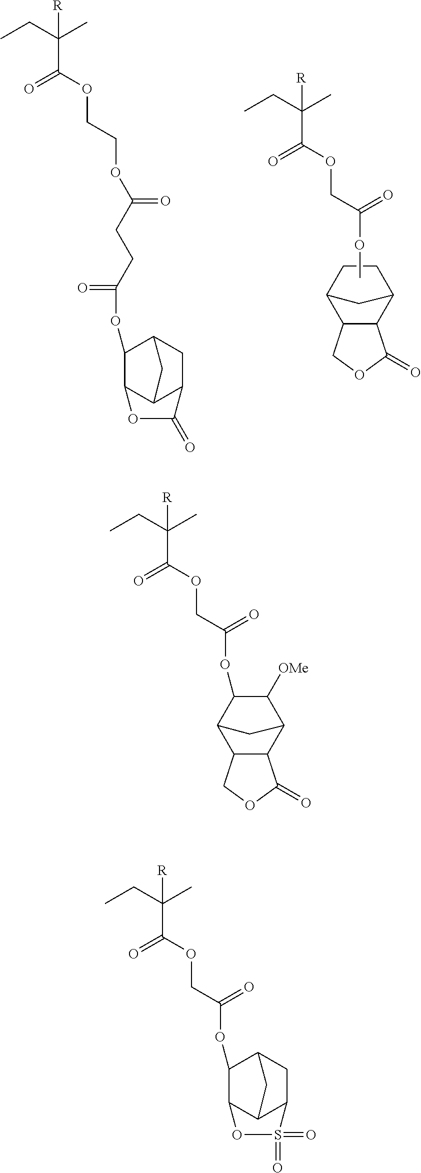

The content of any of the repeating units of general formula (III), the total content when two or more types thereof are contained, is preferably in the range of 15 to 60 mol %, more preferably 20 to 60 mol % and further more preferably 30 to 50 mol %, based on all the repeating units of the resin (B).

In one mode, the repeating units represented by general formula (III) may be those represented by general formula (AII′) below.

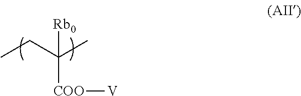

In general formula (AII′),

Rb₀ represents a hydrogen atom, a halogen atom or an alkyl group having 1 to 4 carbon atoms. As preferred substituents that may be introduced in the alkyl group represented by Rb₀, there can be mentioned a hydroxyl group and a halogen atom. As the halogen atom, there can be mentioned a fluorine atom, a chlorine atom, a bromine atom or an iodine atom. Preferably, Rb₀ represents a hydrogen atom, a methyl group, a hydroxymethyl group, or a trifluoromethyl group, and more preferably a hydrogen atom or a methyl group.

V represents a group with any of the structures of general formulae (LC1-1) to (LC1-17), (SL1-1) and (SL1-2).

The resin (B) may also contain a repeating unit with a lactone or sultone structure as mentioned above other than the units of general formula (III).

As particular examples of the repeating units each containing a lactone or sultone group, there can be mentioned not only those set forth hereinbefore but also the following repeating units, which in no way limit the scope of the present invention.

In the formulae, Rx is H, CH₃, CH₂OH or CF₃.

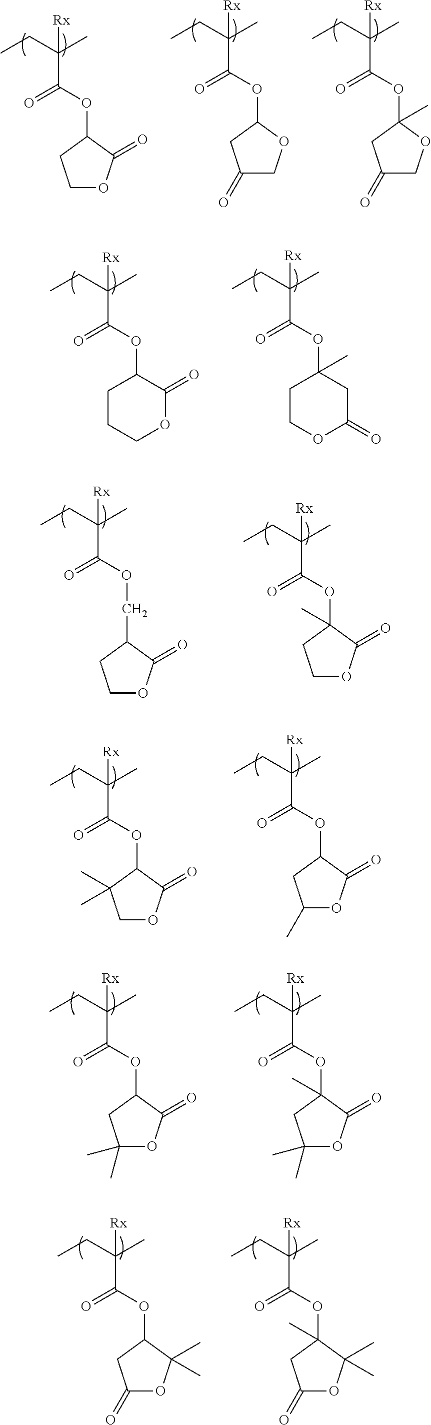

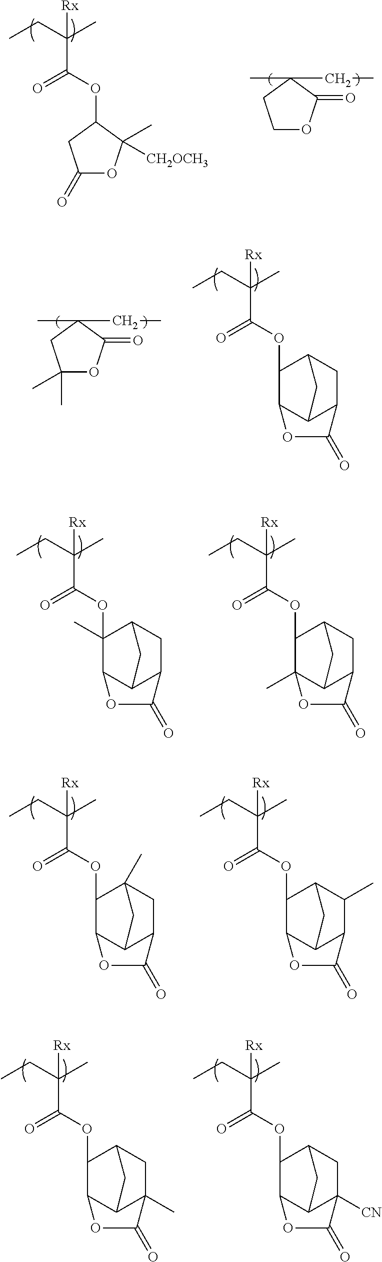

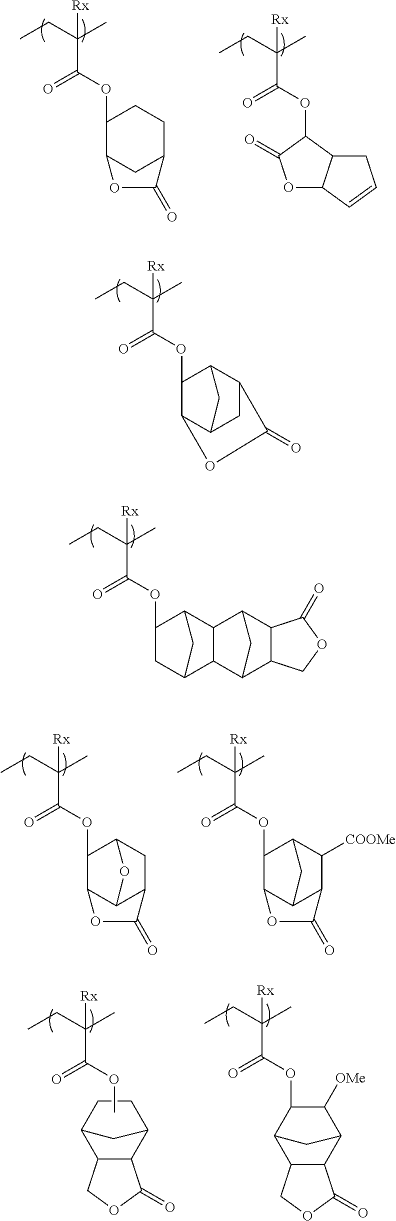

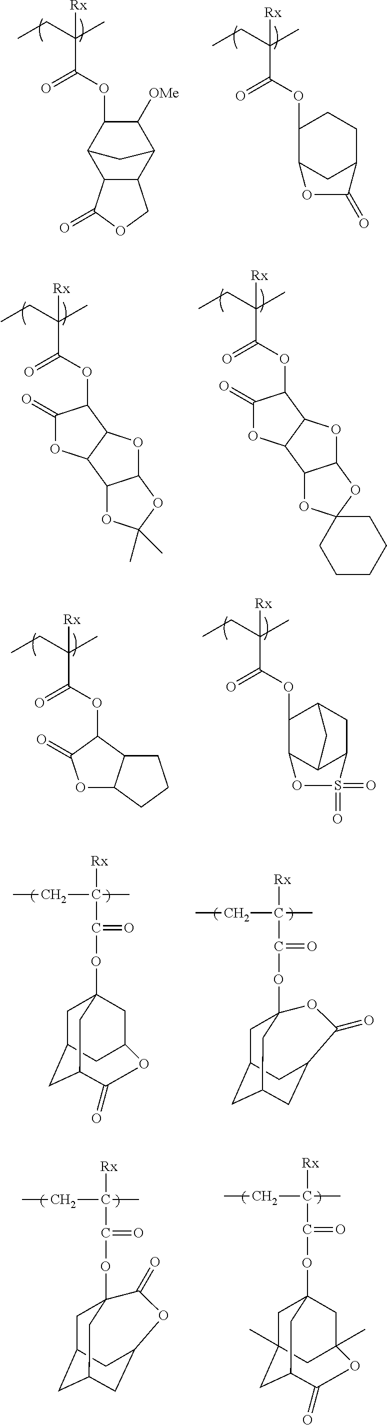

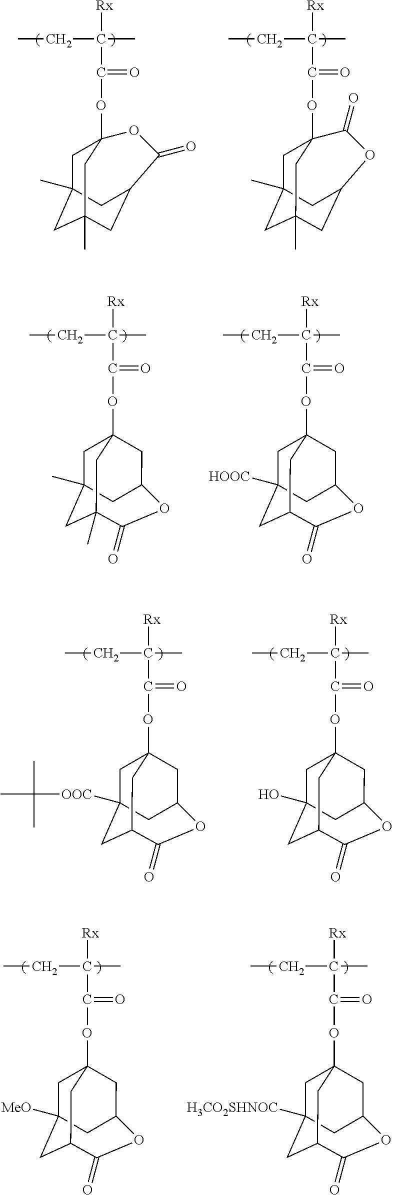

Among the above particular examples, especially preferred repeating units are as shown below. Selecting the most appropriate lactone or sultone group realizes enhancements of pattern profile and iso/dense bias.

In the formulae, Rx is H, CH₃, CH₂OH or CF₃.

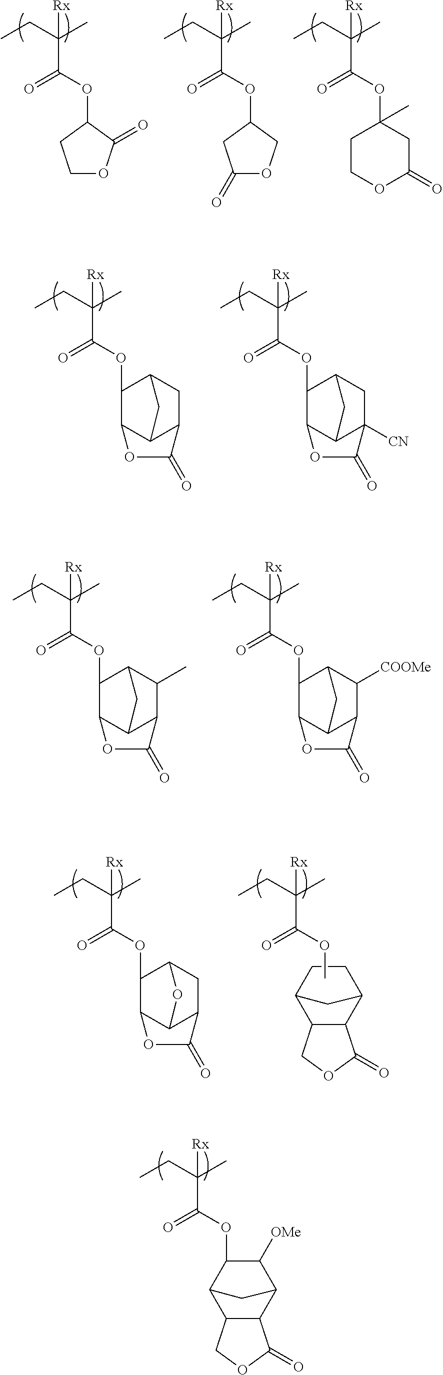

The repeating unit having a lactone group or a sultone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity thereof is preferably 90% ee or higher, more preferably 95% ee or higher.

The content of repeating unit containing a lactone structure a sultone structure other than the repeating units of general formula (III), the total content when two or more types thereof are contained, is preferably in the range of 15 to 60 mol %, more preferably 20 to 50 mol % and further more preferably 30 to 50 mol %, based on all the repeating units of the resin.

In order to enhance the effect of the present invention, two or more types of lactone or sultone repeating units selected from among those of general formula (III) can be used in combination. When such a combinational use is conducted, it is preferred to select two or more from among the lactone or sultone repeating units of general formula (III) in which n is 1 and use them in combination.

The resin (B) may further contain a repeating unit containing a hydroxy group or a cyano group other than repeating units represented by general formulae (AI) and (III). The containment of this repeating unit would realize enhancements of adhesion to substrate and developer affinity. The repeating unit containing a hydroxy group or a cyano group is preferably a repeating unit having an alicyclic hydrocarbon structure substituted with a hydroxy group or a cyano group. Further, the repeating unit containing a hydroxy group or a cyano group is preferably free from the acid-decomposable group. In the alicyclic hydrocarbon structure substituted with a hydroxy group or a cyano group, the alicyclic hydrocarbon structure preferably consists of an adamantyl group, a diamantyl group or a norbornane group. As preferred alicyclic hydrocarbon structures substituted with a hydroxy group or a cyano group, the partial structures represented by the following general formulae (VIIa) to (VIId) can be exemplified.

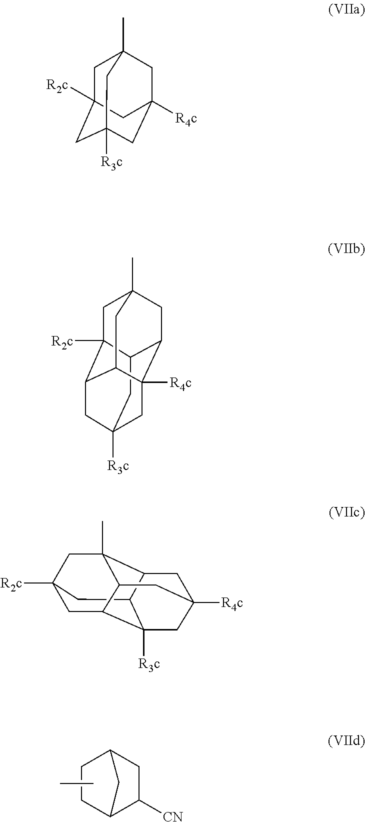

In the general formulae (VIIa) to (VIIc),

each of R₂c to R₄c independently represents a hydrogen atom, a hydroxy group or a cyano group, with the proviso that at least one of the R₂c to R₄c represents a hydroxy group or a cyano group. Preferably, one or two of the R₂c to R₄c are hydroxy groups and the remainder is a hydrogen atom. In the general formula (VIIa), more preferably, two of the R₂c to R₄c are hydroxy groups and the remainder is a hydrogen atom.

As the repeating units having any of the partial structures represented by the general formulae (VIIa) to (VIId), those of the following general formulae (AIIa) to (AIId) can be exemplified.

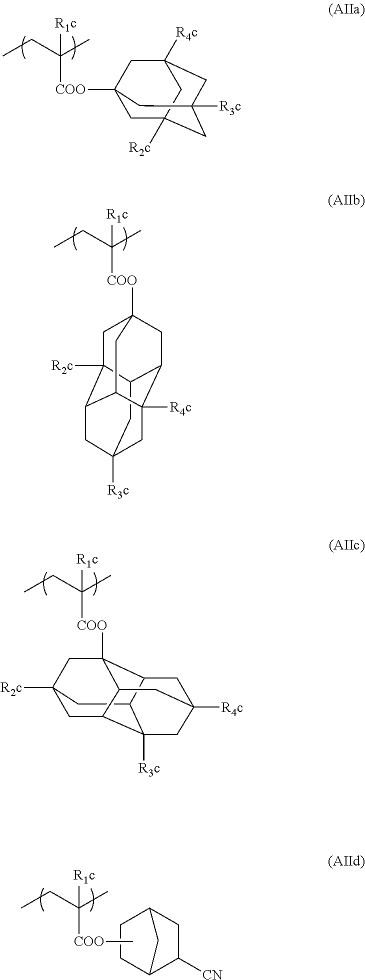

In general formulae (AIIa) to (AIId),

R₁c represents a hydrogen atom, a methyl group, a trifluoromethyl group or a hydroxymethyl group.

R₂c to R₄c have the same meaning as those of the general formulae (VIIa) to (VIIc).

The content of the repeating unit containing a hydroxyl group or a cyano group based on all the repeating units of the resin (B) is preferably in the range of 5 to 40 mol %, more preferably 5 to 30 mol % and further more preferably 10 to 25 mol %.

Specific examples of the repeating units containing a hydroxyl group or a cyano group will be shown below, which however in no way limit the scope of the present invention.

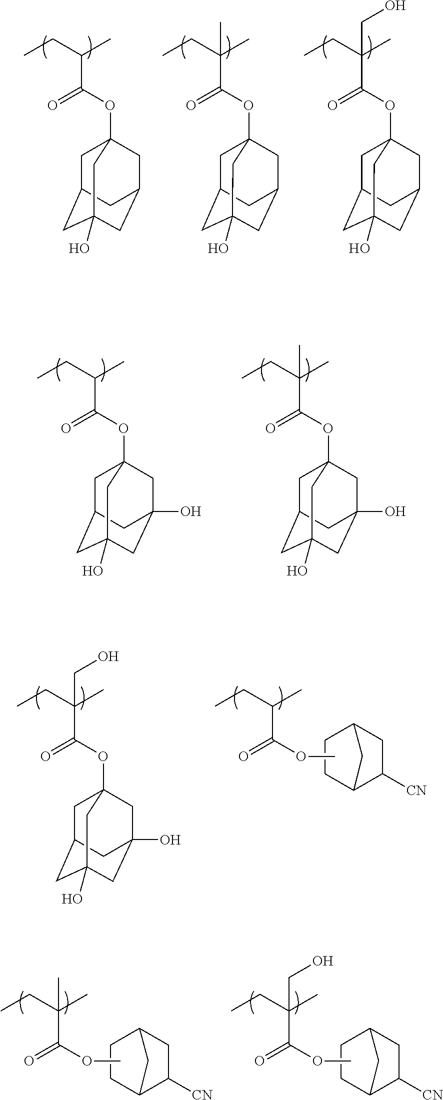

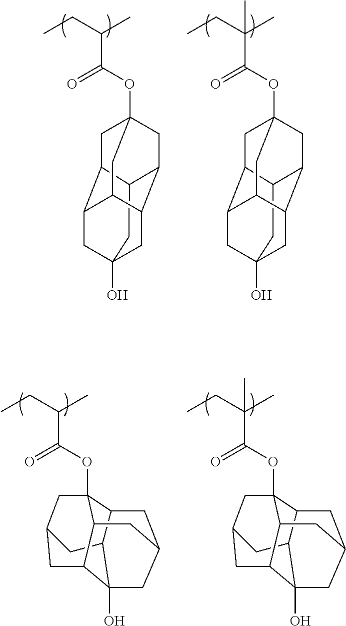

The resin for use in the composition of the present invention may contain a repeating unit containing an alkali-soluble group. As the alkali-soluble group, there can be mentioned a phenolic hydroxyl group, a carboxyl group, a sulfonamido group, a sulfonylimido group, a bisulfonylimido group or an aliphatic alcohol substituted at its α-position with an electron withdrawing group (for example, a hexafluoroisopropanol group). It is more preferred to contain a repeating unit containing a carboxyl group. The incorporation of the repeating unit containing an alkali-soluble group increases the resolution in contact hole usage. The repeating unit containing an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a mono- or polycyclohydrocarbon structure. The repeating unit of acrylic acid or methacrylic acid is especially preferred.

The content of the repeating unit containing an alkali-soluble group based on all the repeating units of the resin (B) is preferably in the range of 0 to 20 mol %, more preferably 3 to 15 mol % and further more preferably 5 to 10 mol %.

Specific examples of the repeating units containing an alkali-soluble group will be shown below, which however in no way limit the scope of the present invention.

In the specific examples, Rx represents H, CH₃, CH₂OH, or CF₃.

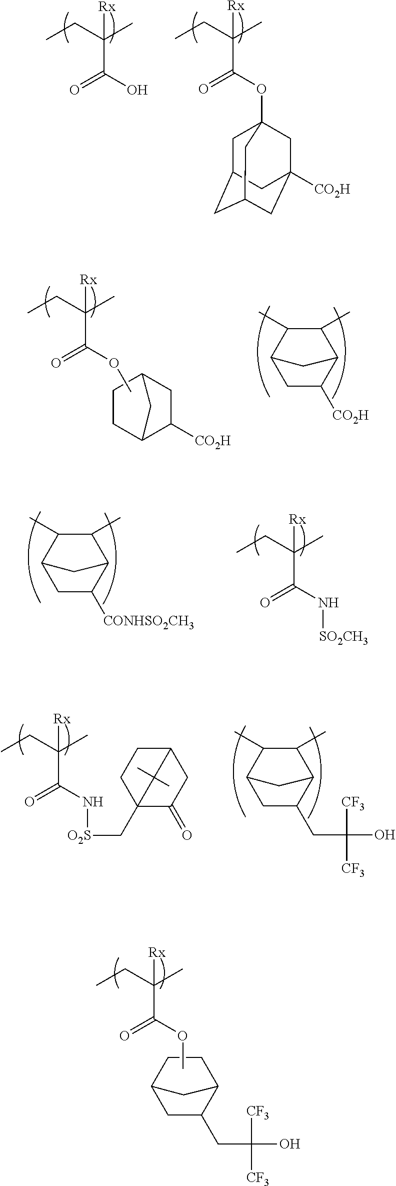

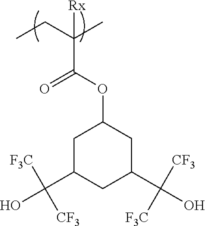

The resin (B) may further contain a repeating unit having an alicyclic hydrocarbon structure containing no polar group (for example, the above alkali-soluble group, a hydroxyl group, or a cyano group), which repeating unit exhibits no acid decomposability. As the repeating unit, there can be mentioned, for example, any of those of general formula (IV) below.

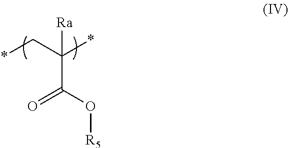

In the general formula (IV), R₅ represents a hydrocarbon group having at least one cyclic structure in which no polar group is contained.

Ra represents a hydrogen atom, an alkyl group or a group of the formula —CH₂—O—Ra₂ in which Ra₂ represents a hydrogen atom, an alkyl group or an acyl group. Ra is preferably a hydrogen atom, a methyl group, a hydroxymethyl group or a trifluoromethyl group, further preferably a hydrogen atom or a methyl group.

The cyclic structures contained in R₅ include a monocyclic hydrocarbon group and a polycyclic hydrocarbon group. As the monocyclic hydrocarbon group, a cycloalkyl group having 3 to 12 carbon atoms and a cycloalkenyl group having 3 to 12 carbon atoms can be exemplified. Preferably, the monocyclic hydrocarbon group is a monocyclic hydrocarbon group having 3 to 7 carbon atoms. As such, a cyclopentyl group and a cyclohexyl group can be exemplified.

The polycyclic hydrocarbon groups include ring-assembly hydrocarbon groups and crosslinked-ring hydrocarbon groups.

As the ring-assembly hydrocarbon groups, for example, a bicyclohexyl group and a perhydronaphthalenyl group can be exemplified.

As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings.

Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenalene rings.

As preferred crosslinked-ring hydrocarbon rings, there can be mentioned a norbornyl group, an adamantyl group, a bicyclooctanyl group, a tricyclo[5.2.1.0^{2,6}]decanyl group and the like. As more preferred crosslinked-ring hydrocarbon rings, there can be mentioned a norbornyl group and an adamantyl group.

These alicyclic hydrocarbon groups may have one or more substituents. As preferred substituents, a halogen atom, an alkyl group, a hydroxyl group protected by a protective group, and an amino group protected by a protective group can be exemplified. The halogen atom is preferably a bromine, chlorine or fluorine atom. The alkyl group is preferably a methyl, ethyl, butyl or t-butyl group. The alkyl group may further have one or more substituents. As the optional substituent, a halogen atom, an alkyl group, a hydroxyl group protected by a protective group, and an amino group protected by a protective group can be exemplified.

As the protective group, an alkyl group, a cycloalkyl group, an aralkyl group, a substituted methyl group, a substituted ethyl group, an alkoxycarbonyl group and an aralkyloxycarbonyl group can be exemplified. Preferred alkyl groups include alkyl groups having 1 to 4 carbon atoms. Preferred substituted methyl groups include methoxymethyl, methoxythiomethyl, benzyloxymethyl, t-butoxymethyl and 2-methoxyethoxymethyl groups. Preferred substituted ethyl groups include 1-ethoxyethyl and 1-methyl-1-methoxyethyl groups. Preferred acyl groups include aliphatic acyl groups having 1 to 6 carbon atoms, such as formyl, acetyl, propionyl, butyryl, isobutyryl, valeryl and pivaloyl groups. Preferred alkoxycarbonyl groups include alkoxycarbonyl groups having 1 to 4 carbon atoms and the like.

It is optional for the resin (B) to contain the repeating unit having an alicyclic hydrocarbon structure containing no polar group, which repeating unit exhibits no acid decomposability. When the repeating unit is contained, the content of the repeating unit based on all the repeating units of the resin (B) is preferably in the range of 1 to 40 mol %, more preferably 2 to 20 mol %.

Specific examples of the repeating unit having an alicyclic hydrocarbon structure containing no polar group, which repeating unit exhibits no acid decomposability will be shown below, which however in no way limit the scope of the present invention. In the formulae, Ra represents H, CH₃, CH₂OH or CF₃.

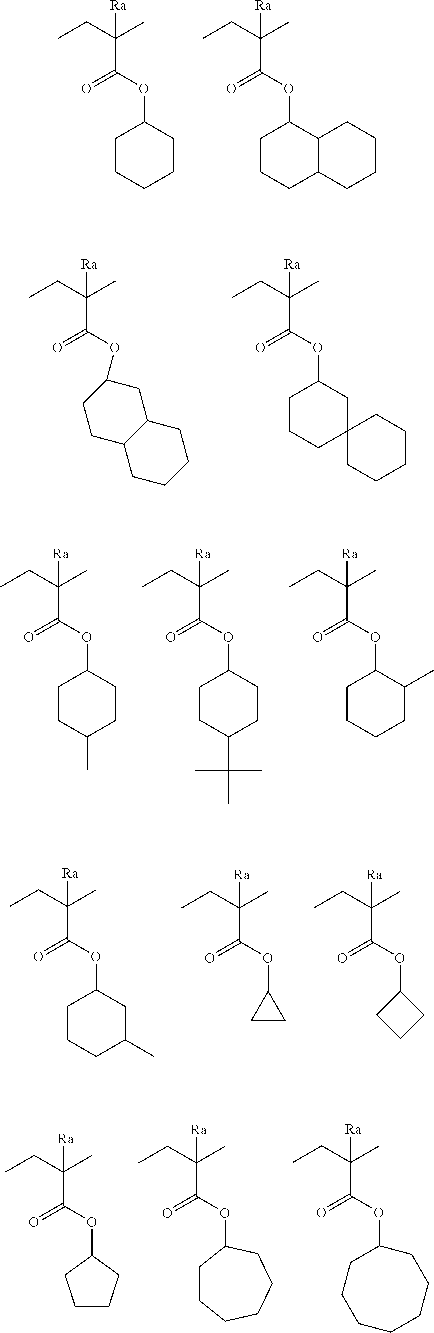

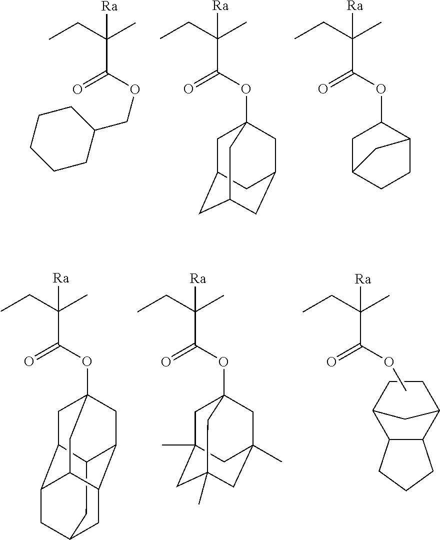

Various repeating structural units other than those mentioned hereinbefore can be introduced in the resin (B) in order to regulate the dry etching resistance, standard developer adaptability, adherence to substrates, resist profile, and generally required properties for resist, such as resolving power, heat resistance, sensitivity, and the like.

As such other repeating structural units, those corresponding to the following monomers can be exemplified, which however are nonlimiting.

Such other repeating structural units would permit fine regulation of the properties required to have by the resin for use in the composition of the present invention, especially, (1) solubility in applied solvents, (2) film forming easiness (glass transition temperature), (3) alkali developability, (4) film thinning (selection of hydrophilicity/hydrophobicity and alkali soluble group), (5) adhesion of unexposed areas to substrate, and (6) dry etching resistance, etc.

As the above-mentioned monomers, compounds having an unsaturated bond capable of addition polymerization, selected from among acrylic esters, methacrylic esters, acrylamides, methacrylamides, allyl compounds, vinyl ethers, vinyl esters and the like can be exemplified.

The monomers are not limited to the above, and unsaturated compounds capable of addition polymerization that are copolymerizable with the monomers corresponding to the above various repeating structural units can be used in the copolymerization.

The molar ratios of individual repeating structural units contained in the resin (B) for use in the composition of the present invention are appropriately determined from the viewpoint of regulation of not only the resist dry etching resistance but also the standard developer adaptability, substrate adhesion, resist profile and generally required properties of resists such as resolving power, heat resistance and sensitivity.

When the composition of the present invention is to be exposed to ArF light, it is preferred for the resin (B) for use in the composition of the present invention to contain substantially no aromatic group from the viewpoint of the transparency to ArF light. In particular, the content of repeating unit containing an aromatic group, based on all the repeating units of the resin (B), is preferably up to 5 mol %, more preferably up to 3 mol % and ideally 0 mol %. Namely, introducing no repeating unit containing an aromatic group is desirable. It is preferred for the resin (B) to have an alicyclic hydrocarbon structure of a single ring or multiple rings.

Further, it is preferred for the resin (B) to contain neither a fluorine atom nor a silicon atom from the viewpoint of compatibility with the second resin, that is, a hydrophobic resin, to be described hereinafter.

Preferred resin (B) is that whose repeating units consisting of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred for the acrylate repeating units to account for 50 mol % or less of all the repeating units. Further, a copolymer containing 20 to 50 mol % of (meth)acrylate repeating unit having an acid-decomposable group; 20 to 50 mol % of (meth)acrylate repeating unit having a lactone structure; 5 to 30 mol % of (meth)acrylate repeating unit containing a hydroxy group or a cyano group; and 0 to 20 mol % of other (meth)acrylate repeating units is also preferred.

In the event of exposing the composition of the present invention to KrF excimer laser beams, electron beams, X-rays or high-energy light rays of wavelength 50 nm or less (EUV, etc.), it is preferred for the resin (B) to further have hydroxystyrene repeating units. More preferably, the resin has hydroxystyrene repeating units, hydroxystyrene repeating units protected by an acid-decomposable group and acid-decomposable repeating units of a (meth)acrylic acid tertiary alkyl ester, etc.

As preferred hydroxystyrene repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl (meth)acrylate and a dialkyl(1-adamantyl)methyl (meth)acrylate are more preferred.

The resin (B) of the present invention can be synthesized by conventional techniques (for example, radical polymerization). As general synthetic methods, there can be mentioned, for example, a batch polymerization method in which a monomer species and an initiator are dissolved in a solvent and heated so as to accomplish polymerization and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or the solvent capable of dissolving the composition of the present invention, such as propylene glycol monomethyl ether acetate, propylene glycol monomethyl ether or cyclohexanone, to be described hereinafter. It is preferred to perform the polymerization with the use of the same solvent as employed in the actinic-ray- or radiation-sensitive resin composition of the present invention. This would inhibit any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10 to 150° C., preferably 30 to 120° C. and more preferably 60 to 100° C.

The weight average molecular weight of the resin (B) in terms of polystyrene molecular weight as measured by GPC is preferably in the range of 1000 to 200,000, more preferably 2000 to 20,000, still more preferably 3000 to 11,000 and further preferably 5000 to 13,000. The regulation of the weight average molecular weight to 1000 to 200,000 would prevent deteriorations of heat resistance and dry etching resistance and also prevent deterioration of developability and increase of viscosity leading to poor film forming property.

Use is made of the resin whose dispersity (molecular weight distribution) is usually in the range of 1.0 to 3.0, preferably 1.0 to 2.6, more preferably 1.0 to 2.0 and most preferably 1.4 to 2.0. The lower the molecular weight distribution, the more excellent the resolving power and resist profile and the smoother the side wall of the resist pattern to thereby attain an excellence in roughness.

In the present invention, the ratio of added resin (B) to the whole composition is preferably in the range of 30 to 99 mass %, more preferably 60 to 95 mass %, based on the total solids of the composition.

In the present invention, one type of resin may be used alone, or two or more types thereof may be used in combination.

A resin other than the resin (B) according to the present invention may be used in combination with the same in a ratio not detrimental to the effects of the present invention. As the resin other than the resin (B) according to the present invention, there can be mentioned an acid-decomposable resin optionally containing any of the above-mentioned repeating units introducible in the resin (B) or any of other generally known acid-decomposable resins.

[3] Hydrophobic Resin

The composition of the present invention may further contain a hydrophobic resin containing at least either a fluorine atom or a silicon atom especially when a liquid immersion exposure is applied thereto (hereinafter also referred to as “hydrophobic resin (HR)”). This localizes the hydrophobic resin (HR) in the surface layer of the film. Accordingly, when the immersion medium is water, the static/dynamic contact angle of the surface of the resist film with respect to water can be increased, thereby enhancing the immersion water tracking property.

Although the hydrophobic resin (HR) is unevenly localized in the interface as mentioned above, as different from surfactants, the hydrophobic resin does not necessarily have to have a hydrophilic group in its molecule and does not need to contribute toward uniform mixing of polar/nonpolar substances.

The hydrophobic resin (HR) typically contains a fluorine atom and/or a silicon atom. The fluorine atom and/or silicon atom may be introduced in the principal chain of the resin or a side chain thereof.

When the hydrophobic resin (HR) contains a fluorine atom, it is preferred for the resin to comprise, as a partial structure containing a fluorine atom, an alkyl group containing a fluorine atom, a cycloalkyl group containing a fluorine atom or an aryl group containing a fluorine atom.

The alkyl group containing a fluorine atom is a linear or branched alkyl group having at least one hydrogen atom thereof substituted with a fluorine atom. This alkyl group preferably has 1 to 10 carbon atoms, more preferably 1 to 4 carbon atoms. A substituent other than the fluorine atom may further be introduced in the alkyl group containing a fluorine atom.

The cycloalkyl group containing a fluorine atom is a mono- or polycycloalkyl group having at least one hydrogen atom thereof substituted with a fluorine atom. A substituent other than the fluorine atom may further be introduced in the cycloalkyl group containing a fluorine atom.

The aryl group containing a fluorine atom is an aryl group having at least one hydrogen atom thereof substituted with a fluorine atom. As the aryl group, there can be mentioned, for example, a phenyl or naphthyl group. A substituent other than the fluorine atom may further be introduced in the aryl group containing a fluorine atom.

As preferred examples of the alkyl groups each containing a fluorine atom, cycloalkyl groups each containing a fluorine atom and aryl groups each containing a fluorine atom, there can be mentioned the groups of general formulae (F2) to (F4) below, which however in no way limit the scope of the present invention.

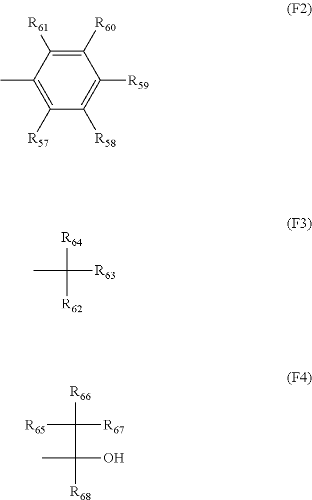

In general formulae (F2) to (F4),

each of R₅₇ to R₆₈ independently represents a hydrogen atom, a fluorine atom or an alkyl group (linear or branched), provided that at least one of each of R₅₇-R₆₁, at least one of each of R₆₂-R₆₄ and at least one of each of R₆₅-R⁶⁸ represent a fluorine atom or an alkyl group (preferably having 1 to 4 carbon atoms) having at least one hydrogen atom thereof substituted with a fluorine atom.

It is preferred that all of R₅₇-R₆₁ and R₆₅-R₆₇ represent fluorine atoms. Each of R₆₂, R₆₃ and R₆₈ preferably represents a fluoroalkyl group (especially having 1 to 4 carbon atoms), more preferably a perfluoroalkyl group having 1 to 4 carbon atoms. When each of R₆₂ and R₆₃ represents a perfluoroalkyl group, R₆₄ preferably represents a hydrogen atom. R₆₂ and R₆₃ may be bonded with each other to thereby form a ring.

Specific examples of the groups of general formula (F2) include a p-fluorophenyl group, a pentafluorophenyl group, a 3,5-di(trifluoromethyl)phenyl group and the like.

Specific examples of the groups of general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of general formula (F4) include —C(CF₃)₂OH, —C(C₂F₅)₂OH, —C(CF₃)(CF₃)OH, —CH(CF₃)OH and the like. —C(CF₃)₂OH is preferred.

The partial structure containing a fluorine atom may be directly bonded to the principal chain, or may be bonded to the principal chain through a group selected from the group consisting of an alkylene group, a phenylene group, an ether group, a thioether group, a carbonyl group, an ester group, an amido group, a urethane group and a ureylene group, or through a group composed of a combination of two or more of these groups.

As preferred repeating units having a fluorine atom, there can be mentioned the repeating units represented by the general formulae below.

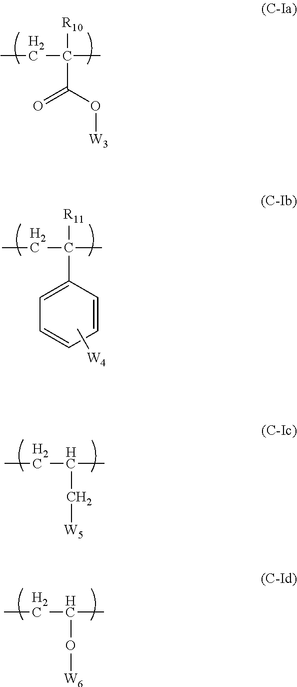

In the formulae, each of R₁₀ and R₁₁ independently represents a hydrogen atom, a fluorine atom or an alkyl group. The alkyl group is preferably a linear or branched alkyl group having 1 to 4 carbon atoms. The alkyl group may have a substituent. As a substituted alkyl group, there can be mentioned, in particular, a fluorinated alkyl group.

Each of W₃ to W₆ independently represents an organic group containing at least one fluorine atom. As such, for example, there can be mentioned the atomic groups of general formulae (F2) to (F4) above.

Further, besides these, the following units may be introduced as the repeating unit containing a fluorine atom.

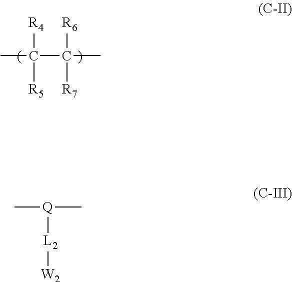

In the formulae, each of R₄ to R₇ independently represents a hydrogen atom, a fluorine atom or an alkyl group. The alkyl group is preferably a linear or branched alkyl group having 1 to 4 carbon atoms. The alkyl group may have a substituent. As a substituted alkyl group, there can be mentioned, in particular, a fluorinated alkyl group.

At least one of R₄ to R₇ represents a fluorine atom. R₄ and R₅, or R₆ and R₇ may cooperate with each other to thereby form a ring.

W₂ represents an organic group containing at least one fluorine atom. As such, for example, there can be mentioned the atomic groups of general formulae (F2) to (F4) above.

L₂ represents a single bond or a bivalent connecting group. As the bivalent connecting group, there can be mentioned a substituted or unsubstituted arylene group, a substituted or unsubstituted alkylene group, a substituted or unsubstituted cycloalkylene group, —O—, —SO₂—, —CO—, —N(R)— (in the formula, R is a hydrogen atom or an alkyl group), —NHSO₂— or a bivalent connecting group consisting of a combination of two or more of these.

Q represents an alicyclic structure. A substituent may be introduced in the alicyclic structure. The alicyclic structure may be monocyclic or polycyclic. The alicyclic structure when being polycyclic may be a bridged one. The alicyclic structure when being monocyclic is preferably a cycloalkyl group having 3 to 8 carbon atoms. As such, there can be mentioned, for example, a cyclopentyl group, a cyclohexyl group, a cyclobutyl group, a cyclooctyl group or the like. As the polycyclic one, there can be mentioned a group with, for example, a bicyclo, tricyclo or tetracyclo structure having 5 or more carbon atoms. A cycloalkyl group having 6 to 20 carbon atoms is preferred. As such, there can be mentioned, for example, an adamantyl group, a norbornyl group, a dicyclopentyl group, a tricyclodecanyl group, a tetracyclododecyl group or the like. The carbon atoms of the cycloalkyl group may be partially replaced with a heteroatom, such as an oxygen atom. It is especially preferred for Q to represent a norbornyl group, a tricyclodecanyl group, a tetracyclododecyl group or the like.

The hydrophobic resin (HR) may contain a silicon atom.

It is preferred for the hydrophobic resin (D) to have an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

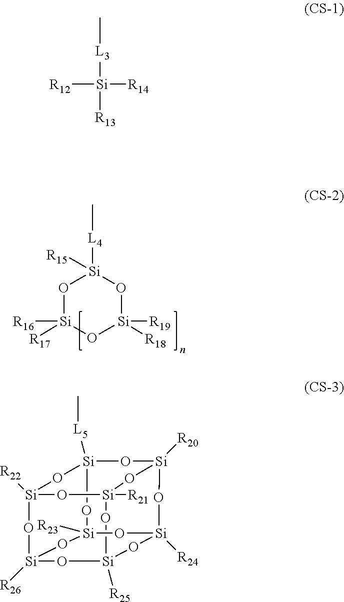

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a urea group.

In the formulae, n is an integer of 1 to 5. n is preferably an integer of 2 to 4.

It is preferred for the repeating unit containing at least either a fluorine atom or a silicon atom to be a (meth)acrylate repeating unit.

Particular examples of the repeating units each containing at least either a fluorine atom or a silicon atom are shown below, which in no way limit the scope of the present invention. In the particular examples, X₁ is a hydrogen atom, —CH₃, —F or —CF₃, and X₂ is —F or —CF₃.

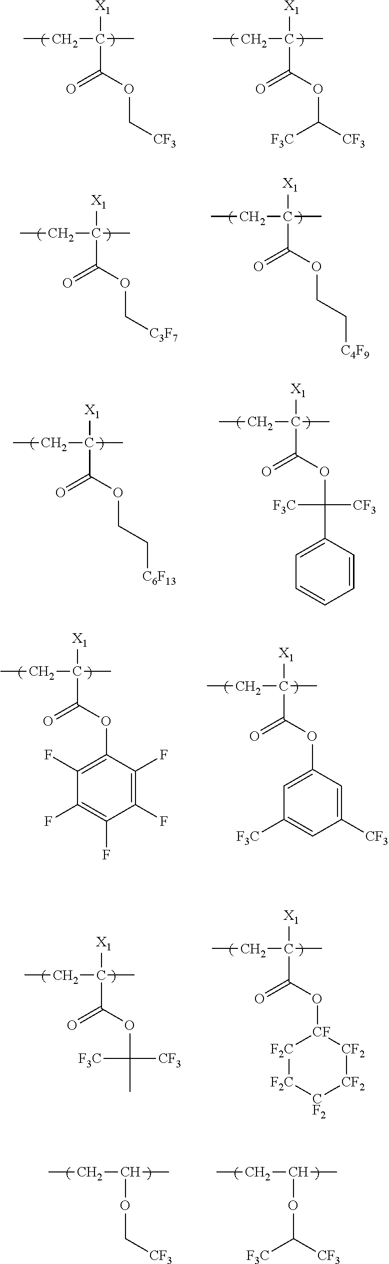

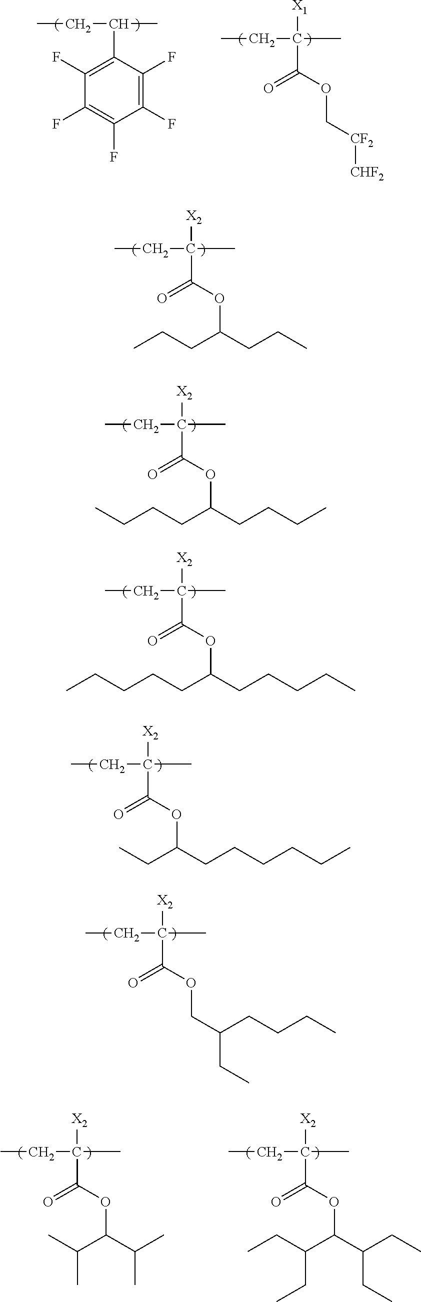

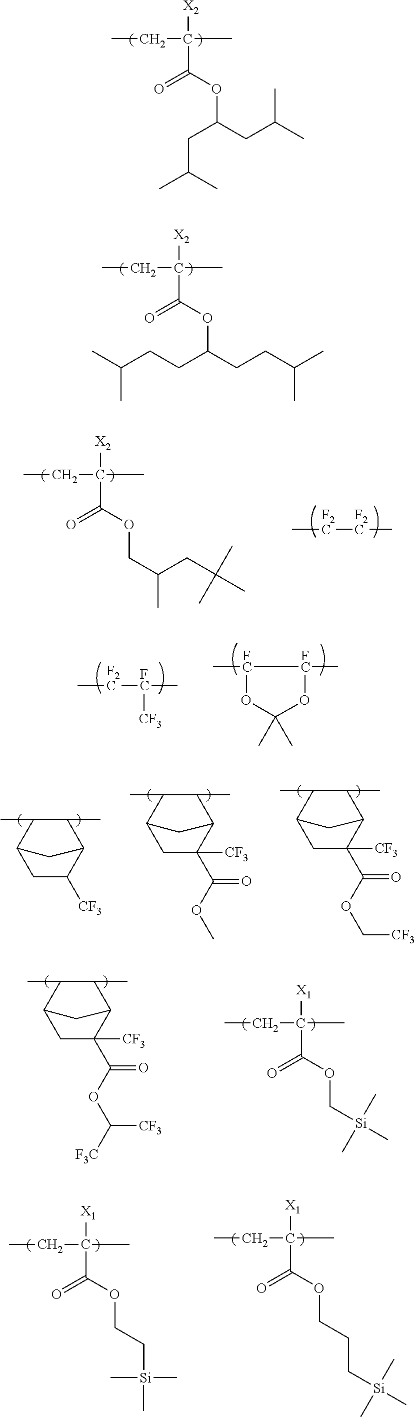

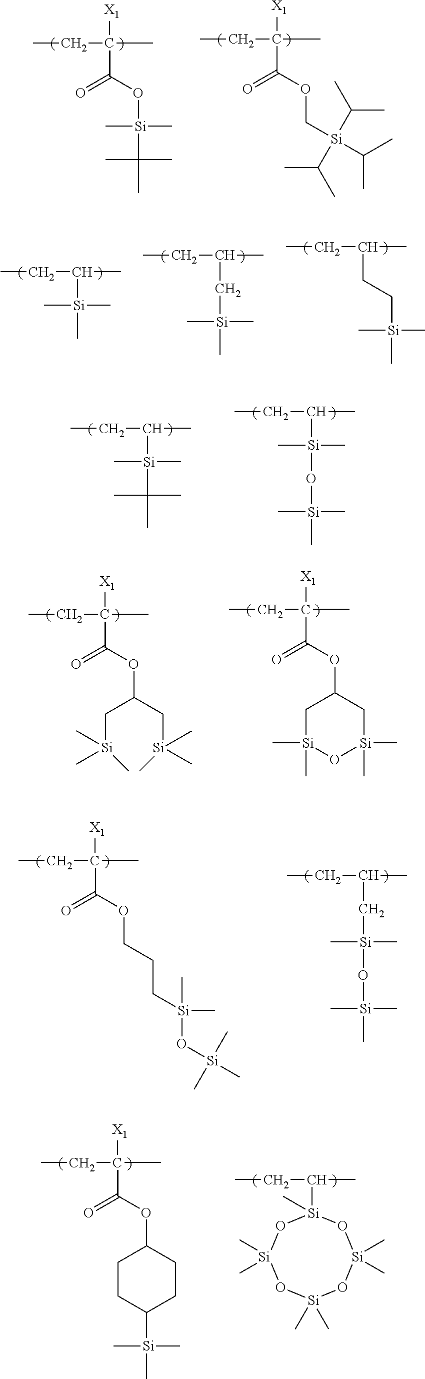

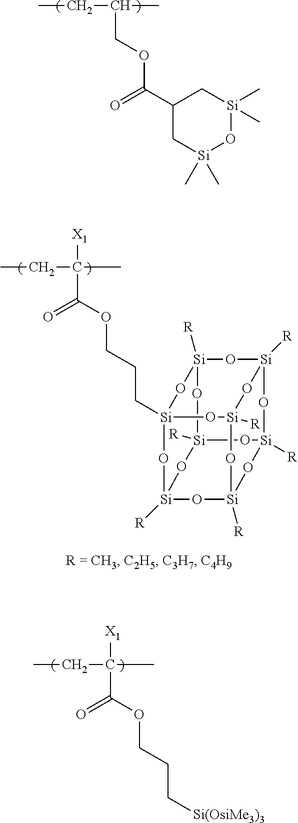

It is preferred for the hydrophobic resin to contain a repeating unit (b) containing at least one group selected from the group consisting of the following groups (x) to (z).

Namely,

(x) an alkali-soluble group,

(y) a group that when acted on by an alkali developer, is decomposed to thereby increase its solubility in the alkali developer (hereinafter referred to as a “polarity conversion group”), and

(z) a group that when acted on by an acid, is decomposed to thereby increase its solubility in an alkali developer.

The following varieties of repeating units (b) can be mentioned.

Namely, the repeating unit (b) may be:

a repeating unit (b′) containing at least either a fluorine atom or a silicon atom and at least one group selected from the group consisting of the above groups (x) to (z) simultaneously introduced in one side chain thereof,

a repeating unit (b*) containing at least one group selected from the group consisting of the above groups (x) to (z) but containing neither a fluorine atom nor a silicon atom, or

a repeating unit (b″) in which at least one group selected from the group consisting of the above groups (x) to (z) is introduced in its one side chain while at least either a fluorine atom or a silicon atom is introduced in a side chain other than the above side chain within the same repeating unit.

It is preferred for the hydrophobic resin to contain the repeating unit (b′) as the repeating unit (b). Namely, it is preferred for the repeating unit (b) containing at least one group selected from the group consisting of the above groups (x) to (z) to further contain at least either a fluorine atom or a silicon atom.

When the hydrophobic resin contains the repeating unit (b*), it is preferred for the hydrophobic resin to be a copolymer with a repeating unit (repeating unit other than the above-mentioned repeating units (b′) and (b″)) containing at least either a fluorine atom or a silicon atom. In the repeating unit (b″), it is preferred for the side chain containing at least one group selected from the group consisting of the above groups (x) to (z) and the side chain containing at least either a fluorine atom or a silicon atom to be bonded to the same carbon atom of the principal chain, namely to be in a positional relationship shown in formula (K1) below.

In the formula, B1 represents a partial structure containing at least one group selected from the group consisting of the above groups (x) to (z), and B2 represents a partial structure containing at least either a fluorine atom or a silicon atom.

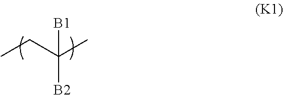

The group selected from the group consisting of the above groups (x) to (z) is preferably (x) an alkali-soluble group or (y) a polarity conversion group, more preferably (y) a polarity conversion group.

As the alkali-soluble group (x), there can be mentioned a phenolic hydroxyl group, a carboxylate group, a fluoroalcohol group, a sulfonate group, a sulfonamido group, a sulfonimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a fluoroalcohol group (preferably hexafluoroisopropanol group), a sulfonimido group and a bis(alkylcarbonyl)methylene group.

As the repeating unit (bx) having an alkali soluble group (x), preferred use is made of any of a repeating unit resulting from direct bonding of an alkali soluble group to the principal chain of a resin like a repeating unit of acrylic acid or methacrylic acid, a repeating unit resulting from bonding, via a connecting group, of an alkali soluble group to the principal chain of a resin and a repeating unit resulting from polymerization with the use of a chain transfer agent or polymerization initiator having an alkali soluble group to thereby introduce the same in a polymer chain terminal.

When the repeating unit (bx) is a repeating unit containing at least either a fluorine atom or a silicon atom (namely, when corresponding to the above-mentioned repeating unit (b′) or repeating unit (b″)), the partial structure containing a fluorine atom contained in the repeating unit (bx) can be the same as set forth above in connection with the repeating unit containing at least either a fluorine atom or a silicon atom. As such, preferably, there can be mentioned any of the groups of general formulae (F2) to (F4) above. Also in that instance, the partial structure containing a silicon atom contained in the repeating unit (bx) can be the same as set forth above in connection with the repeating unit containing at least either a fluorine atom or a silicon atom. As such, preferably, there can be mentioned any of the groups of general formulae (CS-1) to (CS-3) above.

The content ratio of repeating units (bx) having an alkali soluble group (x) is preferably in the range of 1 to 50 mol %, more preferably 3 to 35 mol % and still more preferably 5 to 20 mol % based on all the repeating units of the hydrophobic resin.

Specific examples of the repeating units (bx) having an alkali-soluble group (x) will be shown below.

In the formulae, Rx represents a hydrogen atom, —CH₃, —CF₃ or —CH₂OH, and X₁ represents a hydrogen atom, —CH₃, —F or —CF₃.

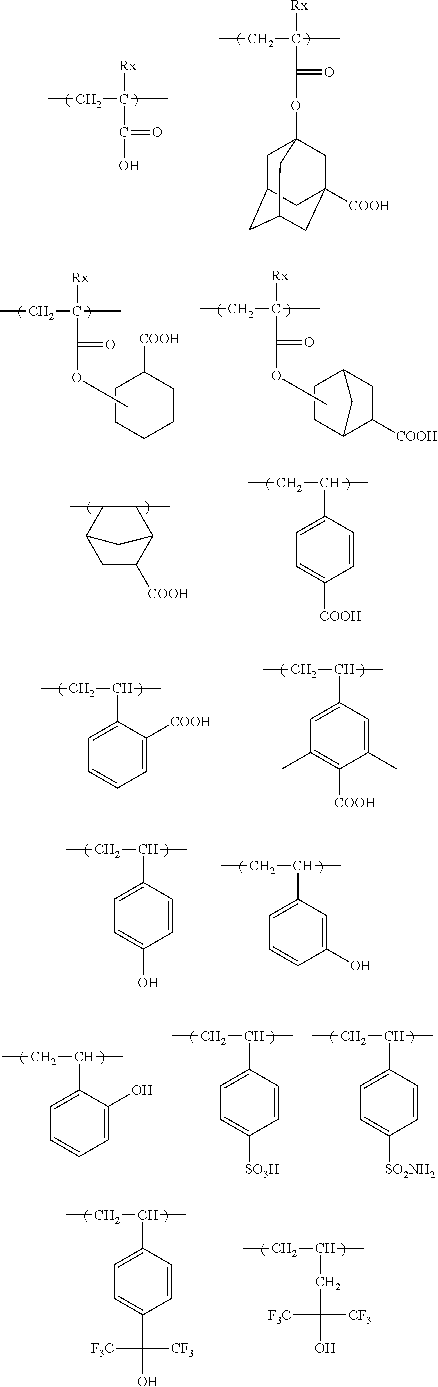

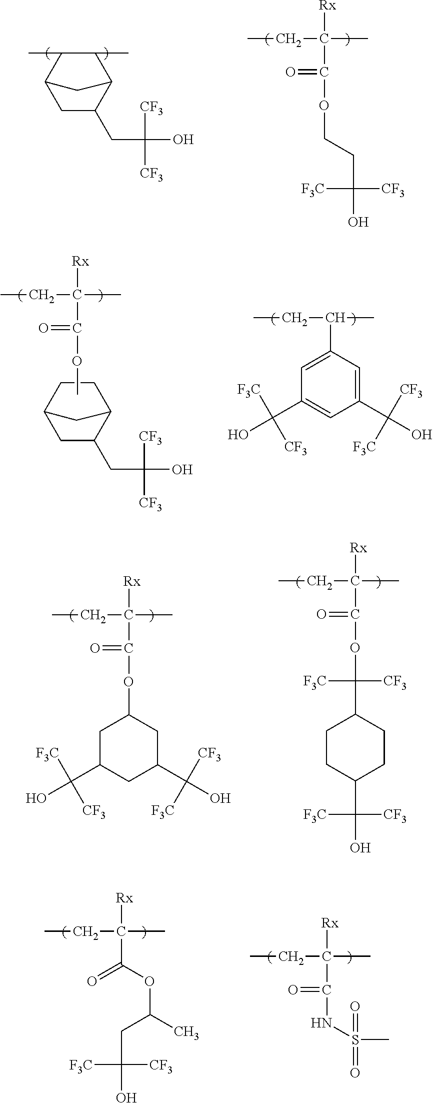

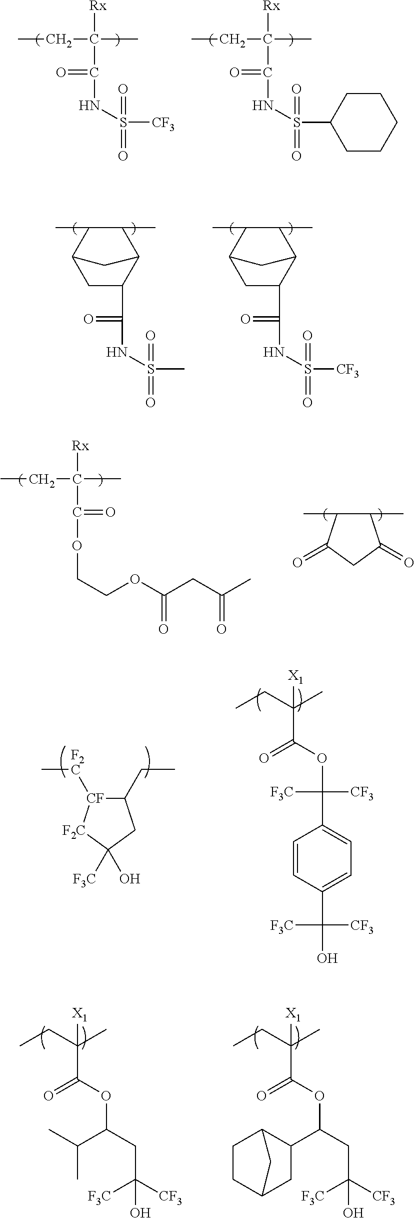

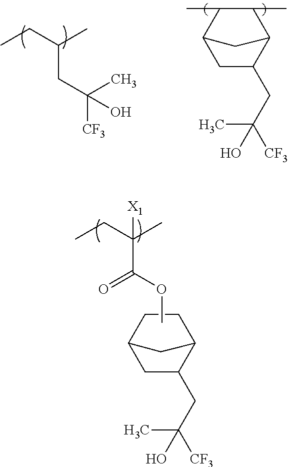

As the polarity conversion group (y), there can be mentioned, for example, a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (−OSO₂O—), a sulfonic ester group (—SO₂O—) or the like. A lactone group is particularly preferred.

The polarity conversion group (y) is contained in, for example, two modes which are both preferred. In one mode, the polarity conversion group (y) is contained in a repeating unit of an acrylic ester or methacrylic ester and introduced in a side chain of a resin. In the other mode, the polarity conversion group is introduced in a terminal of a polymer chain by using a polymerization initiator or chain transfer agent containing the polarity conversion group (y) in the stage of polymerization.

As particular examples of the repeating units (by) each containing a polarity conversion group (y), there can be mentioned the repeating units with a lactone structure of formulae (KA-1-1) to (KA-1-17) to be shown hereinafter.

Further, it is preferred for the repeating unit (by) containing a polarity conversion group (y) to be a repeating unit containing at least either a fluorine atom or a silicon atom (namely, corresponding to the above-mentioned repeating unit (b′) or repeating unit (b″)). The resin comprising this repeating unit (by) is hydrophobic, and is especially preferred from the viewpoint of the reduction of development defects.

As the repeating unit (by), there can be mentioned, for example, any of the repeating units of formula (K0) below.

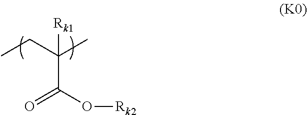

In the formula, Rₖ₁ represents a hydrogen atom, a halogen atom, a hydroxyl group, an alkyl group, a cycloalkyl group, an aryl group or a group containing a polarity conversion group.

Rₖ₂ represents an alkyl group, a cycloalkyl group, an aryl group or a group containing a polarity conversion group.

Here, at least one of Rₖ₁ and Rₖ₂ is a group containing a polarity conversion group.

The polarity conversion group, as mentioned above, refers to a group that is decomposed by the action of an alkali developer to thereby increase its solubility in the alkali developer. It is preferred for the polarity conversion group to be a group represented by X in the partial structures of general formulae (KA-1) and (KB-1) below.

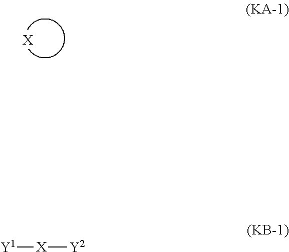

In general formulae (KA-1) and (KB-1), X represents a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—) or a sulfonic ester group (—SO₂O—).

Y¹ and Y² may be identical to or different from each other, and each thereof represents an electron withdrawing group.

The repeating unit (by) contains a preferred group whose solubility in an alkali developer is increased by containing a group with the partial structure of general formula (KA-1) or (KB-1). When the partial structure has no bonding hand as in the case of the partial structure of general formula (KA-1) or the partial structure of general formula (KB-1) in which Y¹ and Y² are monovalent, the above group with the partial structure refers to a group containing a monovalent or higher-valent group resulting from the deletion of at least one arbitrary hydrogen atom from the partial structure.

The partial structure of general formula (KA-1) or (KB-1) is linked at its arbitrary position to the principal chain of the hydrophobic resin via a substituent.

The partial structure of general formula (KA-1) is a structure in which a ring structure is formed in cooperation with a group represented by X.

In general formula (KA-1), X is preferably a carboxylic ester group (namely, in the case of the formation of a lactone ring structure as KA-1), an acid anhydride group or a carbonic ester group. More preferably, X is a carboxylic ester group.

A substituent may be introduced in the ring structure of general formula (KA-1). For example, when Zₖₐ₁ is a substituent, nka substituents may be introduced.

Zₖₐ₁, or each of a plurality of Zₖₐ₁s independently, represents a halogen atom, an alkyl group, a cycloalkyl group, an ether group, a hydroxyl group, an amido group, an aryl group, a lactone ring group or an electron withdrawing group.

Zₖₐ₁s may be linked to each other to thereby form a ring. As the ring formed by the mutual linkage of Zₖₐ₁s, there can be mentioned, for example, a cycloalkyl ring or a heterocycle (for example, a cycloether ring or a lactone ring).

The above nka is an integer of 0 to 10, preferably 0 to 8, more preferably 0 to 5, further more preferably 1 to 4 and most preferably 1 to 3.

The electron withdrawing groups represented by Zₖₐ₁ are the same as those represented by Y¹ and Y² to be described hereinafter. These electron withdrawing groups may be substituted with other electron withdrawing groups.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be one substituted with, for example, an alkyl group or a cycloalkyl group, namely, to be an alkyl ether group or the like. The electron withdrawing group is as mentioned above.

As the halogen atom represented by Zₖₐ₁, there can be mentioned a fluorine atom, a chlorine atom, a bromine atom, an iodine atom or the like. Among these, a fluorine atom is preferred.

The alkyl group represented by Zₖₐ₁ may contain a substituent, and may be linear or branched. The linear alkyl group preferably has 1 to 30 carbon atoms, more preferably 1 to 20 carbon atoms. As the linear alkyl group, there can be mentioned, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group or the like. The branched alkyl group preferably has 3 to 30 carbon atoms, more preferably 3 to 20 carbon atoms. As the branched alkyl group, there can be mentioned, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl (t-decanoyl) group or the like. It is preferred for the alkyl group represented by Zₖₐ₁ to be one having 1 to 4 carbon atoms, such as a methyl group, an ethyl group, an n-propyl group, an i-propyl group, an n-butyl group, an i-butyl group or a t-butyl group.

The cycloalkyl group represented by Zₖₐ₁ may contain a substituent and may be monocyclic or polycyclic. When polycyclic, the cycloalkyl group may be a bridged one. Namely, in that case, the cycloalkyl group may have a bridged structure. The monocycloalkyl group is preferably a cycloalkyl group having 3 to 8 carbon atoms. As such a cycloalkyl group, there can be mentioned, for example, a cyclopropyl group, a cyclopentyl group, a cyclohexyl group, a cyclobutyl group, a cyclooctyl group or the like. As the polycycloalkyl group, there can be mentioned a group with, for example, a bicyclo, tricyclo or tetracyclo structure having 5 or more carbon atoms. This polycycloalkyl group is preferably a cycloalkyl group having 6 to 20 carbon atoms. As such, there can be mentioned, for example, an adamantyl group, a norbornyl group, an isobornyl group, a camphonyl group, a bicyclopentyl group, an α-pinanyl group, a tricyclodecanyl group, a tetracyclododecyl group, an androstanyl group or the like. As the cycloalkyl groups, there can also be mentioned any of the following structures. The at least one of the carbon atoms of each of the cycloalkyl groups may be replaced with a heteroatom, such as an oxygen atom.

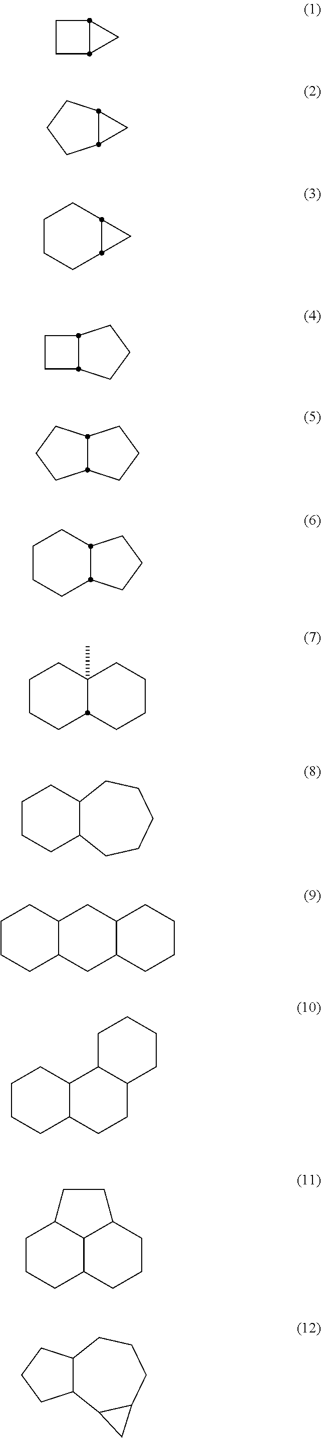

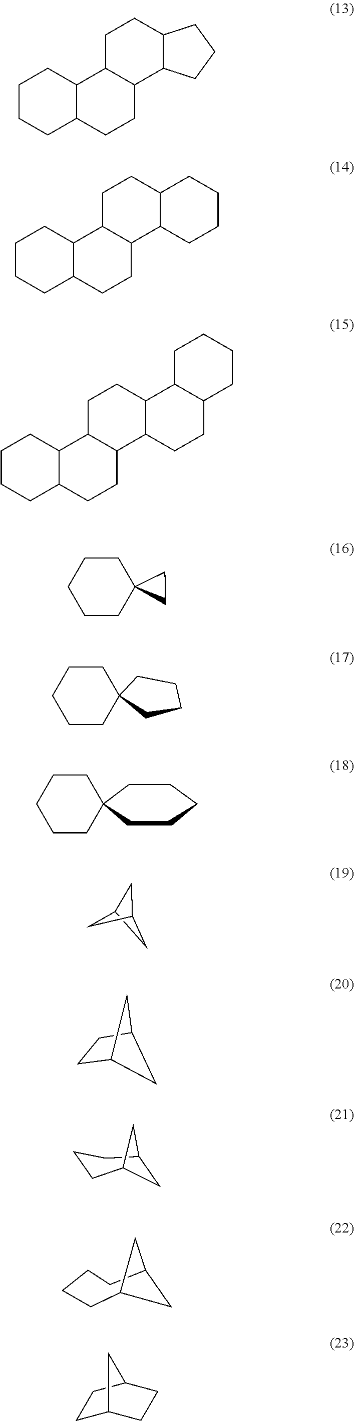

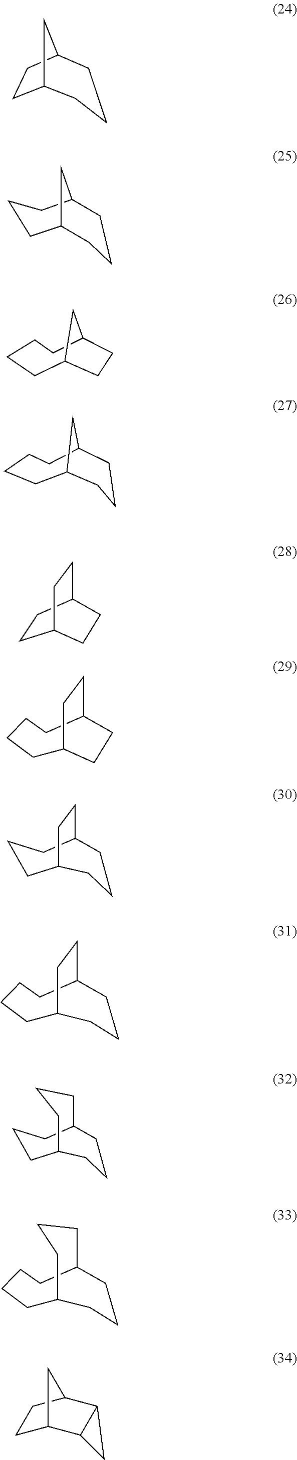

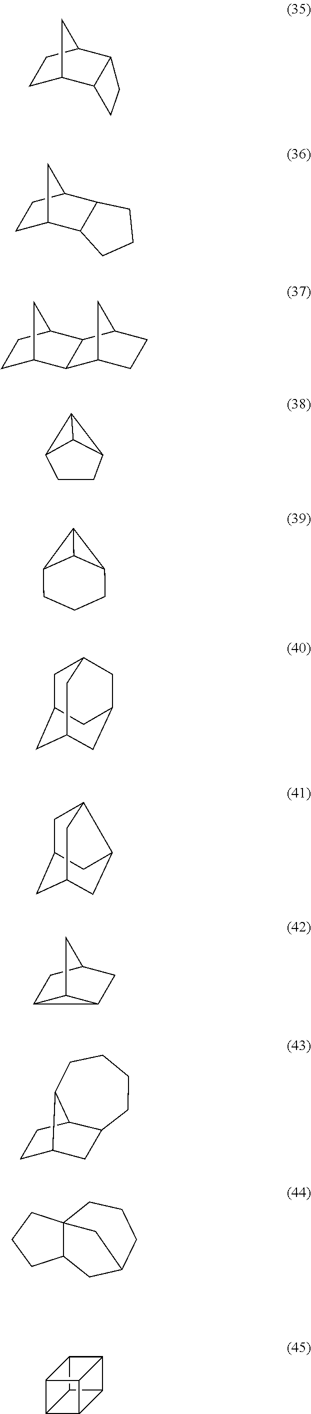

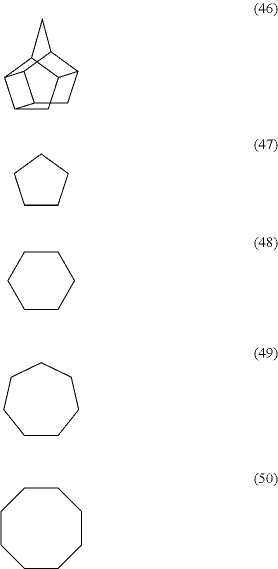

As preferred alicyclic moieties among the above, there can be mentioned an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group. As more preferred alicyclic moieties, there can be mentioned an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group.

As a substituent that can be introduced in these alicyclic structures, there can be mentioned an alkyl group, a halogen atom, a hydroxyl group, an alkoxy group, a carboxyl group or an alkoxycarbonyl group. The alkyl group is preferably a lower alkyl group, such as a methyl group, an ethyl group, a propyl group, an isopropyl group or a butyl group. More preferably, the alkyl group is a methyl group, an ethyl group, a propyl group or an isopropyl group. As preferred alkoxy groups, there can be mentioned those each having 1 to 4 carbon atoms, such as a methoxy group, an ethoxy group, a propoxy group and a butoxy group. As a substituent that may be introduced in these alkyl and alkoxy groups, there can be mentioned a hydroxyl group, a halogen atom, an alkoxy group (preferably having 1 to 4 carbon atoms) or the like.

Further substituents may be introduced in these groups. As further substituents, there can be mentioned a hydroxyl group; a halogen atom (fluorine, chlorine, bromine or iodine); a nitro group; a cyano group; the above alkyl groups; an alkoxy group, such as a methoxy group, an ethoxy group, a hydroxyethoxy group, a propoxy group, a hydroxypropoxy group, an n-butoxy group, an isobutoxy group, a sec-butoxy group or a t-butoxy group; an alkoxycarbonyl group, such as a methoxycarbonyl group or an ethoxycarbonyl group; an aralkyl group, such as a benzyl group, a phenethyl group or a cumyl group; an aralkyloxy group; an acyl group, such as a formyl group, an acetyl group, a butyryl group, a benzoyl group, a cinnamoyl group or a valeryl group; an acyloxy group, such as a butyryloxy group; an alkenyl group, such as a vinyl group, a propenyl group or an allyl group; an alkenyloxy group, such as a vinyloxy group, a propenyloxy group, an allyloxy group or a butenyloxy group; an aryl group, such as a phenyl group or a naphthyl group; an aryloxy group, such as a phenoxy group; an aryloxycarbonyl group, such as a benzoyloxy group; and the like.

Preferably, X of general formula (KA-1) represents a carboxylic ester group and the partial structure of general formula (KA-1) is a lactone ring. A 5- to 7-membered lactone ring is preferred.

Further, as shown in formulae (KA-1-1) to (KA-1-17) below, the 5- to 7-membered lactone ring as the partial structure of general formula (KA-1) is preferably condensed with another ring structure in such a fashion that a bicyclo structure or a spiro structure is formed.

The peripheral ring structures to which the ring structure of general formula (KA-1) may be bonded can be, for example, those shown in formulae (KA-1-1) to (KA-1-17) below, or those similar to the same.

It is preferred for the structure containing the lactone ring structure of general formula (KA-1) to be the structure of any of formulae (KA-1-1) to (KA-1-17) below. The lactone structure may be directly bonded to the principal chain. As preferred structures, there can be mentioned those of formulae (KA-1-1), (KA-1-4), (KA-1-5), (KA-1-6), (KA-1-13), (KA-1-14) and (KA-1-17).

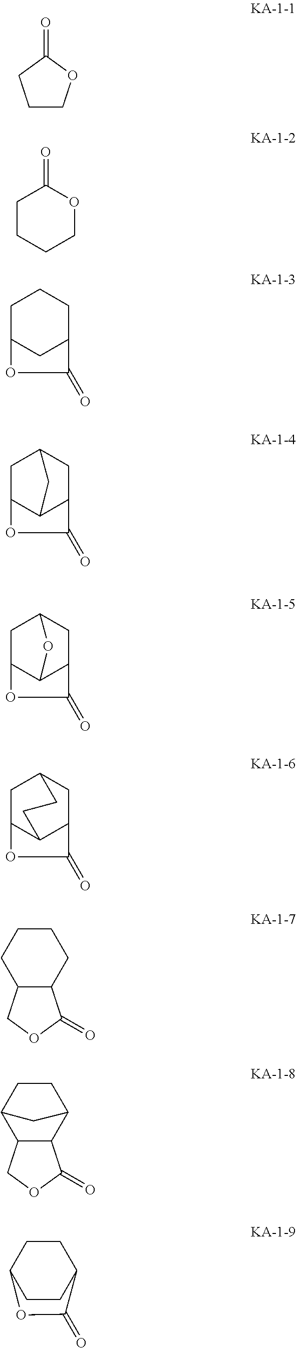

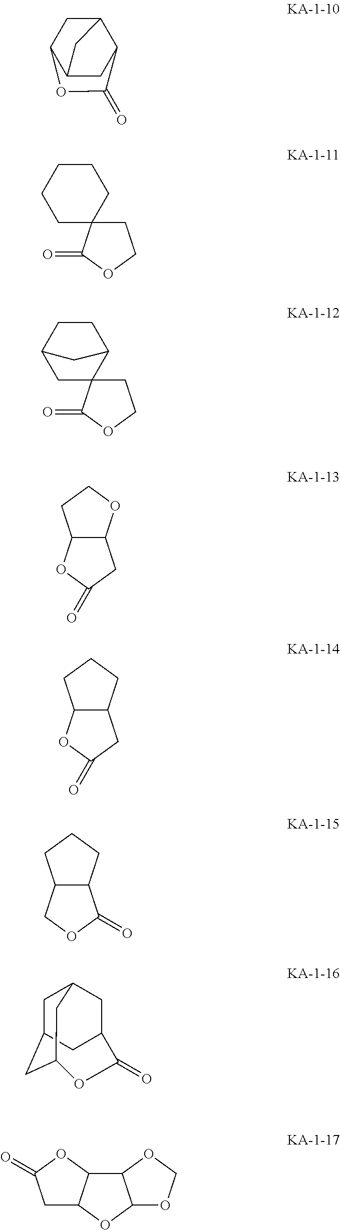

It is optional for the above structures containing the lactone ring structure to have a substituent. As preferred substituents, there can be mentioned the same as the substituents Zₖₐ₁ that may be introduced in the ring structure of general formula (KA-1) above.

In general formula (KB-1), X is preferably a carboxylic ester group (—COO—).

In general formula (KB-1), each of Y¹ and Y² independently represents an electron withdrawing group.

The electron withdrawing group has the partial structure of formula (EW) below. In formula (EW), * represents either a bonding hand directly bonded to the structure of general formula (KA-1) or a bonding hand directly bonded to X of general formula (KB-1).

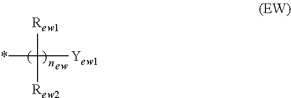

In formula (EW),

each of R_{ew1} and R_{ew2} independently represents an arbitrary substituent, for example, a hydrogen atom, an alkyl group, a cycloalkyl group or an aryl group.

n_{ew} is the number of repetitions of each of the connecting groups of the formula —C(R_{ew1})(R_{ew2})—, being an integer of 0 or 1. When n_{ew} is 0, a single bond is represented, indicating the direct bonding of Y_{ew1}.

Y_{ew1} can be any of a halogen atom, a cyano group, a nitrile group, a nitro group, any of the halo(cyclo)alkyl groups or haloaryl groups of the formula —C(R_{f1})(R_{f2})—R_{f3} to be described hereinafter, an oxy group, a carbonyl group, a sulfonyl group, a sulfinyl group and a combination thereof. The electron withdrawing groups may have, for example, the following structures. Herein, the “halo(cyclo)alkyl group” refers to an at least partially halogenated alkyl group or cycloalkyl group. The “haloaryl group” refers to an at least partially halogenated aryl group. In the following structural formulae, each of R_{ew3} and R_{ew4} independently represents an arbitrary structure. Regardless of the types of the structures of R_{ew3} and R_{ew4}, the partial structures of formula (EW) exhibit electron withdrawing properties, and may be linked to, for example, the principal chain of the resin. Preferably, each of R_{ew3} and R_{ew4} is an alkyl group, a cycloalkyl group or a fluoroalkyl group.

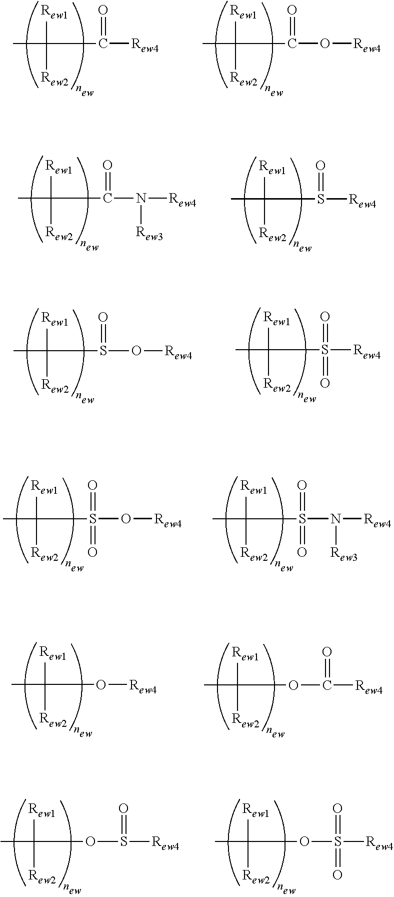

When Y_{ew1} is a bivalent or higher-valent group, the remaining bonding hand or hands form a bond with an arbitrary atom or substituent. At least any of the groups represented by Y_{ew1}, R_{ew1} and R_{ew2} may be linked via a further substituent to the principal chain of the hydrophobic resin.

Y_{ew1} is preferably a halogen atom or any of the halo(cyclo)alkyl groups or haloaryl groups of the formula —C(R_{f1})(R_{f2})—R_{f3}.

At least two of R_{ew1}, R_{ew2} and Y_{ew1} may be linked to each other to thereby form a ring.

In the above formula, R_{f1} represents a halogen atom, a perhaloalkyl group, a perhalocycloalkyl group or a perhaloaryl group. R_{f1} is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group. R_{f2} and R_{f3} may be linked to each other to thereby form a ring. As the organic group, there can be mentioned, for example, an alkyl group, a cycloalkyl group, an alkoxy group or the like. It is preferred for R_{f2} to represent the same groups as R_{f1} or to be linked to R_{f3} to thereby form a ring.

R_{f1} to R_{f3} may be linked to each other to thereby form a ring. As the formed ring, there can be mentioned a (halo)cycloalkyl ring, a (halo)aryl ring or the like.

As the (halo)alkyl groups represented by R_{f1} to R_{f3}, there can be mentioned, for example, the alkyl groups mentioned above as being represented by Zₖₐ₁ and structures resulting from halogenation thereof.

As the (per)halocycloalkyl groups and (per)haloaryl groups represented by R_{f1} to R_{f3} or contained in the ring formed by the mutual linkage of R_{f2} and R_{f3}, there can be mentioned, for example, structures resulting from halogenation of the cycloalkyl groups mentioned above as being represented by Zₖₐ₁, preferably fluorocycloalkyl groups of the formula —C₍ₙ₎F₍₂ₙ₋₂₎H and perfluoroaryl groups of the formula —C₍ₙ₎F₍ₙ₋₁₎. The number of carbon atoms, n, is not particularly limited. Preferably, however, it is in the range of 5 to 13, more preferably 6.

As preferred rings that may be formed by the mutual linkage of at least two of R_{ew1}, R_{ew2} and Y_{ew1}, there can be mentioned cycloalkyl groups and heterocyclic groups. Preferred heterocyclic groups are lactone ring groups. As the lactone rings, there can be mentioned, for example, the structures of formulae (KA-1-1) to (KA-1-17) above.

The repeating unit (by) may contain two or more of the partial structures of general formula (KA-1), or two or more of the partial structures of general formula (KB-1), or both any one of the partial structures of general formula (KA-1) and any one of the partial structures of general formula (KB-1).

A part or the whole of any of the partial structures of general formula (KA-1) may double as the electron withdrawing group represented by Y¹ or Y² of general formula (KB-1). For example, when X of general formula (KA-1) is a carboxylic ester group, the carboxylic ester group can function as the electron withdrawing group represented by Y¹ or Y² of general formula (KB-1).

When the repeating unit (by) corresponds to the above-mentioned repeating unit (b*) or repeating unit (b″) and contains any of the partial structures of general formula (KA-1), it is preferred for the partial structures of general formula (KA-1) to be a partial structure in which the polarity conversion group is expressed by —COO— appearing in the structures of general formula (KA-1).

The repeating unit (by) can be a repeating unit with the partial structure of general formula (KY-0) below.

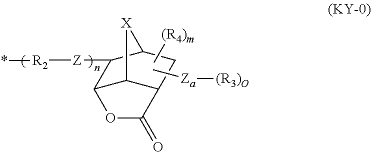

In general formula (KY-0),

R₂ represents a chain- or cycloalkylene group,

provided that two or more R₂s may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of formula R—C(═O)— or R—C(═O)O— in which R is an alkyl group or a cycloalkyl group. Two or more R₄s may be identical to or different from each other, and may be bonded to each other to thereby form a ring.

X represents an alkylene group, an oxygen atom or a sulfur atom.

Each of Z and Za independently represents a single bond, an ether bond, an ester bond, an amido bond, a urethane bond or a urea bond. When there are a plurality of Zs or Zas, they may be identical to or different from each other.

In the formula, * represents the bonding hand to the principal chain or side chain of the resin;

O is the number of substituents, being an integer of 1 to 7;

m is the number of substituents, being an integer of 0 to 7; and

n is the number of repetitions, being an integer of 0 to 5.

The structure —R₂—Z— is preferably the structure of formula —(CH₂)l-COO— in which l is an integer of 1 to 5.

With respect to the chain- or cycloalkylene group represented by R₂, the preferred number of carbon atoms and particular examples are as mentioned above in connection with the chain- or cycloalkylene group represented by Z₂ of general formula (bb).

The number of carbon atoms of the linear, branched or cyclic hydrocarbon group represented by R₃ is preferably in the range of 1 to 30, more preferably 1 to 20 when the hydrocarbon group is linear; is preferably in the range of 3 to 30, more preferably 3 to 20 when the hydrocarbon group is branched; and is in the range of 6 to 20 when the hydrocarbon group is cyclic. As particular examples of the R₃ groups, there can be mentioned the above particular examples of the alkyl and cycloalkyl groups represented by Zₖₐ₁.

With respect to the alkyl groups and cycloalkyl groups represented by R₄ or R, the preferred number of carbon atoms and particular examples are as mentioned above in connection with the alkyl groups and cycloalkyl groups represented by Zₖₐ₁.

The acyl group represented by R₄ preferably has 1 to 6 carbon atoms. As such, there can be mentioned, for example, a formyl group, an acetyl group, a propionyl group, a butyryl group, an isobutyryl group, a valeryl group, a pivaloyl group or the like.

As the alkyl moiety of the alkoxy group and alkoxycarbonyl group represented by R₄, there can be mentioned a linear, branched or cyclic alkyl moiety. With respect to the alkyl moiety, the preferred number of carbon atoms and particular examples are as mentioned above in connection with the alkyl groups and cycloalkyl groups represented by Zₖₐ₁.

With respect to the alkylene group represented by X, there can be mentioned a chain- or cycloalkylene group. The preferred number of carbon atoms and particular examples thereof are as mentioned above in connection with the chain- or cycloalkylene group represented by R₂.

Moreover, as particular structures of the repeating units (by), there can be mentioned the repeating units with the following partial structures.

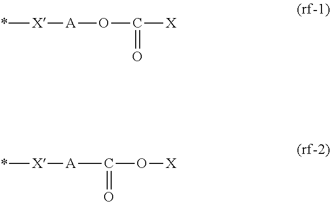

In general formulae (rf-1) and (rf-2),

X′ represents an electron withdrawing substituent, preferably a carbonyloxy group, an oxycarbonyl group, an alkylene group substituted with a fluorine atom or a cycloalkylene group substituted with a fluorine atom.

A represents a single bond or a bivalent connecting group of the formula —C(Rx)(Ry)—. In the formula, each of Rx and Ry independently represents a hydrogen atom, a fluorine atom, an alkyl group (preferably having 1 to 6 carbon atoms, optionally substituted with a fluorine atom) or a cycloalkyl group (preferably having 5 to 12 carbon atoms, optionally substituted with a fluorine atom). Each of Rx and Ry is preferably a hydrogen atom, an alkyl group or an alkyl group substituted with a fluorine atom.

X represents an electron withdrawing group. As particular examples thereof, there can be mentioned the electron withdrawing groups set forth above as being represented by Y¹ and Y². X is preferably a fluoroalkyl group, a fluorocycloalkyl group, an aryl group substituted with fluorine or a fluoroalkyl group, an aralkyl group substituted with fluorine or a fluoroalkyl group, a cyano group or a nitro group.

* represents a bonding hand to the principal chain or a side chain of the resin, namely, a bonding hand bonded to the principal chain of the resin through a single bond or a connecting group.

When X′ is a carbonyloxy group or an oxycarbonyl group, A is not a single bond.

The receding contact angle with water of the resin composition film after alkali development can be decreased by the polarity conversion effected by the decomposition of the polarity conversion group by the action of an alkali developer. The decrease of the receding contact angle between water and the film after alkali development is preferred from the viewpoint of the inhibition of development defects.

The receding contact angle with water of the resin composition film after alkali development is preferably 50° or less, more preferably 40° or less, further more preferably 35° or less and most preferably 30° or less at 23±3° C. in a humidity of 45±5%.

The receding contact angle refers to a contact angle determined when the contact line at a droplet-substrate interface draws back. It is generally known that the receding contact angle is useful in the simulation of droplet mobility in a dynamic condition. In brief, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

The rate of hydrolysis of the hydrophobic resin in an alkali developer is preferably 0.001 nm/sec or greater, more preferably 0.01 nm/sec or greater, further more preferably 0.1 nm/sec or greater and most preferably 1 nm/sec or greater.

Herein, the rate of hydrolysis of the hydrophobic resin in an alkali developer refers to the rate of decrease of the thickness of a resin film formed from only the hydrophobic resin in 23° C. TMAH (aqueous solution of tetramethylammonium hydroxide) (2.38 mass %)

It is preferred for the repeating unit (by) to be a repeating unit containing at least two polarity conversion groups.

When the repeating unit (by) contains at least two polarity conversion groups, it is preferred for the repeating unit to contain a group with any of the partial structures having two polarity conversion groups of general formula (KY-1) below. When the structure of general formula (KY-1) has no bonding hand, a group with a mono- or higher-valent group resulting from the removal of at least any arbitrary one of the hydrogen atoms contained in the structure is referred to.

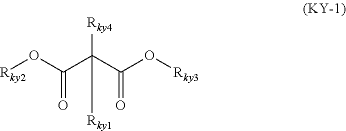

In general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. Alternatively, both R_{ky1} and R_{ky4} may be bonded to the same atom to thereby form a double bond. For example, both R_{ky1} and R_{ky4} may be bonded to the same oxygen atom to thereby form a part (═O) of a carbonyl group.

Each of R_{ky2} and R_{ky3} independently represents an electron withdrawing group. Alternatively, R_{ky1} and R_{ky2} are linked to each other to thereby form a lactone structure, while R_{ky3} is an electron withdrawing group. The formed lactone structure is preferably any of the above-mentioned structures (KA-1-1) to (KA-1-17). As the electron withdrawing group, there can be mentioned any of the same groups as mentioned above with respect to Y¹ and Y² of general formula (KB-1). This electron withdrawing group is preferably a halogen atom, or any of the halo(cyclo)alkyl groups or haloaryl groups of the formula —C(R_{f1})(R_{f2})—R_{f3} above. Preferably, R_{ky3} is a halogen atom, or any of the halo(cyclo)alkyl groups or haloaryl groups of the formula —C(R_{f1})(R_{f2})—R_{f3} above, while R_{ky2} is either linked to R_{ky1} to thereby form a lactone ring, or an electron withdrawing group containing no halogen atom.

R_{ky1}, R_{ky2} and R_{ky4} may be linked to each other to thereby form a monocyclic or polycyclic structure.

As R_{ky1} and R_{ky4}, there can be mentioned, for example, the same groups as set forth above with respect to Zₖₐ₁ of general formula (KA-1).

The lactone rings formed by the mutual linkage of R_{ky1} and R_{ky2} preferably have the structures of formulae (KA-1-1) to (KA-1-17) above. As the electron withdrawing groups, there can be mentioned those mentioned above as being represented by Y¹ and Y² of general formula (KB-1) above.

It is more preferred for the structure of general formula (KY-1) to be the structure of general formula (KY-2) below. The structure of general formula (KY-2) refers to a group with a mono- or higher-valent group resulting from the removal of at least any arbitrary one of the hydrogen atoms contained in the structure.

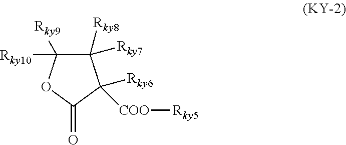

In formula (KY-2),

each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group.

At least two of R_{ky6} to R_{ky10} may be linked to each other to thereby form a monocyclic or polycyclic structure.

R_{ky5} represents an electron withdrawing group. As the electron withdrawing group, there can be mentioned any of the same groups as set forth above with respect to Y¹ and Y². This electron withdrawing group is preferably a halogen atom, or any of the halo(cyclo)alkyl groups or haloaryl groups of the formula —C(R_{f1})(R_{f2})—R_{f3} above.

As R_{ky5} to R_{ky10}, there can be mentioned, for example, the same groups as set forth above with respect to Zₖₐ₁ of formula (KA-1).

It is more preferred for the structure of formula (KY-2) to be the partial structure of general formula (KY-3) below.

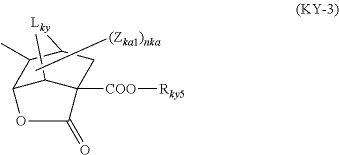

In formula (KY-3), Zₖₐ₁ and nka are as defined above in connection with general formula (KA-1). R_{ky5} is as defined above in connection with formula (KY-2).

L_{ky} represents an alkylene group, an oxygen atom or a sulfur atom. As the alkylene group represented by L_{ky}, there can be mentioned a methylene group, an ethylene group or the like. L_{ky} is preferably an oxygen atom or a methylene group, more preferably a methylene group.

The repeating units (b) are not limited as long as they are derived by polymerization, such as addition polymerization, condensation polymerization or addition condensation. Preferred repeating units are those obtained by the addition polymerization of a carbon to carbon double bond. As such repeating units, there can be mentioned, for example, acrylate repeating units (including the family having a substituent at the α- and/or β-position), styrene repeating units (including the family having a substituent at the α- and/or β-position), vinyl ether repeating units, norbornene repeating units, repeating units of maleic acid derivatives (maleic anhydride, its derivatives, maleimide, etc.) and the like. Of these, acrylate repeating units, styrene repeating units, vinyl ether repeating units and norbornene repeating units are preferred. Acrylate repeating units, vinyl ether repeating units and norbornene repeating units are more preferred. Acrylate repeating units are most preferred.

When the repeating unit (by) is a repeating unit containing at least either a fluorine atom or a silicon atom (namely, corresponding to the above repeating unit (b′) or (b″)), as the partial structure containing a fluorine atom within the repeating unit (by), there can be mentioned any of those set forth in connection with the aforementioned repeating unit containing at least either a fluorine atom or a silicon atom, preferably the groups of general formulae (F2) to (F4) above. As the partial structure containing a silicon atom within the repeating unit (by), there can be mentioned any of those set forth in connection with the aforementioned repeating unit containing at least either a fluorine atom or a silicon atom, preferably the groups of general formulae (CS-1) to (CS-3) above.

The content of repeating unit (by) in the hydrophobic resin, based on all the repeating units of the hydrophobic resin, is preferably in the range of 10 to 100 mol %, more preferably 20 to 99 mol %, further more preferably 30 to 97 mol % and most preferably 40 to 95 mol %.

Particular examples of the repeating units (by) containing a group whose solubility in an alkali developer is increased are shown below, which however in no way limit the scope of the repeating units. Further, the above-mentioned particular examples of the repeating units (a3) introduced in the resin (B) can also be mentioned as particular examples of the repeating units (by).

In the following particular examples, Ra represents a hydrogen atom, a fluorine atom, a methyl group or a trifluoromethyl group.

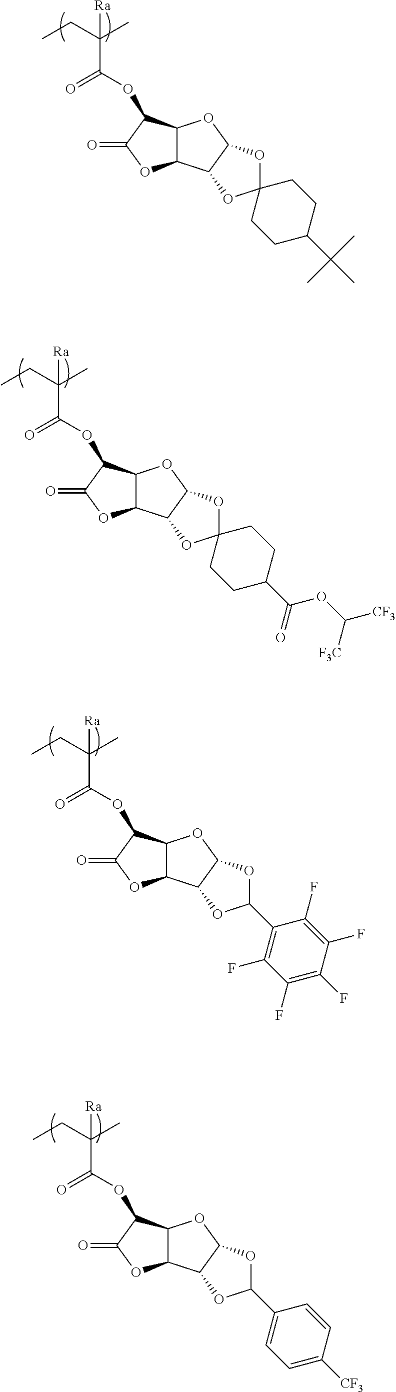

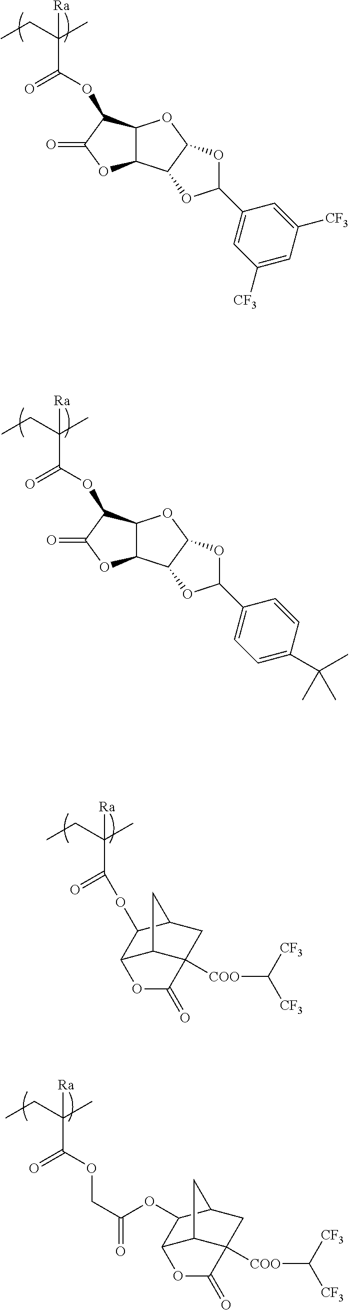

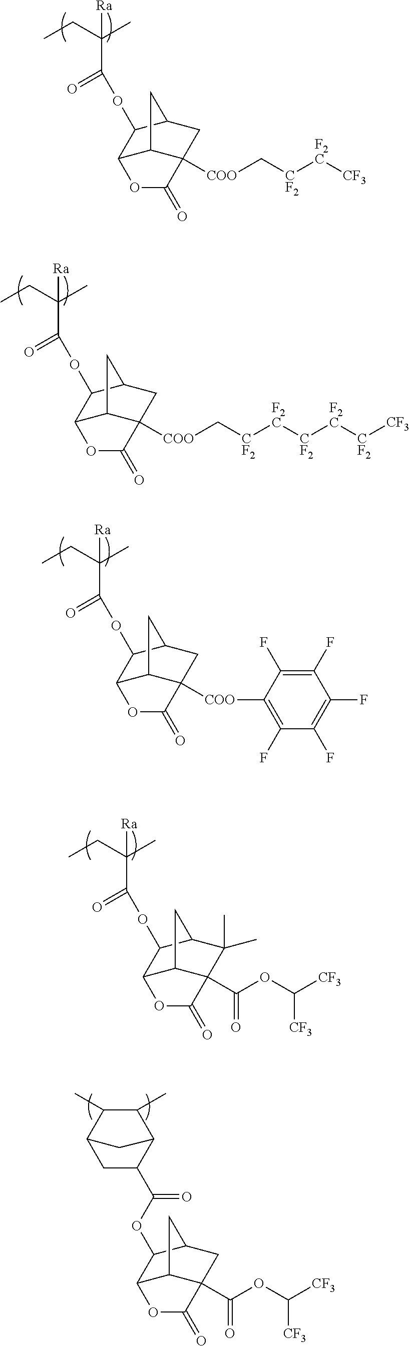

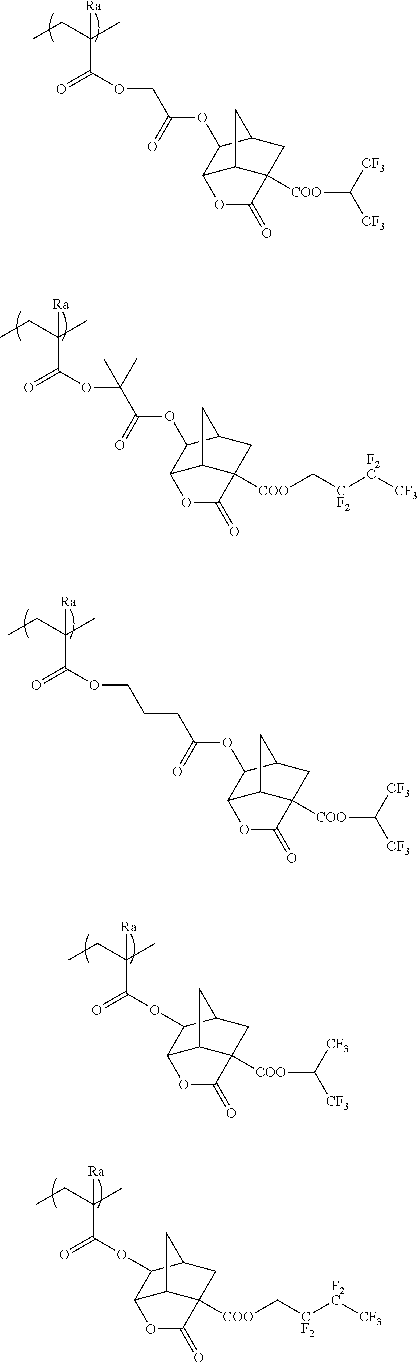

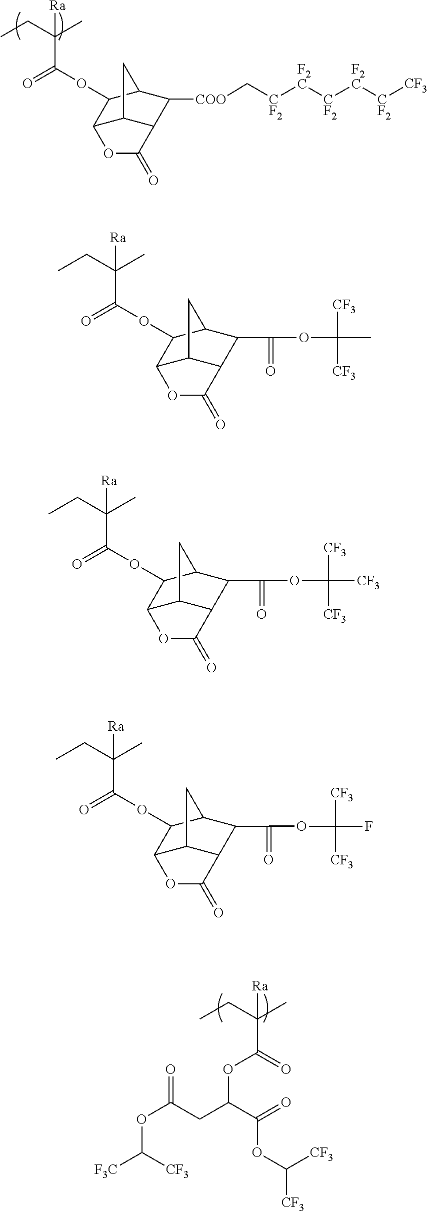

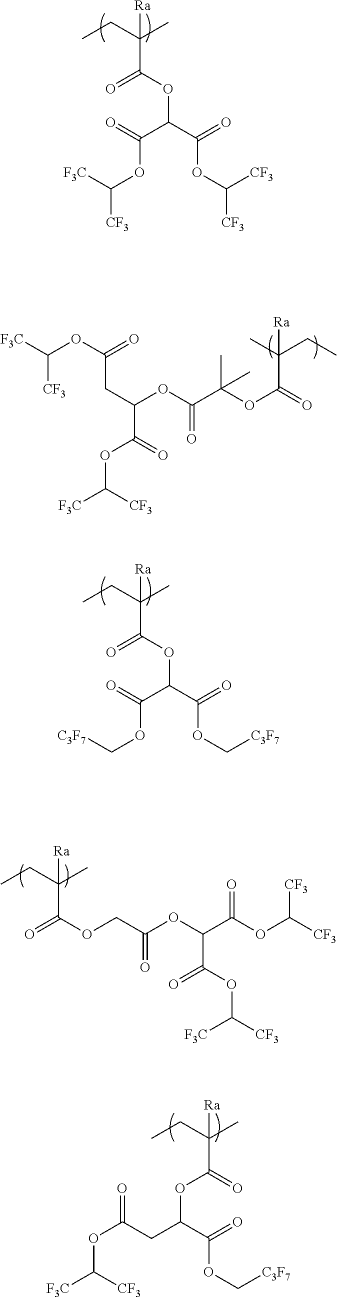

The synthesis of the monomers corresponding to the above-mentioned repeating units (by) each containing a polarity conversion group (y) can be carried out with reference to the methods described in, for example, International Publication No. 2010/067905.

The repeating unit (bz) containing a group that when acted on by an acid, is decomposed (z), contained in the hydrophobic resin can be the same as any of the repeating units each containing an acid-decomposable group set forth above in connection with the resin (B).

When the repeating unit (bz) is a repeating unit containing at least either a fluorine atom or a silicon atom (namely, when corresponding to the above-mentioned repeating unit (b′) or repeating unit (b″)), the partial structure containing a fluorine atom contained in the repeating unit (bz) can be the same as set forth above in connection with the repeating unit containing at least either a fluorine atom or a silicon atom. As such, preferably, there can be mentioned any of the groups of general formulae (F2) to (F4) above. Also in that instance, the partial structure containing a silicon atom contained in the repeating unit (bz) can be the same as set forth above in connection with the repeating unit containing at least either a fluorine atom or a silicon atom. As such, preferably, there can be mentioned any of the groups of general formulae (CS-1) to (CS-3) above.

The content of repeating unit (bz) containing a group that when acted on by an acid, is decomposed (z) in the hydrophobic resin is preferably in the range of 1 to 80 mol %, more preferably 10 to 80 mol % and further more preferably 20 to 60 mol %, based on all the repeating units of the hydrophobic resin.

The repeating unit (b) containing at least one group selected from the group consisting of the above groups (x) to (z) has been described. The content of repeating unit (b) in the hydrophobic resin is preferably in the range of 1 to 98 mol %, more preferably 3 to 98 mol %, further more preferably 5 to 97 mol % and most preferably 10 to 95 mol %, based on all the repeating units of the hydrophobic resin.

The content of repeating unit (b′) in the hydrophobic resin is preferably in the range of 1 to 100 mol %, more preferably 3 to 99 mol %, further more preferably 5 to 97 mol % and most preferably 10 to 95 mol %, based on all the repeating units of the hydrophobic resin.

The content of repeating unit (b*) in the hydrophobic resin is preferably in the range of 1 to 90 mol %, more preferably 3 to 80 mol %, further more preferably 5 to 70 mol % and most preferably 10 to 60 mol %, based on all the repeating units of the hydrophobic resin. The content of repeating unit containing at least either a fluorine atom or a silicon atom used in combination with the repeating unit (b*) is preferably in the range of 10 to 99 mol %, more preferably 20 to 97 mol %, further more preferably 30 to 95 mol % and most preferably 40 to 90 mol %, based on all the repeating units of the hydrophobic resin.

The content of repeating unit (b″) in the hydrophobic resin is preferably in the range of 1 to 100 mol %, more preferably 3 to 99 mol %, further more preferably 5 to 97 mol % and most preferably 10 to 95 mol %, based on all the repeating units of the hydrophobic resin.

The hydrophobic resin may further contain any of the repeating units represented by general formula (CIII) below.

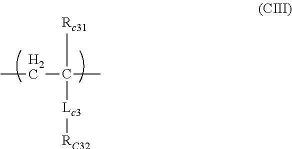

In general formula (CIII),

R_{c31} represents a hydrogen atom, an alkyl group (optionally substituted with a fluorine atom and the like), a cyano group or a group of the formula —CH₂—O—R_{ac2} in which R_{ac2} represents a hydrogen atom, an alkyl group or an acyl group. R_{c31} is preferably a hydrogen atom, a methyl group, a hydroxymethyl group, or a trifluoromethyl group, more preferably a hydrogen atom or a methyl group.

R_{c32} represents a group containing an alkyl group, a cycloalkyl group, an alkenyl group, a cycloalkenyl group, or an aryl group. These groups may be substituted with fluorine atom and/or silicon atom.

L_{c3} represents a single bond or a bivalent connecting group.

In general formula (CIII), the alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms such as a phenyl group or a naphthyl group. These groups may have one or more substituents.

Preferably, R_{c32} represents an unsubstituted alkyl group or an alkyl group substituted with a fluorine atom.

As the bivalent connecting group represented by L_{c3}, an alkylene group (preferably having 1 to 5 carbon atoms), an oxy group, a phenylene group, or an ester bond (a group represented by —COO—) can be exemplified.

The hydrophobic resin may further contain any of the repeating units represented by general formula (BII-AB) below.

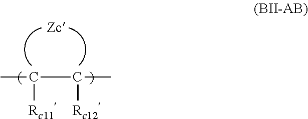

In formula (BII-AB),

each of R_{c11}′ and R_{c12}′ independently represents a hydrogen atom, a cyano group, a halogen atom or an alkyl group.

Zc′ represents an atomic group required for forming an alicyclic structure in cooperation with two carbon atoms (C—C) to which R_{c11}′, and R_{c12}′ are respectively bonded.

When any of the groups contained in the repeating unit represented by general formulae (III) or (BII-AB) is substituted with a group containing a fluorine atom or a silicone atom, the repeating unit is also corresponding to the aforementioned repeating unit containing at least either a fluorine atom or a silicon atom.

Specific examples of the repeating unit represented by general formulae (III) or (BII-AB) will be shown below, which however in no way limit the scope of the present invention. In the formulae, Ra represents H, CH₃, CH₂OH, CF₃ or CN. Note that the repeating unit in which Ra represents CF₃ also corresponds to the repeating unit containing at least either a fluorine atom or a silicon atom.

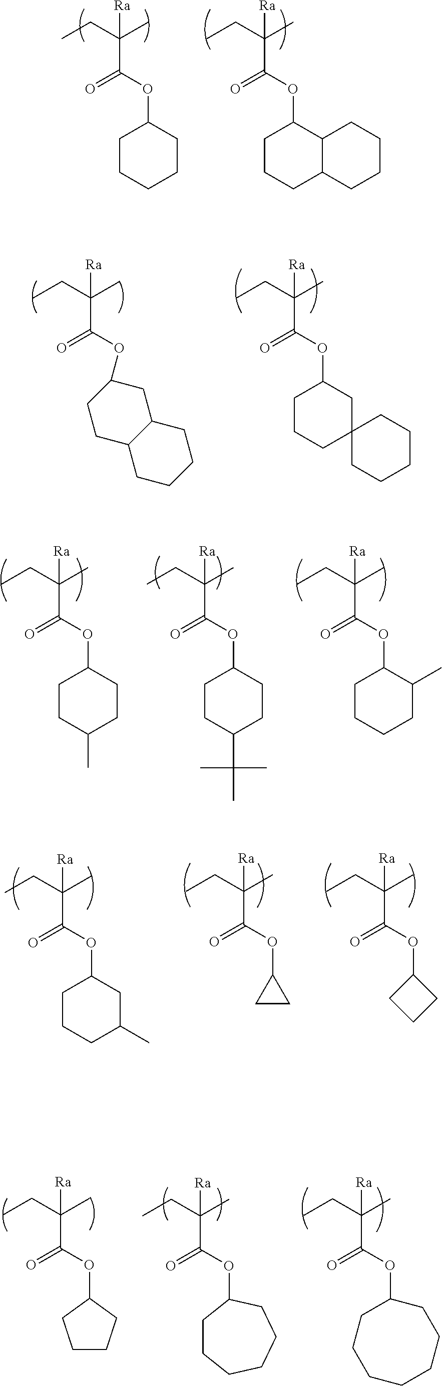

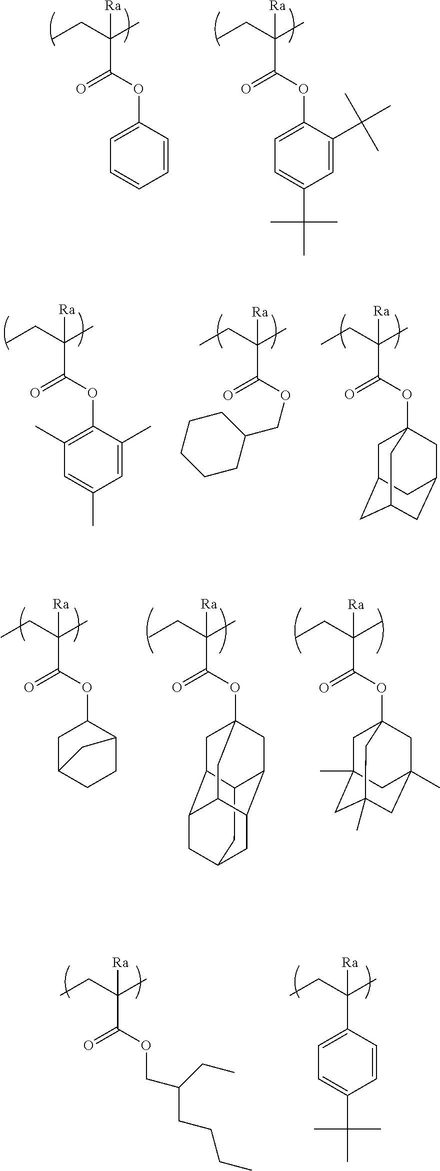

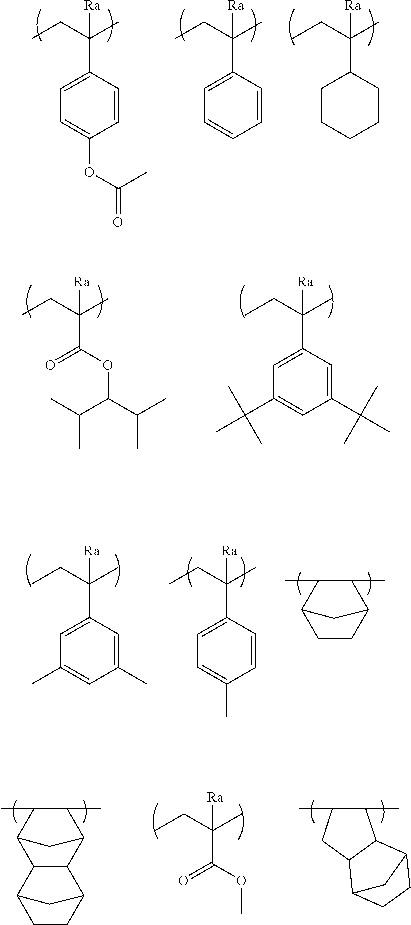

Impurities such as metals in the hydrophobic resin should naturally be of low quantity as in the resin (B). The content of residual monomers and oligomer components is preferably in the range of 0 to 10 mass %, more preferably 0 to 5 mass %, and still more preferably 0 to 1 mass %. Accordingly, there can be obtained a resist composition being free from in-liquid foreign matters and a change in sensitivity, etc. over time. From the viewpoint of resolving power, resist pattern profile, side wall of resist pattern, roughness, etc., the molecular weight distribution (Mw/Mn, also referred to as the degree of dispersal) thereof is preferably in the range of 1 to 3, more preferably 1 to 2, still more preferably 1 to 1.8, and most preferably 1 to 1.5.

A variety of commercially available products can be used as the hydrophobic resin, and also the resin can be synthesized in accordance with conventional methods (for example, by radical polymerization). As general synthesizing methods, a batch polymerization method in which a monomer species and an initiator are dissolved in a solvent and heated to carry out polymerization and a dropping polymerization method in which a solution of monomer species and initiator is dropped into a hot solvent over a period of 1 to 10 hours can be exemplified. Of these, the dropping polymerization method is preferred.

The reaction solvent, polymerization initiator, reaction conditions (temperature, concentration, etc.) and purification method after reaction are the same as described above in connection with the resin (B).

Specific examples of the hydrophobic resins will be shown below. The following Table 1 shows the molar ratio of individual repeating units (corresponding to individual repeating units in order from the left), weight average molecular weight, and degree of dispersal with respect to each of the resins.

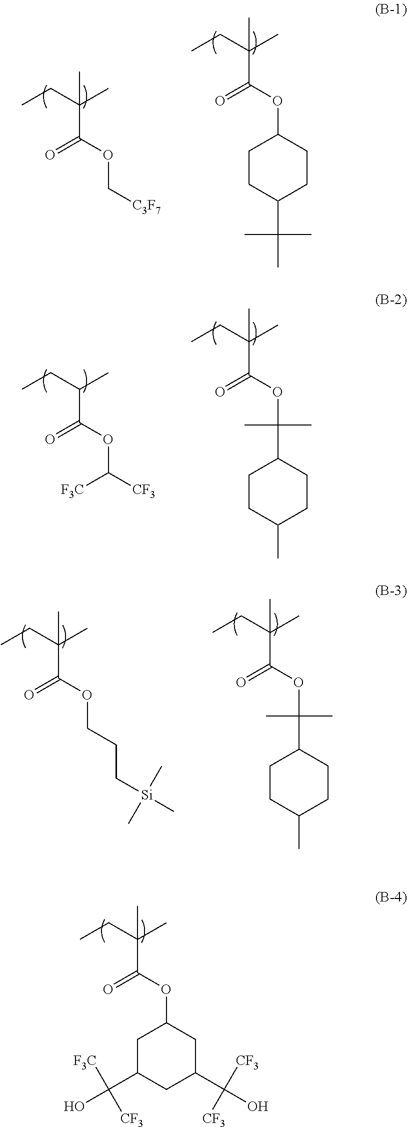

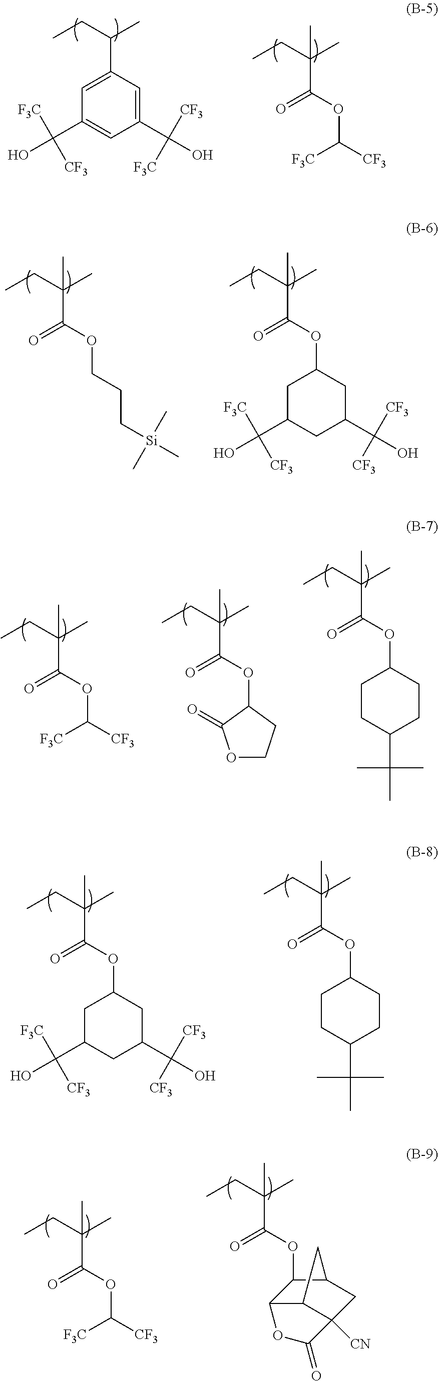

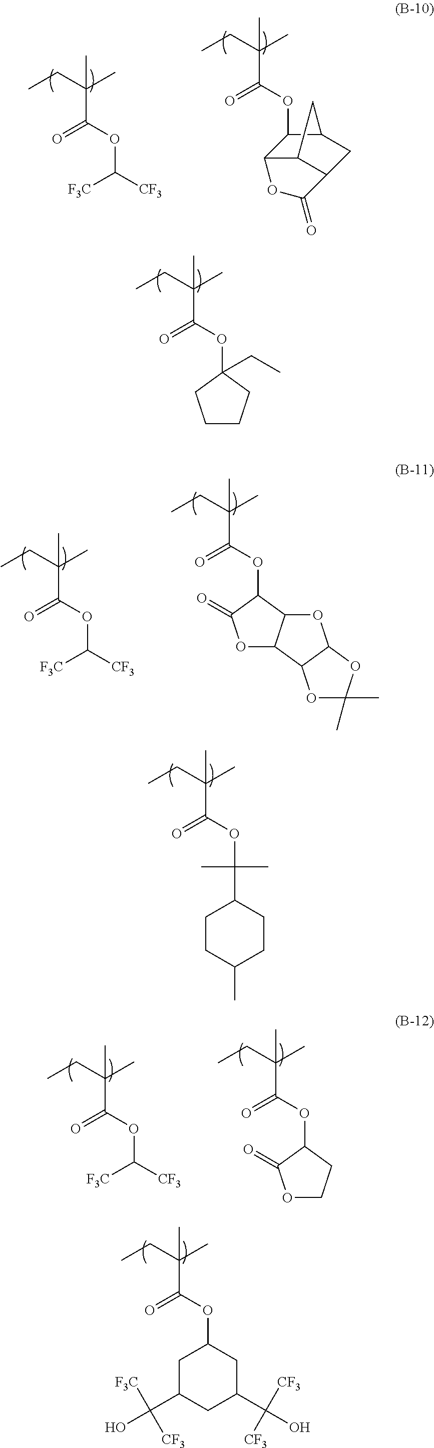

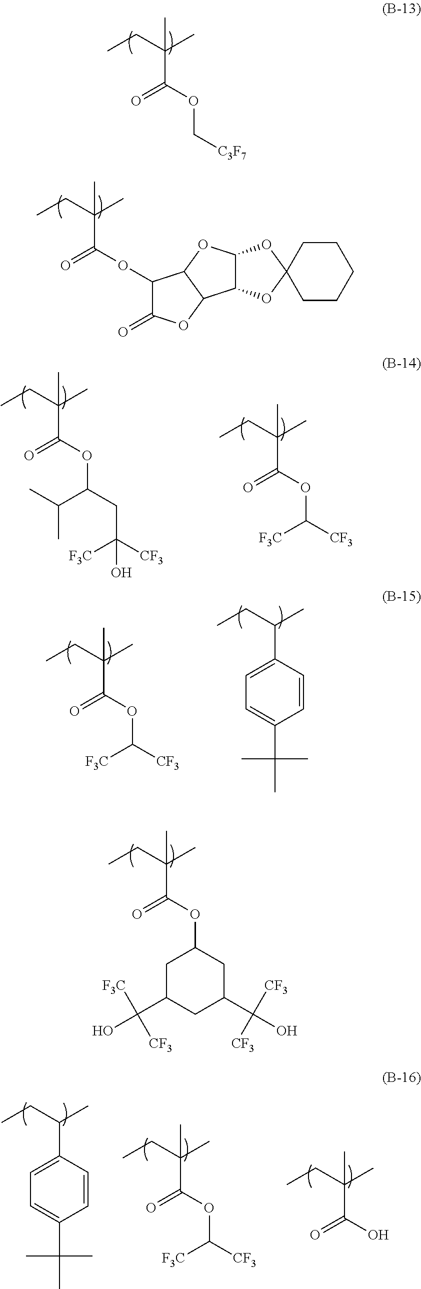

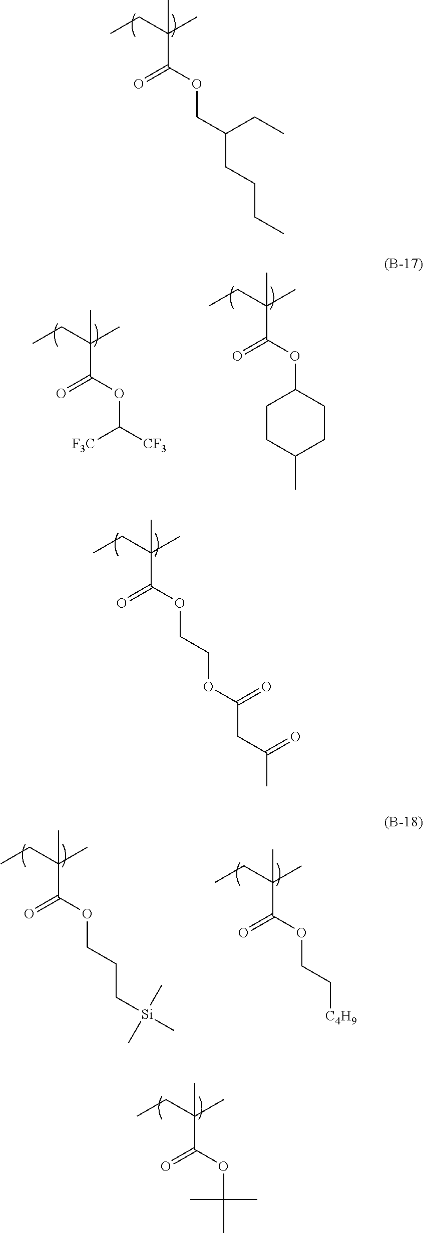

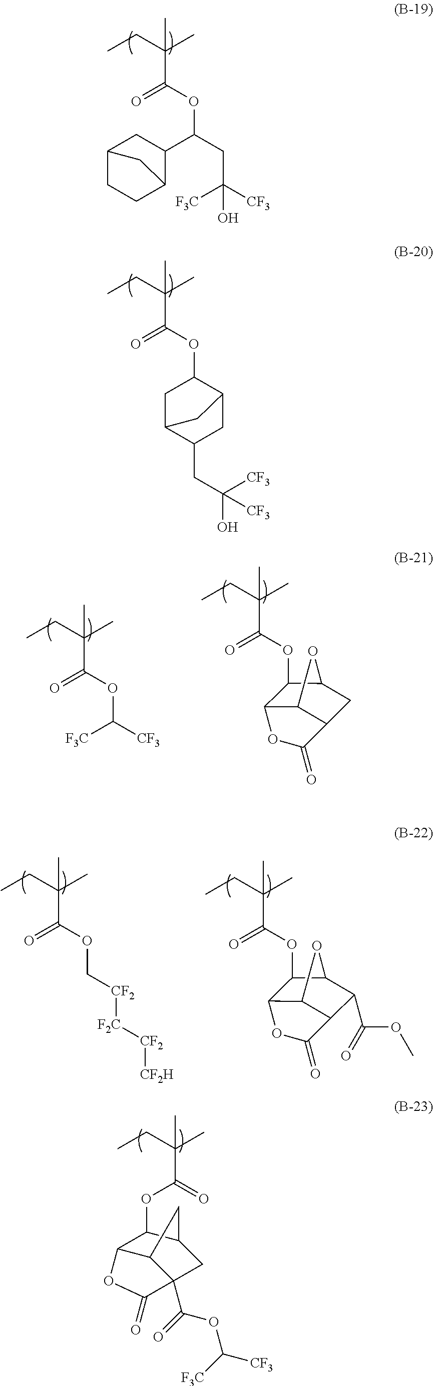

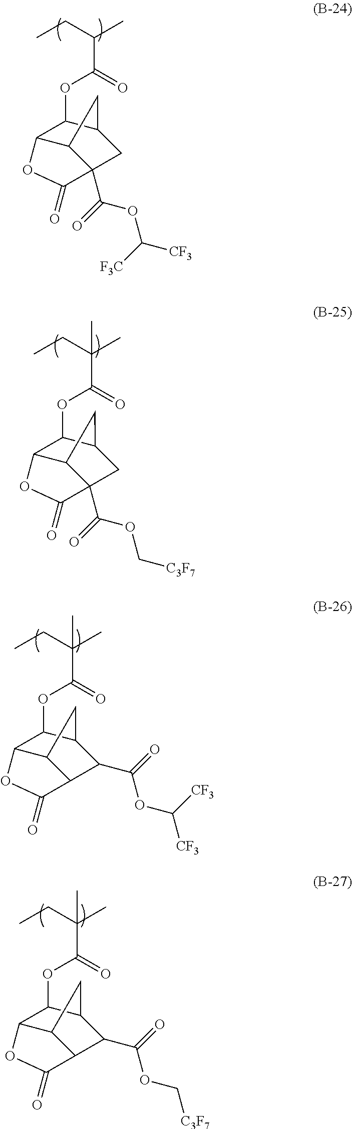

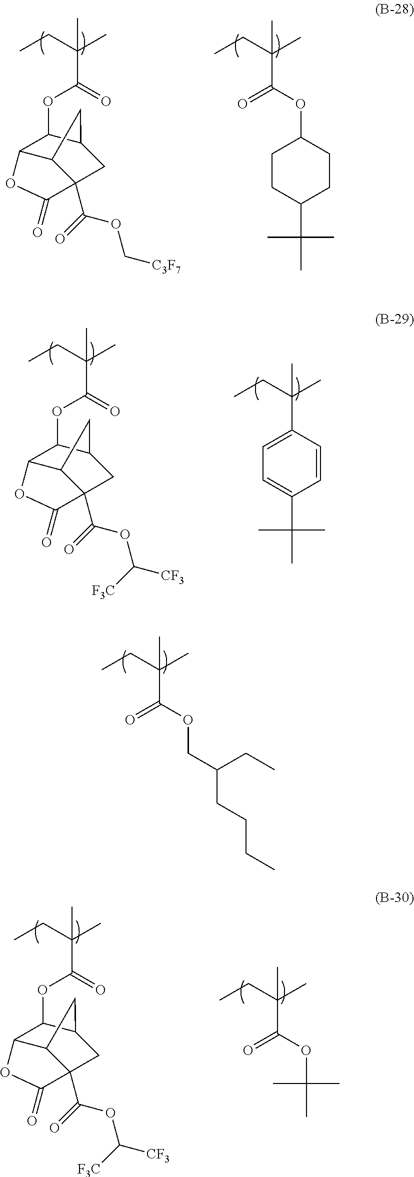

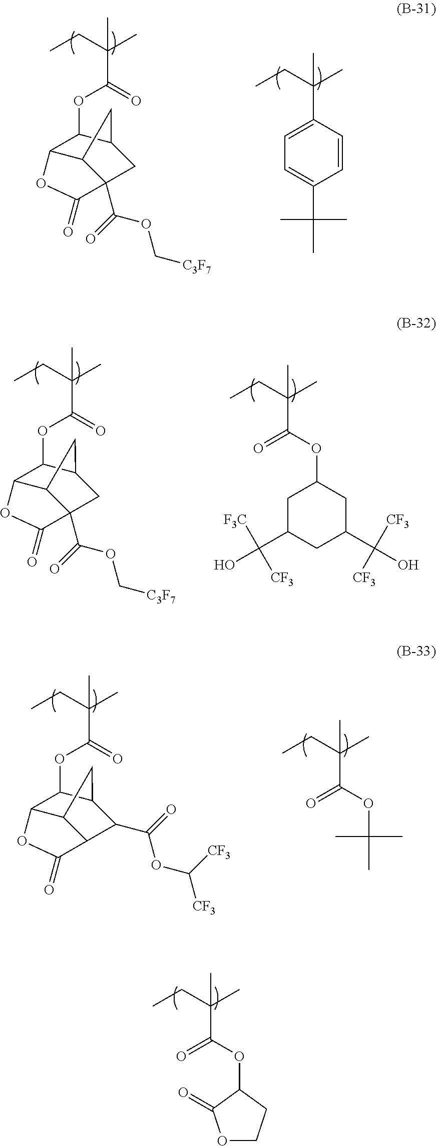

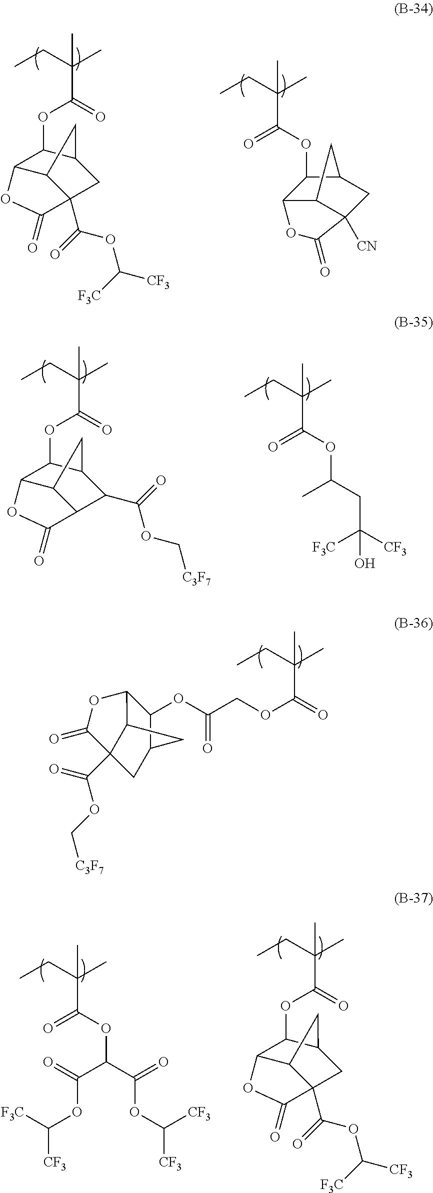

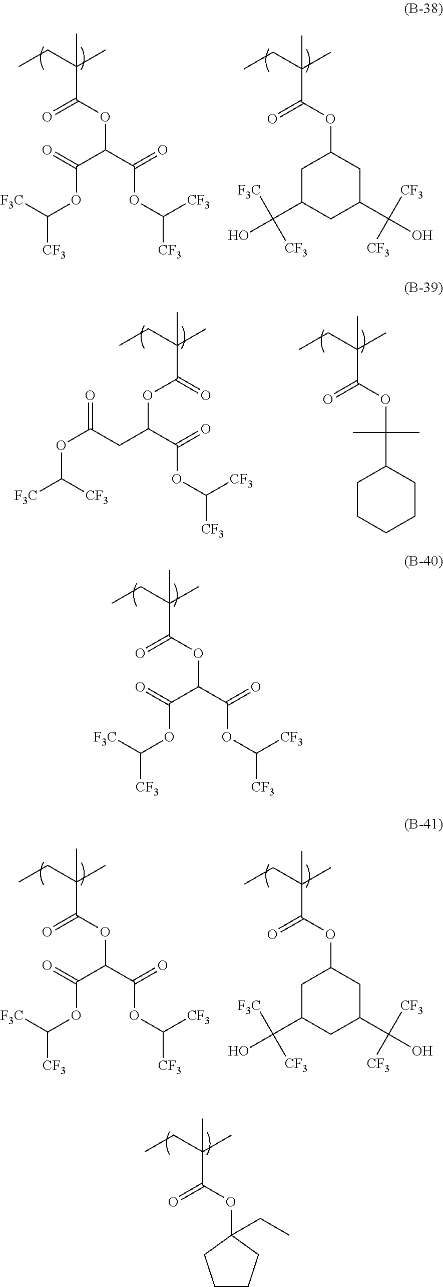

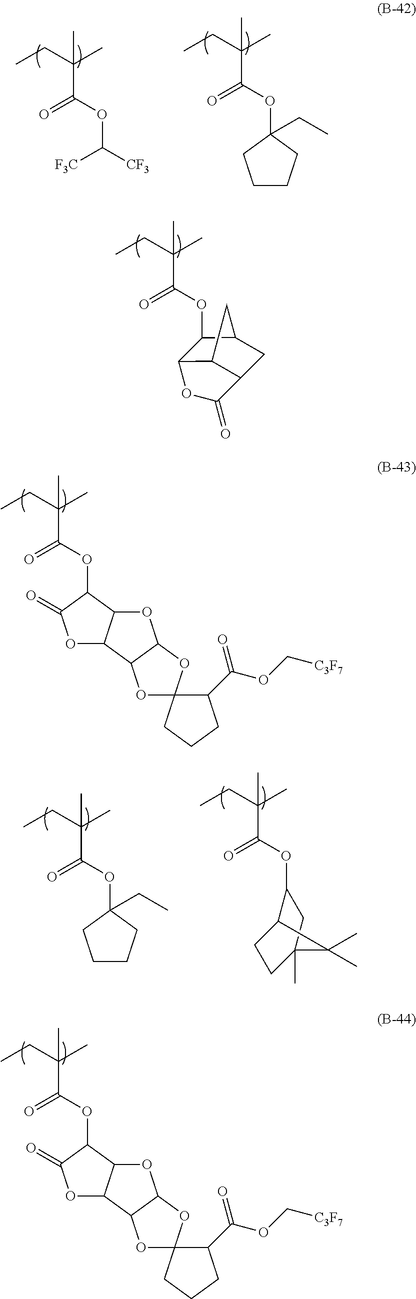

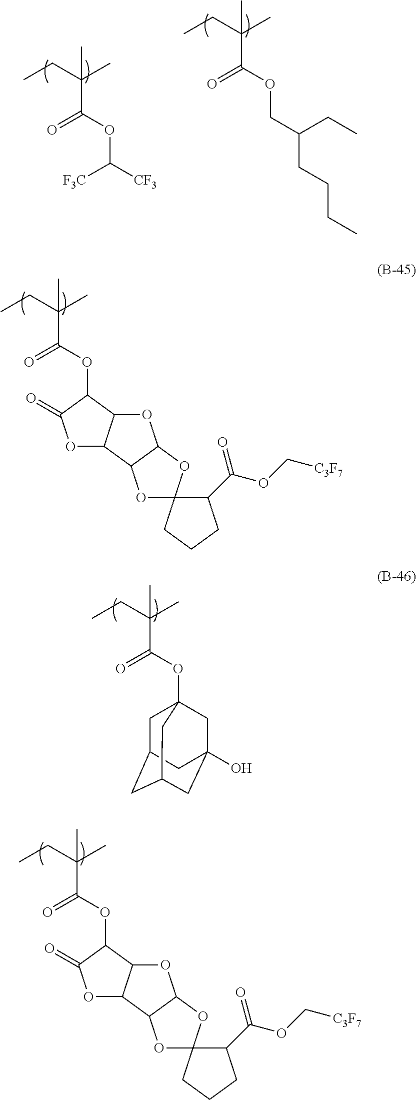

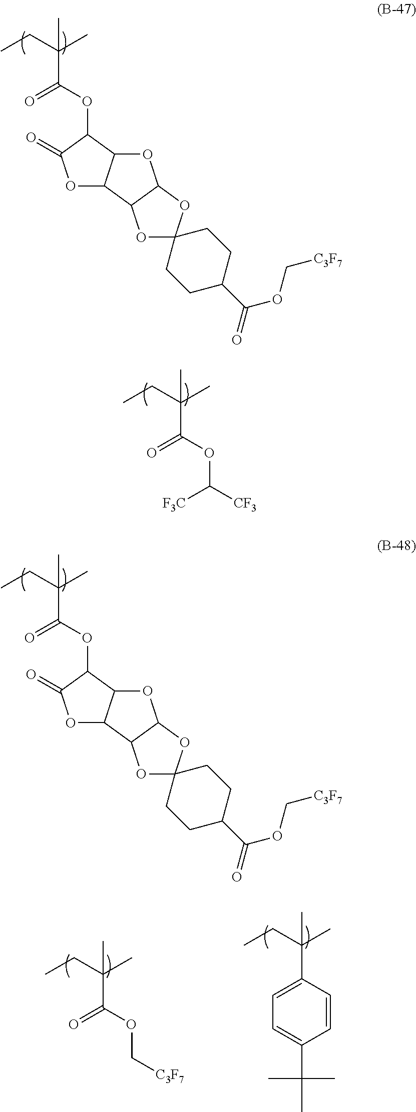

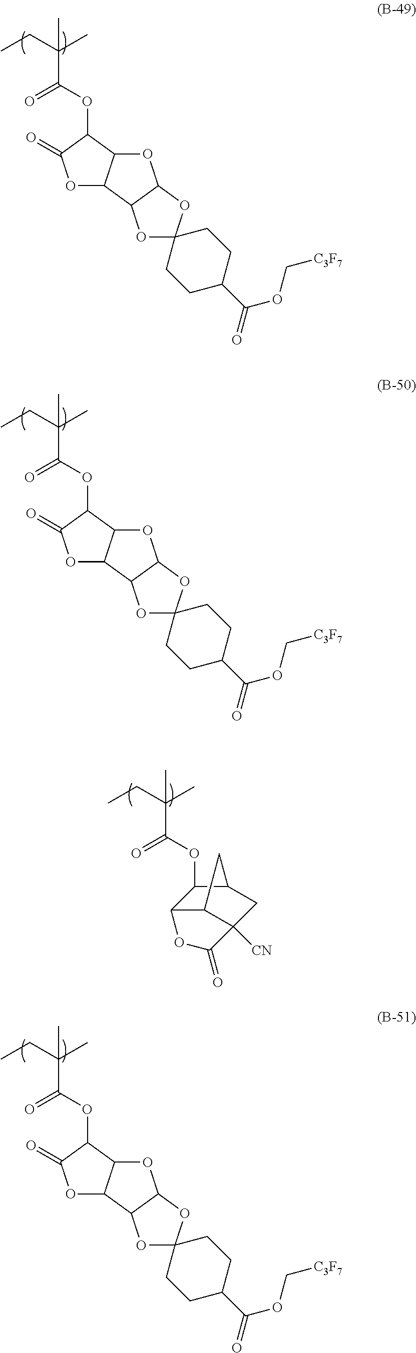

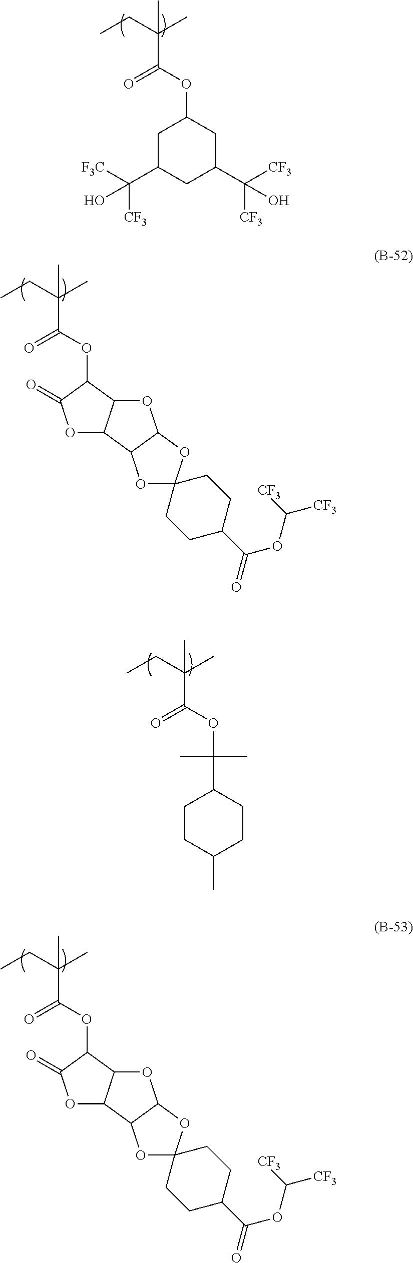

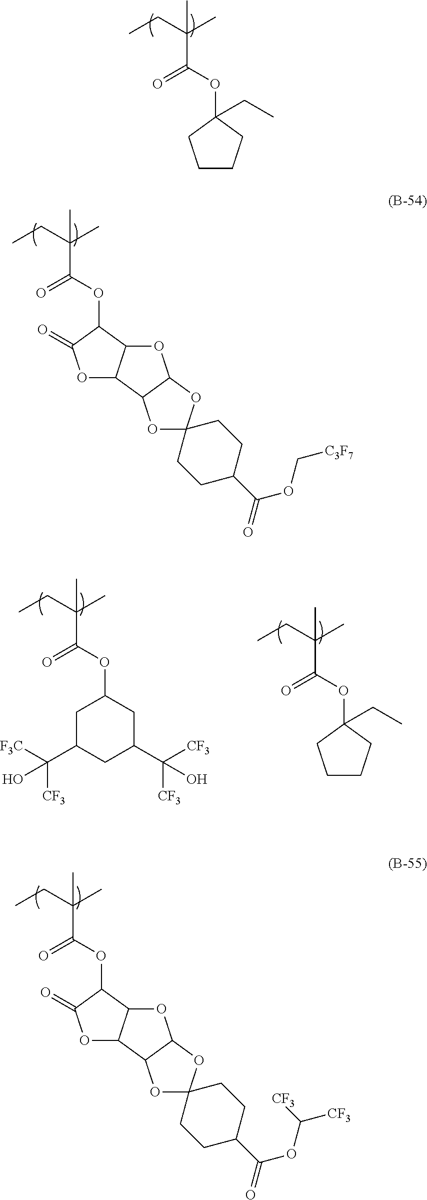

TABLE 1

| | Composition | | |
|---|---|---|---|
| | (mol %) | Mw | Mw/Mn |
| Polymer | | | |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| Resin | | | |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

When the hydrophobic resin containing at least either a fluorine atom or a silicon atom is contained, the hydrophobic resin is unevenly distributed in a surface layer portion of the film formed from the composition of the present invention. When the immersion medium is water, the receding contact angle of the film surface with respect to water is increased so that the immersion-water tracking properties can be enhanced.

The receding contact angle of the film of the composition of the present invention after the bake of the coating but prior to the exposure thereof is preferably in the range of 60° to 90°, more preferably 65° or greater, further more preferably 70° or greater and most preferably 75° or greater at the exposure temperature, generally room temperature 23±3° C. in a humidity of 45±5%.

Although the hydrophobic resin is unevenly localized on any interface, as different from the surfactant, the resin does not necessarily have to have a hydrophilic group in its molecule and does not need to contribute toward uniform mixing of polar/nonpolar substances.

In the operation of liquid immersion exposure, it is needed for the liquid for liquid immersion to move on a wafer while tracking the movement of an exposure head involving high-speed scanning on the wafer and thus forming an exposure pattern. Therefore, the contact angle of the liquid for liquid immersion with respect to the resist film in dynamic condition is important, and it is required for the resist composition to be capable of tracking the high-speed scanning of the exposure head without leaving droplets.

The hydrophobic resin, due to its hydrophobicity, is likely to cause the blob defect and development residue (scum) after alkali development to deteriorate. When use is made of a hydrophobic resin having three or more polymer chains via at least one branch portion, as compared with a linear-chain resin, the alkali dissolution rate is increased to thereby improve the development residue (scum) and blob defect performance.

When the hydrophobic resin contains fluorine atoms, the content of the fluorine atoms based on the molecular weight of the hydrophobic resin is preferably in the range of 5 to 80 mass %, and more preferably 10 to 80 mass %. The repeating unit containing fluorine atoms preferably exists in the hydrophobic resin in an amount of 10 to 100 mol % more preferably 30 to 100 mol %.

When the hydrophobic resin contains silicon atoms, the content of the silicon atoms based on the molecular weight of the hydrophobic resin is preferably in the range of 2 to 50 mass %, more preferably 2 to 30 mass %. The repeating unit containing silicon atoms preferably exists in the hydrophobic resin in an amount of 10 to 90 mol %, more preferably 20 to 80 mol %.

The weight average molecular weight of the hydrophobic resin is preferably in the range of 1000 to 100,000, more preferably 2000 to 50,000 and further more preferably 3000 to 35,000. Herein, the weight average molecular weight of the resin refers to the polystyrene-equivalent molecular weight measured by GPC (carrier: tetrahydrofuran (THF)).

The content of hydrophobic resin in the actinic-ray- or radiation-sensitive resin composition can be regulated so that the receding contact angle of the actinic-ray- or radiation-sensitive resin film falls within the above-mentioned range. The content of hydrophobic resin based on the total solids of the actinic-ray- or radiation-sensitive resin composition is preferably in the range of 0.01 to 20 mass %, more preferably 0.1 to 15 mass %, further more preferably 0.1 to 10 mass % and most preferably 0.2 to 8 mass %.

One type of hydrophobic resin may be used alone, or two or more types thereof may be used in combination.

[4] Basic Compound

The actinic-ray- or radiation-sensitive resin composition of the present invention may contain a basic compound so as to decrease any performance alteration over time from exposure to heating.

As preferred basic compounds, there can be mentioned the compounds having the structures of the following formulae (A) to (E).

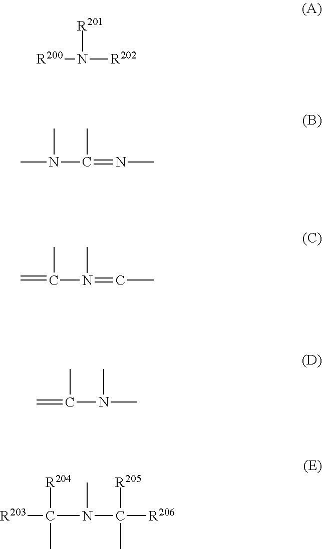

In the general formulae (A) and (E),

R²⁰⁰, R²⁰¹ and R²⁰² may be identical to or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded with each other to thereby form a ring.

R²⁰³, R²⁰⁴, R²⁰⁵ and R²⁰⁶ may be identical to or different from each other and each represent an alkyl group having 1 to 20 carbon atoms.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

More preferably, in these general formulae (A) and (E) the alkyl group is unsubstituted.

As preferred compounds, there can be mentioned guanidine, aminopyrrolidine, pyrazole, pyrazoline, piperazine, aminomorpholine, aminoalkylmorpholine, piperidine and the like. Further, as preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ether bond and the like.

As the compounds with an imidazole structure, there can be mentioned imidazole, 2,4,5-triphenylimidazole, benzimidazole, 2-phenylbenzoimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, triarylsulfonium hydroxide, phenacylsulfonium hydroxide, and sulfonium hydroxides having a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having a carboxylate at the anion moiety of the compounds with an onium hydroxide structure, for example, acetate, adamantane-1-carboxylate, perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives having a hydroxyl group and/or an ether bond, there can be mentioned ethanolamine, diethanolamine, triethanolamine, N-phenyldiethanolamine, tris(methoxyethoxyethyl)amine and the like. As the aniline derivatives having a hydroxyl group and/or an ether bond, there can be mentioned N,N-bis(hydroxyethyl)aniline and the like.

As preferred basic compounds, there can be further mentioned an amine compound having a phenoxy group, an ammonium salt compound having a phenoxy group, an amine compound having a sulfonic ester group and an ammonium salt compound having a sulfonic ester group.

As the amine compound, use can be made of primary, secondary and tertiary amine compounds. An amine compound having its at least one alkyl group bonded to the nitrogen atom thereof is preferred. Among the amine compounds, a tertiary amine compound is more preferred. In the amine compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. In the amine compounds, it is preferred for the alkyl chain to contain an oxygen atom so as to form an oxyalkylene group. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the ammonium salt compound, use can be made of primary, secondary, tertiary and quaternary ammonium salt compounds. An ammonium salt compound having its at least one alkyl group bonded to the nitrogen atom thereof is preferred. Of the ammonium salt compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. Of the ammonium salt compounds, it is preferred for the alkyl chain to contain an oxygen atom so as to form an oxyalkylene group. The number of oxyalkylene groups in each molecule is one or more, preferably 3 to 9 and still more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the anion of the ammonium salt compounds, there can be mentioned a halide atom, a sulfonate, a borate, a phosphate or the like. Of these, a halide and a sulfonate are preferred. Among halides, chloride, bromide and iodide are especially preferred. Among sulfonates, an organic sulfonate having 1 to 20 carbon atoms is especially preferred. As the organic sulfonate, there can be mentioned an aryl sulfonate and an alkyl sulfonate having 1 to 20 carbon atoms. The alkyl group of the alkyl sulfonate may have a substituent. As the substituent, there can be mentioned, for example, fluorine, chlorine, bromine, an alkoxy group, an acyl group, an aryl group or the like. As specific examples of the alkyl sulfonates, there can be mentioned methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate and the like. As the aryl group of the aryl sulfonate, there can be mentioned a benzene ring, a naphthalene ring or an anthracene ring. The benzene ring, naphthalene ring or anthracene ring may have a substituent. As preferred substituents, there can be mentioned a linear or branched alkyl group having 1 to 6 carbon atoms and a cycloalkyl group having 3 to 6 carbon atoms. As specific examples of the linear or branched alkyl groups and cycloalkyl groups, there can be mentioned methyl, ethyl, n-propyl, isopropyl, n-butyl, i-butyl, t-butyl, n-hexyl, cyclohexyl and the like. As other substituents, there can be mentioned an alkoxy group having 1 to 6 carbon atoms, a halogen atom, cyano, nitro, an acyl group, an acyloxy group and the like.

The amine compound having a phenoxy group and ammonium salt compound having a phenoxy group are those having a phenoxy group at the end of the alkyl group of the amine compound or ammonium salt compound opposed to the nitrogen atom. The phenoxy group may have a substituent. As the substituent of the phenoxy group, there can be mentioned, for example, an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like. The substitution position of the substituent may be any of 2- to 6-positions. The number of substituents is optional within the range of 1 to 5.

It is preferred that at least one oxyalkylene group exist between the phenoxy group and the nitrogen atom. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

The sulfonic ester group of the amine compound having a sulfonic ester group or ammonium salt compound having a sulfonic ester group may be any of an alkylsulfonic ester, a cycloalkylsulfonic ester and an arylsulfonic ester. In the alkylsulfonic ester, the alkyl group preferably has 1 to 20 carbon atoms. In the cycloalkylsulfonic ester, the cycloalkyl group preferably has 3 to 20 carbon atoms. In the arylsulfonic ester, the aryl group preferably has 6 to 12 carbon atoms. The alkylsulfonic ester, cycloalkylsulfonic ester and arylsulfonic ester may have substituents. As preferred substituents, there can be mentioned a halogen atom, a cyano group, a nitro group, a carboxyl group, a carboxylic ester group and a sulfonic ester group.

It is preferred that at least one oxyalkylene group exist between the sulfonic ester group and the nitrogen atom. The number of oxyalkylene groups in each molecule is one or more, preferably 3 to 9 and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

The following compounds are also preferred as the basic compound.

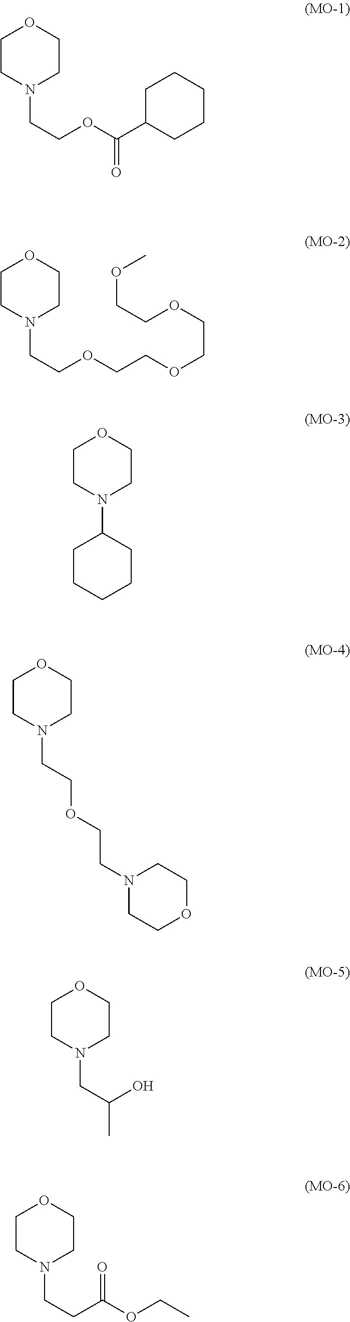

These basic compounds may be used either individually or in combination.

It is optional for the composition of the present invention to contain a basic compound. When a basic compound is contained, the content of the basic compound is typically in the range of 0.001 to 10 mass %, preferably 0.01 to 5 mass % based on the total solids of the actinic-ray- or radiation-sensitive resin composition.

With respect to the ratio of the acid generator (including the acid generator (A′)) to the basic compound used in the composition, preferably, the acid generator/the basic compound (molar ratio)=2.5 to 300. The reason for this is that the molar ratio is preferred to be 2.5 or higher from the viewpoint of sensitivity and resolving power. The molar ratio is preferred to be 300 or below from the viewpoint of the inhibition of any resolving power deterioration due to thickening of resist pattern over time from exposure to heating treatment. The acid generator/the basic compound (molar ratio) is more preferably in the range of 5.0 to 200, still more preferably 7.0 to 150.

These basic compounds are preferably used in a molar ratio to the low-molecular compound (D) to be described in section [5] below [low-molecular compound (D)/basic compound] of 100/0 to 10/90, more preferably 100/0 to 30/70 and most preferably 100/0 to 50/50.

Herein, the basic compounds do not include any low-molecular compound (D) containing a nitrogen atom and a group cleaved under the action of an acid, which functions as a basic compound.

[5] Low-Molecular Compound Containing a Nitrogen Atom and a Group Cleaved by the Action of an Acid

The composition of the present invention may be loaded with a low-molecular compound (hereinafter also referred to as “low-molecular compound (D)” or “compound (D)”) containing a nitrogen atom and a group cleaved by the action of an acid.

The group that is cleaved when acted on by an acid is not particularly limited. However, an acetal group, a carbonate group, a carbamate group, a tertiary ester group, a tertiary hydroxyl group and a hemiaminal ether group are preferably used. A carbamate group and a hemiaminal ether group are especially preferred.

The molecular weight of the compound (D) is preferably in the range of 100 to 1000, more preferably 100 to 700 and most preferably 100 to 500.

As the compound (D), an amine derivative containing a group that is cleaved when acted on by an acid being connected to a nitrogen atom.

The compound (D) may contain a carbamate group with a protective group, the carbamate group being connected to a nitrogen atom. The protective group contained in the carbamate group can be represented, for example, by the following formula (d-1).

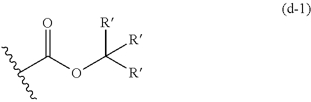

In formula (d-1),

Each of R's independently represents a hydrogen atom, an alkyl group, a cycloalkyl group, an aryl group, an aralkyl group, or an alkoxyalkyl group. At least two of R's may be connected to each other to form a ring.

The alkyl group, the cycloalkyl group, the aryl group, and the aralkyl group represented by R′ may be substituted with a functional group such as a hydroxyl group, a cyano group, an amino group, a pyrrolidino group, a piperidino group, a morpholino group, and an oxo group; an alkoxy group; or a halogen atom. The same applies to the alkoxyalkyl group represented by R′.

As the alkyl group, the cycloalkyl group, the aryl group, and the aralkyl group (these groups may be substituted with the above functional group, an alkoxy group, or a halogen atom) represented by R′, the following groups can be exemplified:

a group derived from a linear or branched alkane such as methane, ethane, propane, butane, pentane, hexane, heptane, octane, nonane, decane, undecane, or dodecane; and the group derived from the alkane and substituted with one or more cycloalkyl groups such as a cyclobutyl group, a cyclopentyl group, or a cyclohexyl group;

a group derived from cycloalkane such as cyclobutane, cyclopentane, cyclohexane, cycloheptane, cyclooctane, norbornane, adamantane, or noradamantane; and the group derived from the cycloalkane and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from aromatic compound such as benzene, naphthalene, or anthracene; and the group derived from the atomatic compound and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from heterocyclic compound such as pyrrolidine, piperidine, morpholine, tetrahydrofuran, tetrahydropyrane, indole, indoline, quinoline, perhydroquinoline, indazole, or benzimidazole; the group derived from heterocyclic compound and substituted with one or more linear or branched alkyl group or a group derived from the aromatic compound;

a group derived from linear or branched alkane and substituted with a group derived from aromatic compound such as a phenyl group, a naphthyl group, or an anthracenyl group;

a group derived from cycloalkane and substituted with a group derived from aromatic compound such as a phenyl group, a naphthyl group, or an anthracenyl group; or

each of these groups substituted with a functional group such as a hydroroxyl group, a cyano group, an amino group, a pyrrolidino group, a piperidino group, a morpholino group, or an oxo group.

Preferably, R′ represents a linear or branched alkyl group, a cycloalkyl group, or an aryl group. More preferably, R′ represents a linear or branched alkyl group, or a cycloalkyl group.

As the ring formed by the mutual bonding of two Rb's, there can be mentioned an alicyclic hydrocarbon group, an aromatic hydrocarbon group, a heterocyclic hydrocarbon group, a derivative thereof or the like.

Specific structures of the groups of general formula (d-1) are shown below.

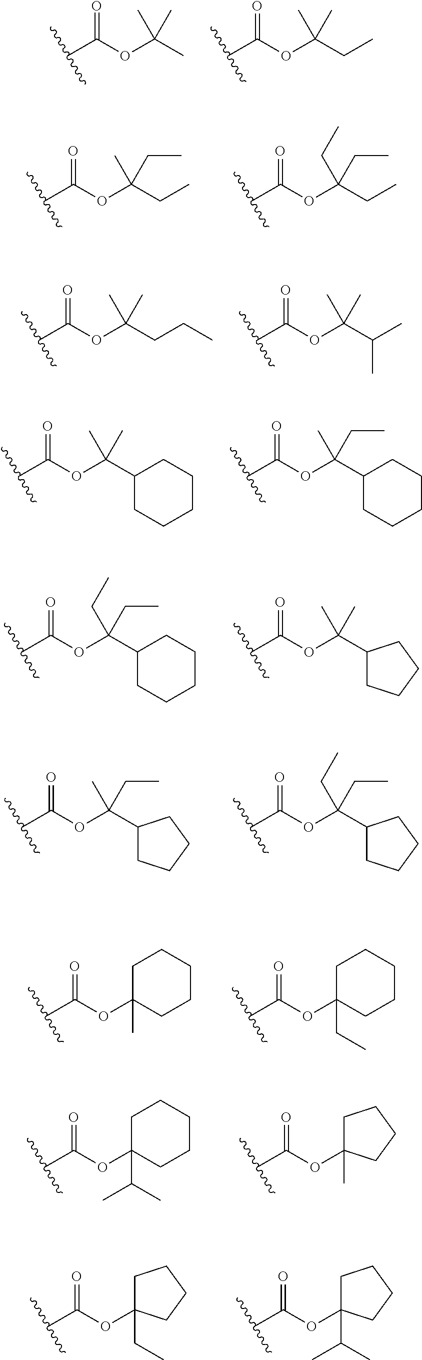

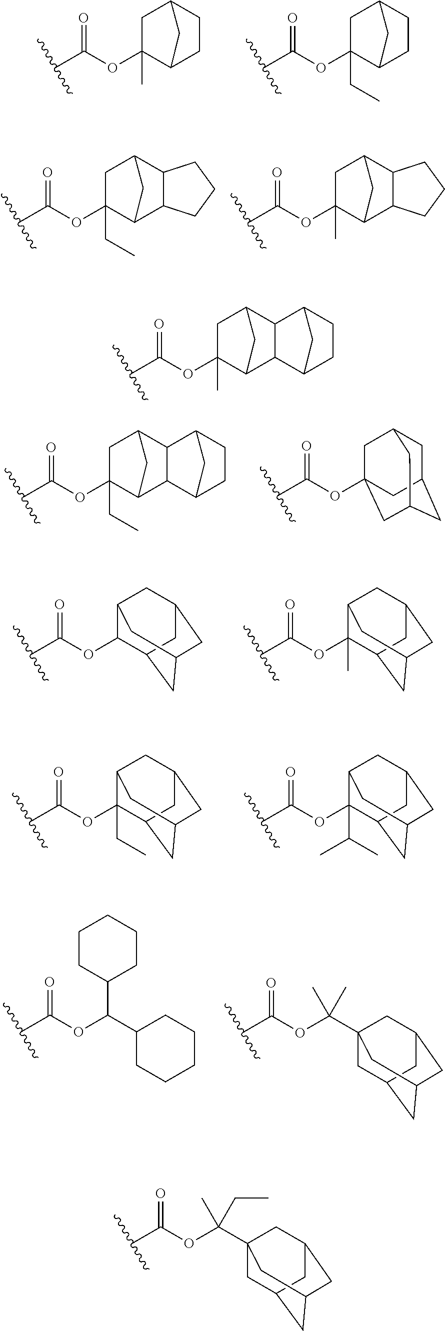

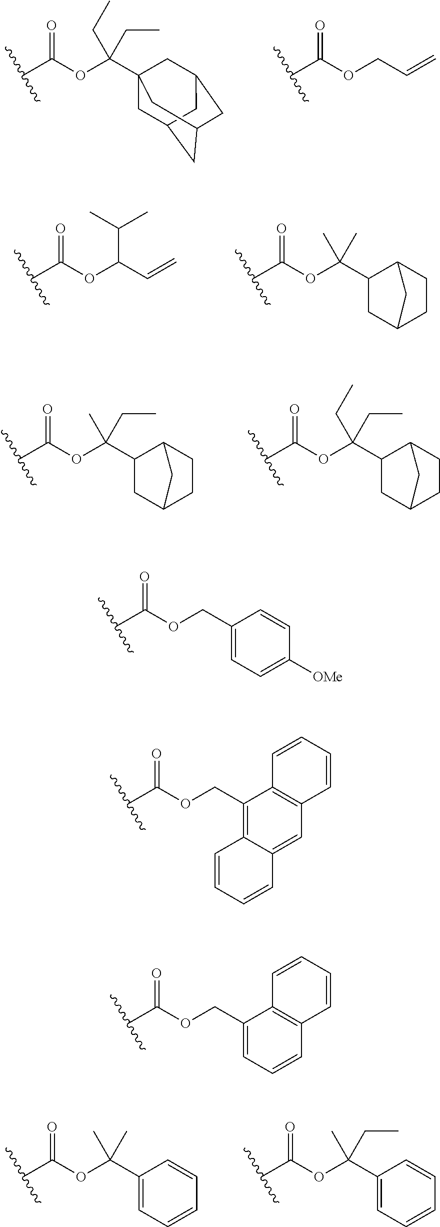

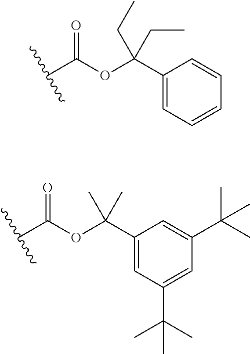

The compound (D) may have a structure in which any of the above-mentioned basic compounds are combined with the structure represented by general formula (d-1).

The compound (D) is especially preferred to be the one represented by general formula (A) below.

Note that, the compound (D) may be any of the basic compounds described above as long as it is a low-molecular compound containing a group that is cleaved when acted on by an acid.

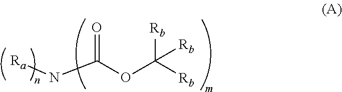

In the general formula (A), Ra represents a hydrogen atom, an alkyl group, a cycloalkyl group, an aryl group, or an aralkyl group. When n=2, two Ra's may be the same or different from each other, and may be connected to each other to form a bivalent heterocyclic hydrocarbon group (preferably having 20 or less carbon atoms) or its derivatives.

Rb has the same meaning as that of R′ appearing in general formula (d-1) above, and preferred examples thereof are also the same, with the proviso that when at least one of Rb's of —C(Rb)(Rb)(Rb) are hydrogen atoms, at least one of the remainder represents a cyclopropyl group, 1-alkoxyalkyl group, or an aryl group.

In formula (A), n represents an integer of 0 to 2, m represents an integer of 1 to 3, and n+m=3.

In formula (A), the alkyl group, the cycloalkyl group, the aryl group, and the aralkyl group represented by Ra may be substituted. As substituents, there can be mentioned the same groups as set forth above with respect to the groups represented by R′.

Particular examples of the alkyl, cycloalkyl, aryl and aralkyl groups (these groups optionally substituted with the above-mentioned groups) represented by Ra are the same as those set forth above in connection with R′.

Further, as the bivalent heterocyclic hydrocarbon group (preferably having 1 to 20 carbon atoms) or its derivative, formed by mutual binding of Ra's, for example, the followings can be exemplified:

a group derived from heterocyclic compound such as pyrrolidine, piperidine, morpholine, 1,4,5,6-tetrahydropyrimidine, 1,2,3,4-tetrahydroquinoline, 1,2,3,6-tetrahydroquinoline, homopiperadine, 4-azabenzimidazole, benztriazole, 5-azabenztriazole, 1H-1,2,3-triazole, 1,4,7-triazacyclononane, tetrazole, 7-azaindole, indazole, benzimidazole, imidazo[1,2-a]pyridine, (1S,4S)-(+)2,5-azabicyclo[2.2.1]heptane, 1,5,7-triazabicyclo[4.4.0]dec-5-en, indole, indoline, 1,2,3,4-tetrahydroquinoxaline, perhydroquinoline, or 1,5,9-triazacyclododecane; or

the group derived from heterocyclic compound and substituted with at least one of a group derived from linear or branched alkane, a group derived from cycloalkane, a group derived from aromatic compound, a group derived from heterocyclic compound, or a functional group such as a hydroxyl group, a cyano group, an amino group, a pyrrolidino group, a piperidino group, a morpholino group, or an oxo group.

Particularly preferred examples of the compound (D) will be shown below, which however in no way limit the scope of the present invention.

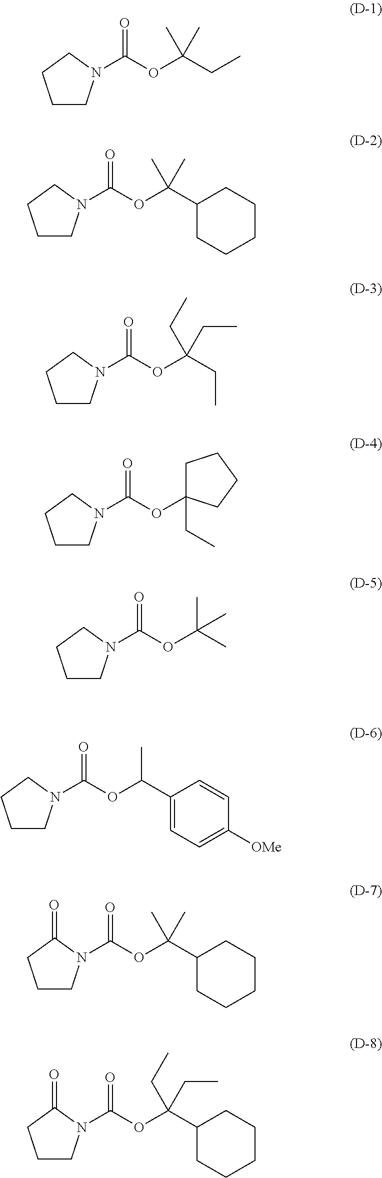

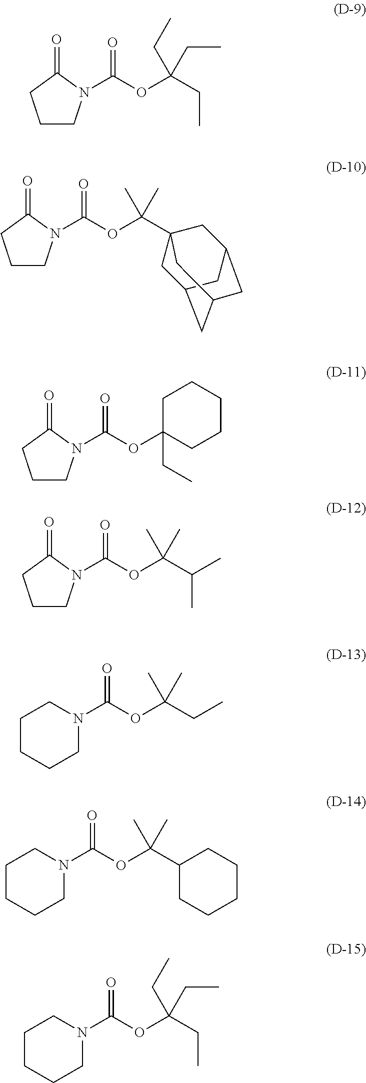

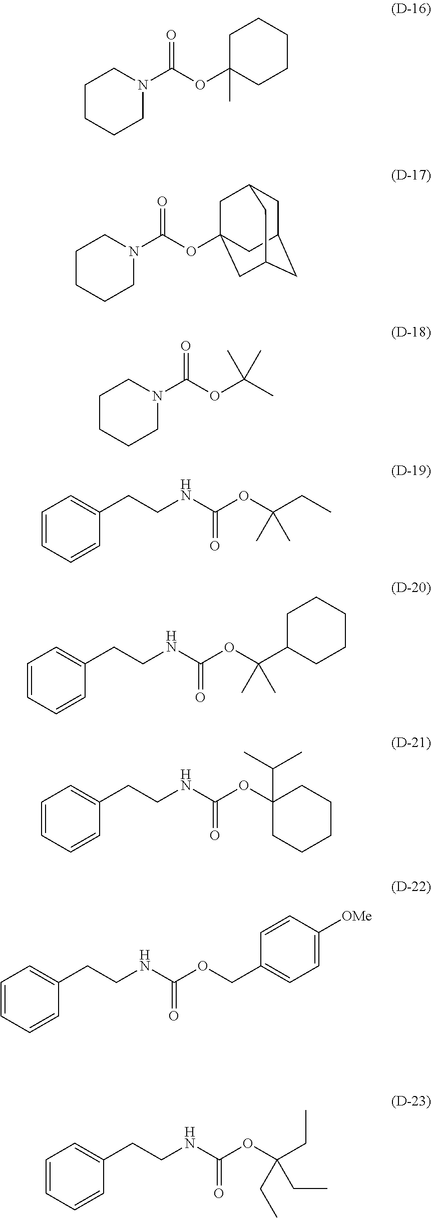

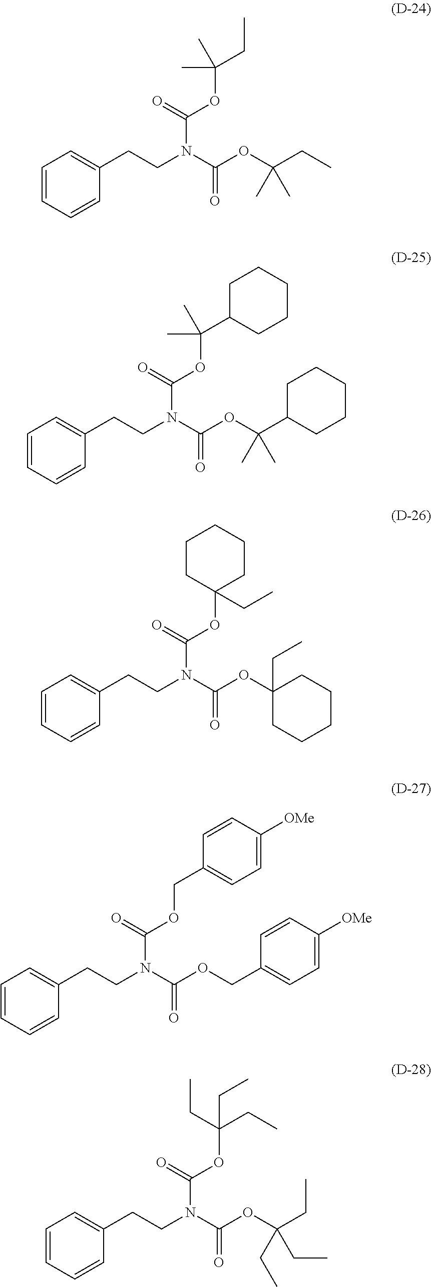 [SMILES: CCC(C)(C)OC(=O)N(CCc1ccccc1)C(=O)OC(C)(C)CC ; CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC]

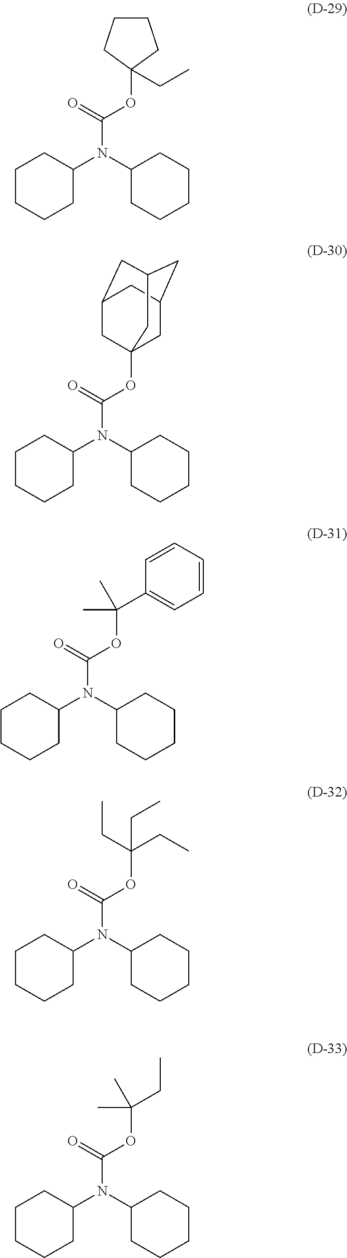

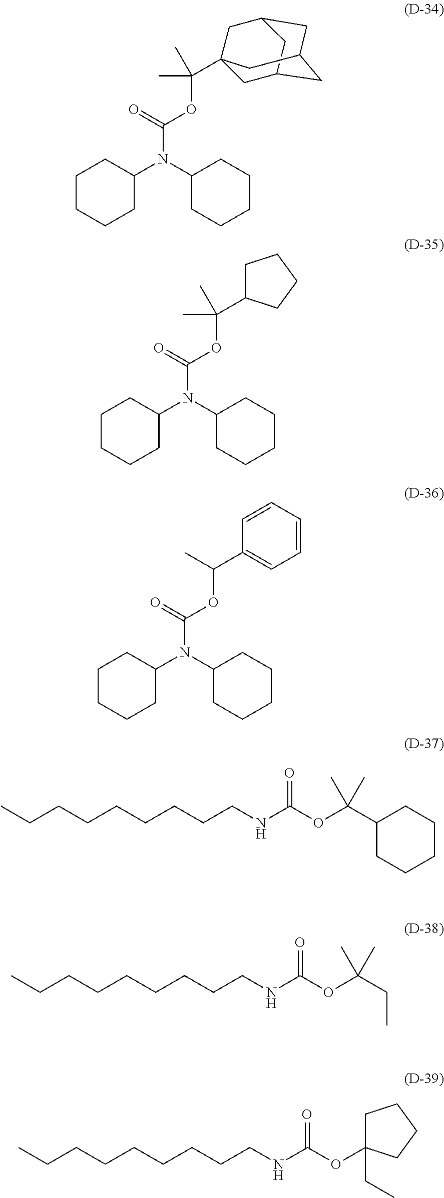

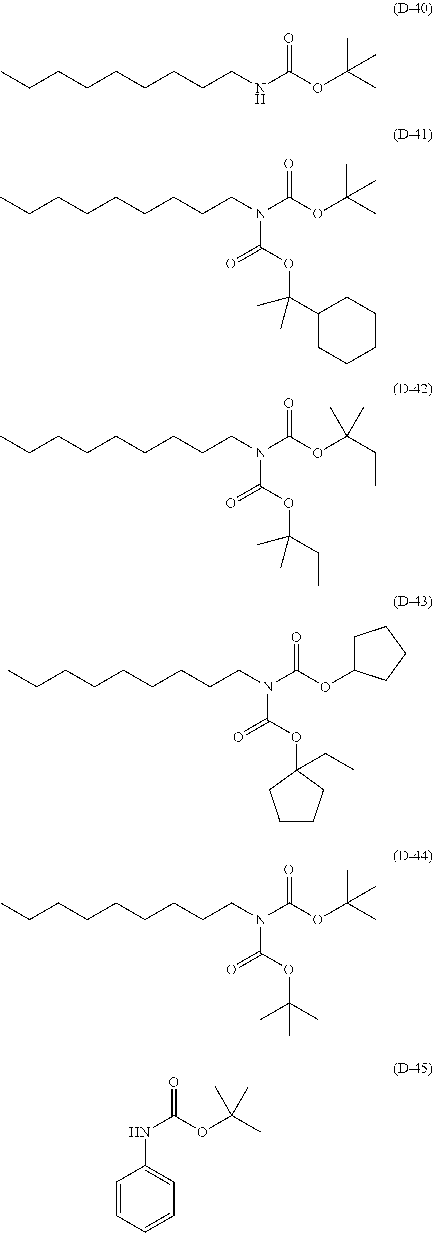

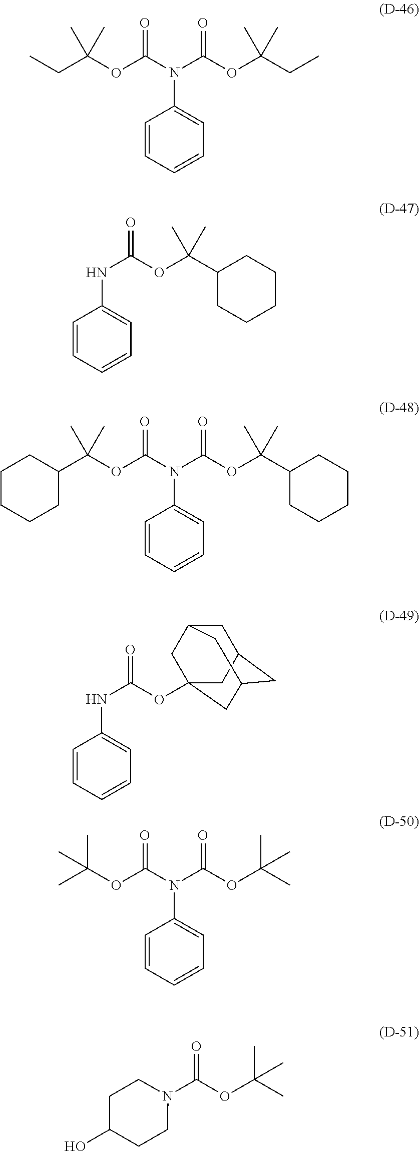

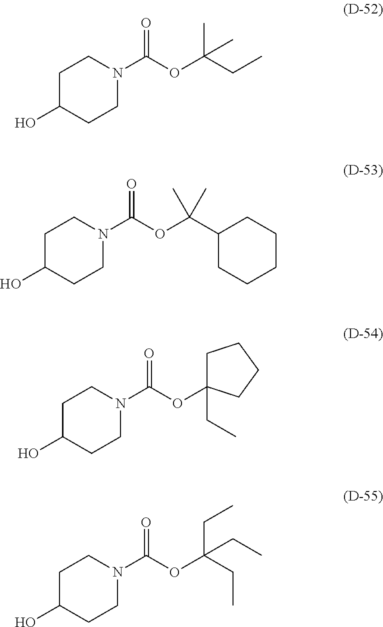 [SMILES: CCC(C)(C)OC(=O)N1CCC(O)CC1 ; CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

The compounds of general formula (A) can be synthesized by, for example, the method described in JP-A-2007-298569 or JP-A-2009-199021.

In the present invention, one type of compound (D) may be used alone, or two or more types thereof may be used in a mixture.

It is optional for the actinic-ray- or radiation-sensitive resin composition of the present invention to contain the compound (D). When the compound (D) is contained, the content of the compound (D), based on the total solids of the composition mixed with the basic compound as described above, is generally in the range of 0.001 to 20 mass %, preferably 0.001 to 10 mass % and more preferably 0.01 to 5 mass %.

[6] Surfactant

It is optional for the composition of the present invention to further contain a surfactant. The surfactant is preferably a fluorinated and/or siliconized surfactant.

As such a surfactant, there can be mentioned Megafac F176 or Megafac R08 produced by DIC Corporation, PF656 or PF6320 produced by OMNOVA SOLUTIONS, INC., Troy Sol S-366 produced by Troy Chemical Co., Ltd., Florad FC430 produced by Sumitomo 3M Ltd., polysiloxane polymer KP-341 produced by Shin-Etsu Chemical Co., Ltd., or the like.

Surfactants other than these fluorinated and/or siliconized surfactants can also be used. In particular, the other surfactants include polyoxyethylene alkyl ethers, polyoxyethylene alkyl aryl ethers and the like.

Moreover, heretofore known surfactants can also be appropriately used. As useful surfactants, there can be mentioned, for example, those described in section [0273] et seq of US Patent Application Publication No. 2008/0248425 A1.

One type of surfactant may be used alone, or two or more types thereof may be used in combination.

It is optional for the actinic-ray- or radiation-sensitive resin composition of the present invention to contain a surfactant. When a surfactant is contained, the amount of surfactant added is preferably in the range of 0 to 2 mass %, more preferably 0.0001 to 2 mass % and most preferably 0.0005 to 1 mass %, based on the total solids of the composition.

Meanwhile, it is also preferred to limit the amount of added surfactant to 10 ppm or less, or to contain no surfactant at all. This would increase the uneven distribution of a hydrophobic resin into a surface portion, so that the surface of the resist film can be highly hydrophobic, thereby enhancing the water tracking properties at liquid-immersion exposure.

[7] Solvent

The solvent that is usable in the preparation of the composition is not particularly limited as long as it can dissolve the components of the composition. For example, use can be made of an alkylene glycol monoalkyl ether carboxylate (propylene glycol monomethyl ether acetate or the like), an alkylene glycol monoalkyl ether (propylene glycol monomethyl ether or the like), an alkyl lactate (ethyl lactate, methyl lactate or the like), a cyclolactone (γ-butyrolactone or the like, preferably having 4 to 10 carbon atoms), a linear or cyclic ketone (2-heptanone, cyclohexanone or the like, preferably having 4 to 10 carbon atoms), an alkylene carbonate (ethylene carbonate, propylene carbonate or the like), an alkyl carboxylate (preferably an alkyl acetate such as butyl acetate), an alkyl alkoxyacetate (preferably ethyl ethoxypropionate) or the like. As other useful solvents, there can be mentioned, for example, those described in section [0244] et seq. of US 2008/0248425 A1 and the like.

Among the above solvents, an alkylene glycol monoalkyl ether carboxylate and an alkylene glycol monoalkyl ether are especially preferred.

These solvents may be used alone or in combination. When two or more types of solvents are mixed together before use, it is preferred to mix a hydroxylated solvent with a non-hydroxylated solvent. The mass ratio of hydroxylated solvent to non-hydroxylated solvent is in the range of, for example, 1/99 to 99/1. The mass ratio is preferably 10/90 to 90/10, more preferably 20/80 to 60/40.

The hydroxylated solvent is preferably an alkylene glycol monoalkyl ether. The non-hydroxylated solvent is preferably an alkylene glycol monoalkyl ether carboxylate.

[8] Other Components

In addition to the above components, an onium salt of carboxylic acid, any of the dissolution inhibiting compounds of 3000 or less molecular weight described in, for example, Proceeding of SPIE, 2724,355 (1996), a dye, a plasticizer, a photosensitizer, a light absorber, an antioxidant, etc. can be appropriately incorporated in the composition of the present invention.

[9] Method of Forming Pattern

The method of forming a pattern according to the present invention comprises the operations of exposing a resist film to light and developing the exposed film.

The resist film is formed from the foregoing actinic-ray- or radiation-sensitive resin composition of the present invention. In particular, the resist film is preferably formed on a substrate. In the method of forming a pattern according to the present invention, all the operations of forming a film of the resist composition on a substrate, exposing the resist film to light and developing the exposed film can be performed through generally known procedures.

From the viewpoint of enhancing the resolving power, it is preferred for the composition of the present invention to be used with a film thickness of 30 to 250 nm. More preferably, the composition is used with a film thickness of 30 to 200 nm. This film thickness can be attained by setting the solid content of the actinic-ray- or radiation-sensitive resin composition within an appropriate range so as to cause the composition to have an appropriate viscosity, thereby improving the applicability and film forming property.

The total solid content of the composition of the present invention is generally in the range of 1 to 10 mass %, preferably 1 to 8.0 mass % and more preferably 1.0 to 6.0 mass %.

In the use of the composition of the present invention, the above components are dissolved in a solvent, filtered and applied onto a support. The filter medium is preferably one made of a polytetrafluoroethylene, polyethylene or nylon having a pore size of 0.1 μm or less, more preferably 0.05 μm or less and further more preferably 0.03 μm or less. In the filtration, two or more types of filters may be connected in series or parallel. Moreover, the composition may be filtered two or more times. Further, deaeration or the like of the composition may be performed prior to and/or after the filtration.

The composition is applied onto a substrate, such as one for use in the production of integrated circuit elements (e.g., silicon/silicon dioxide coating), by appropriate application means, such as a spinner. Thereafter, the applied composition is dried, thereby forming a sensitive resist film.

This film is exposed through a given mask to actinic rays or radiation, preferably baked (heated), developed and rinsed. Thus, a favorable pattern can be obtained. When the film is exposed to electron beams, lithography through no mask (direct lithography) is generally carried out.

In the pattern forming method of the present invention, a pre-bake (PB) operation is preferably carried out after the operation of film formation but prior to the exposure operation.

Also preferably, a post-exposure bake (PEB) is carried out after the exposure operation but prior to the development operation.

In both PB and PEB operations, the bake is preferably carried out at 70 to 120° C., more preferably 80 to 110° C.

The baking time is preferably in the range of 30 to 300 seconds, more preferably 30 to 180 seconds and further more preferably 30 to 90 seconds.

The baking can be carried out using means provided in common exposure/development equipment. The baking may also be carried out using a hot plate or the like.

The baking accelerates the reaction in exposed areas, thereby enhancing the sensitivity and pattern profile.

The employable actinic rays or radiation is not particularly limited. For example, there can be mentioned a KrF excimer laser, an ArF excimer laser, EUV light, electron beams and the like. Of these, an ArF excimer laser, EUV light and electron beams are preferred.

Generally, an aqueous solution of any of quaternary ammonium salts, a typical example thereof being tetramethylammonium hydroxide, is employed as the alkali developer for use in the development operation. However, other aqueous alkali solutions of an inorganic alkali, a primary amine, a secondary amine, a tertiary amine, an alcoholamine, a cycloamine, etc. can also be employed.

An appropriate amount of alcohol and/or surfactant may be added to the alkali developer.

The alkali concentration of the alkali developer is generally in the range of 0.1 to 20 mass %.

The pH value of the alkali developer is generally in the range of 10.0 to 15.0.

Pure water is used as the rinse liquid. An appropriate amount of surfactant may be added to the rinse liquid before use.

As the development method, use can be made of, for example, a method in which the substrate is dipped in a tank filled with a developer for a given period of time (dip method), a method in which a developer is puddled on the surface of the substrate by its surface tension and allowed to stand still for a given period of time to thereby effect development (puddle method), a method in which a developer is sprayed onto the surface of the substrate (spray method), or a method in which a developer is continuously discharged onto the substrate being rotated at a given speed while scanning a developer discharge nozzle at a given speed (dynamic dispense method).

Further, the development operation or rinse operation may be followed by the treatment of removing any portion of developer or rinse liquid adhering onto the pattern by use of a supercritical fluid.

The application of the composition to the substrate can be preceded by the application of an antireflection film.

As the anti-reflection film, use can be made of not only an inorganic film of titanium, titanium oxide, titanium nitride, chromium oxide, carbon, amorphous silicon or the like but also an organic film composed of a light absorber and a polymer material. Also, as the organic anti-reflection film, use can be made of commercially available organic anti-reflection films, such as the DUV30 Series and DUV40 Series produced by Brewer Science Inc. and AR-2, AR-3 and AR-5 produced by Shipley Co., Ltd.

Exposure (liquid immersion exposure) may be carried out after filling the interstice between a film and a lens with a liquid (liquid immersion medium) of refractive index higher than that of air at the time of exposure to actinic rays or radiation. The resolution can be enhanced by the exposure through the liquid immersion medium. The useful liquid immersion medium is preferably water. Water is preferred from the viewpoint of a refractive index with a low temperature coefficient, easy procurement and easy handling.

Further, from the viewpoint of refractive index increase, use can be made of a medium having a refractive index of 1.5 or higher. Such a medium may be an aqueous solution or an organic solvent.

When water is used as a liquid for liquid immersion, an additive intended for an increase of refractive index, etc. may be added to water in slight proportion. Examples of such additives are particularized in Chapter 12 of “Process and Material of Liquid Immersion Lithography” published by CMC Publishing Co., Ltd. On the other hand, the presence of a substance being opaque in 193-nm light or presence of an impurity whose refractive index is greatly different from that of water would invite a distortion of optical image projected on the film. Accordingly, it is preferred to use distilled water as the liquid immersion water. Further, use may be made of water having been purified through an ion exchange filter or the like. Desirably, the electrical resistance of pure water is 18.3 MQcm or higher, and the TOC (organic matter concentration) thereof is 20 ppb or below. Prior deaeration of the water is desired.

For the prevention of any direct contact of the resist film with the immersion liquid, a film that is highly insoluble in the immersion liquid (hereinafter also referred to as a “top coat”) may be provided between the resist film and the immersion liquid. The functions to be fulfilled by the top coat are applicability onto the resist film, transparency in radiation of especially 193 nm wavelength and high insolubility in the immersion liquid. It is preferred to use, as the top coat, one that does not mix with the resist film and is uniformly applicable onto the resist film.

From the viewpoint of transparency at 193 nm, the top coat is preferably comprised of a polymer containing no aromatic moiety. As such a polymer, there can be mentioned, for example, a hydrocarbon polymer, an acrylic ester polymer, polymethacrylic acid, polyacrylic acid, polyvinyl ether, a siliconized polymer or a fluoropolymer. The aforementioned hydrophobic resin finds appropriate application in the top coat. Any optical lens is contaminated by leaching of impurities from the top coat into the immersion liquid, so that it is preferred to effectively reduce the amount of residual monomer components of polymer contained in the top coat.

At the detachment of the top coat, use may be made of a developer, or a separate peeling agent. The peeling agent is preferably comprised of a solvent exhibiting a lower permeation into the resist film. Detachability by an alkali developer is preferred from the viewpoint that the detaching operation can be performed simultaneously with the development processing operation for the resist. It is preferred for the top coat to be acidic from the viewpoint of detachment with the use of an alkali developer. However, from the viewpoint of non-intermiscibility with the resist, the top coat may be neutral or alkaline.

It is preferred to render any difference in refractive index between the top coat and the immersion liquid less or closer to nil. If so, the resolving power can be increased. When an ArF excimer laser (wavelength: 193 nm) is used as an exposure light source, water is preferably used as the immersion liquid, so that it is preferred for the top coat for ArF liquid immersion exposure to have a refractive index close to that of water (1.44).

From the viewpoint of transparency and refractive index, it is preferred for the top coat to be a thin film. Preferably, the top coat does not mix with the resist film and also does not mix with the immersion liquid. From this viewpoint, when the immersion liquid is water, it is preferred for the solvent for use in the top coat to be highly insoluble in the solvent used in the actinic-ray- or radiation-sensitive resin composition of the present invention and to be a non-water-soluble medium. In contrast, when the immersion liquid is an organic solvent, the top coat may be soluble or insoluble in water.

Furthermore, the present invention relates to a process for manufacturing an electronic device in which the above-described pattern forming method of the present invention is included, and relates to an electronic device manufactured by the process.

The electronic device of the present invention can be appropriately mounted in electrical and electronic equipments (household electronic appliance, OA/media-related equipment, optical apparatus, telecommunication equipment and the like).

### EXAMPLE

The present invention will be described in greater detail below by way of its examples. However, the gist of the present invention is in no way limited to these examples.

### Synthetic Examples 1

### Synthesis of Compound A-34

Compound A-34 was synthesized in accordance with the following scheme.

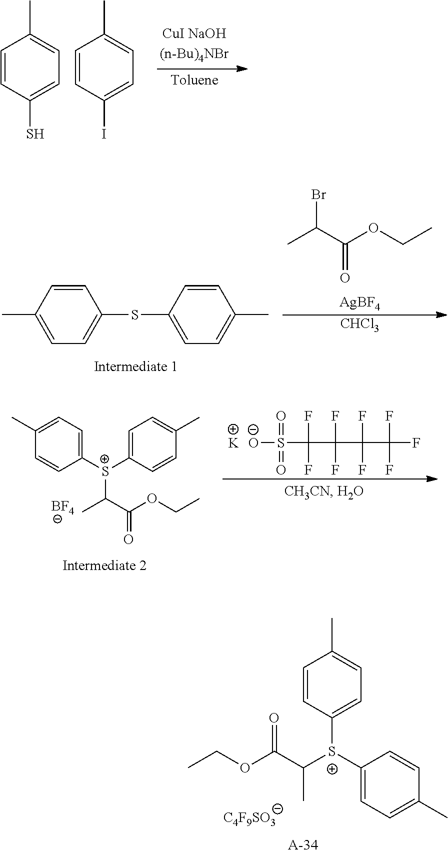

<<Synthesis of intermediate 1>>

First, 24.8 g (0.2 mol) of toluenethiol, 43.6 g (0.2 mol) of 4-iodotoluene, 3.8 g (0.02 mol) of copper iodide, 6.4 g (0.02 mol) of tetra-n-butylammonium bromide, 16 g (0.4 mol) of sodium hydroxide and 100 ml of toluene were placed in a 300 ml three-necked flask. The mixture was agitated for 18 hours while heating under reflux in a nitrogen gas atmosphere. Thereafter, 500 ml of water was added to the reaction liquid, and extraction was performed with 200 ml of ethyl acetate. The extract was dewatered over magnesium sulfate, and filtered. The thus obtained residue was concentrated in vacuum. The desired substance was separated therefrom by column chromatography (SiO₂, hexane). The thus obtained residue was concentrated in vacuum. Thereafter, recrystallization was performed with 50 ml of methanol, thereby obtaining 21.5 g of intermediate 1 (yield: 50.2%).

¹H-NMR, 400 MHz, δ(CDCl₃) ppm: 2.31 (6H, s), 7.07-7.09 (4H, s), 7.21-7.24 (4H, s).

<<Synthesis of intermediate 2>>

Intermediate 1 amounting to 1.54 g (7.19 mmol), 1.69 g (9.34 mmol) of ethyl 2-bromopropionate, 1.68 g (8.62 mmol) of silver tetrafluoroborate and 5 ml of chloroform were placed in a 50 ml round-bottomed flask. The mixture was agitated for 19 hours while heating under reflux. Thereafter, any insoluble matter was separated by filtration, and 150 ml of water was added to the reaction liquid. Extraction was performed with 50 ml of ethyl acetate, and the residue was dried in vacuum. The dried residue was washed with 20 ml of diisopropyl ether and washed with a mixed solvent comprised of 15 ml of hexane and 5 ml of ethyl acetate. The washed residue was dried in vacuum, thereby obtaining 2.0 g of intermediate 2 (yield: 76.1%).

¹H-NMR, 400 MHz, δ(CDCl₃) ppm: 1.13-1.17 (3H, t), 1.62-1.65 (3H, d), 2.42-2.44 (6H, d), 4.12-4.22 (2H, q), 5.79-5.83 (1H, q), 7.42-7.56 (4H, m), 7.94-8.02 (4H, m).

<Synthesis of Compound A-34>>

Intermediate 2 amounting to 2.2 g (5.47 mmol), 3.65 g (10.8 mmol) of potassium n-nonafluorobutanesulfonate, 10 ml of acetonitrile and 10 ml of water were placed in a 50 ml round-bottomed flask, and agitated at room temperature for 1.5 hours. Thereafter, any insoluble matter was separated by filtration, and 100 ml of water was added to the reaction liquid. Extraction was performed with 50 ml of ethyl acetate, and the residue was dried in vacuum. The dried residue was washed with 20 ml of diisopropyl ether and washed with a mixed solvent comprised of 15 ml of hexane and 5 ml of ethyl acetate. The washed residue was dried in vacuum, thereby obtaining 3.3 g of compound A-34 (yield: 98.2%).

¹H-NMR, 400 MHz, δ(CDCl₃) ppm: 1.13-1.17 (3H, t), 1.62-1.65 (3H, d), 2.42-2.44 (6H, d), 4.12-4.22 (2H, q), 6.13-6.22 (1H, q), 7.44-7.56 (4H, m), 8.01-8.09 (4H, m).

The following compounds were synthesized in the same manner as described above for the synthesis of compound A-34.

Compound A-16:

¹H-NMR, 400 MHz, δ(CDCl₃) ppm: 0.72-1.82 (18H, m), 2.63-2.72 (1H, t), 3.00-3.09 (1H, t), 3.75-3.81 (1H, br), 3.82-3.89 (6H, d), 3.93-4.03 (1H, br), 4.11-4.19 (2H, q), 5.94-6.02 (1H, q), 7.08-7.18 (4H, m), 8.04-8.13 (4H, m).

Compound A-33:

¹H-NMR, 400 MHz, δ(CDCl₃) ppm: 0.82-1.82 (21H, m), 2.63-2.72 (1H, t), 3.01-3.11 (1H, t), 3.62-3.81 (5H, m), 3.8-3.92 (6H, d), 3.93-4.03 (1H, br), 4.66-4.74 (1H, br), 5.95-6.05 (1H, q), 7.10-7.19 (4H, m), 8.04-8.12 (4H, m).

Compound A-35:

¹H-NMR, 400 MHz, δ(CDCl₃) ppm: 1.17-1.23 (3H, t), 2.40-2.45 (6H, s), 4.15-4.23 (2H, q), 5.12-5.16 (2H, s), 7.43-7.48 (4H, d), 7.83-7.9 (4H, d).

Compound A-36:

¹H-NMR, 400 MHz, δ(CDCl₃) ppm: 1.13-1.30 (3H, m), 1.67-1.72 (3H, m), 2.38-2.44 (3H, d), 4.04-4.27 (2H, m), 6.4-6.48 (1H, m), 7.43-7.51 (2H, m), 7.63-7.72 (1H, m), 7.73-7.82 (1H, m), 7.83-7.92 (1H, m), 7.93-8.05 (1H, m), 8.07-8.13 (2H, m), 8.14-8.22 (1H, m), 8.38-8.44 (1H, m), 8.82-8.94 (1H, m).

Compound A-37:

¹H-NMR, 400 MHz, δ(CDCl₃) ppm: 1.08-1.18 (3H, m), 2.34-2.42 (3H, d), 4.09-4.20 (2H, m), 5.38-5.62 (2H, m), 7.33-7.45 (2H, m), 7.63-7.72 (1H, m), 7.62-7.70 (1H, m), 7.71-7.80 (1H, m), 7.81-7.88 (1H, m), 7.91-8.03 (2H, m), 8.12-8.21 (1H, m), 8.32-8.38 (1H, m), 8.58-8.63 (1H, m).

Compound A-58:

¹H-NMR, 400 MHz, δ(CDCl₃) ppm: 0.81-1.84 (18H, m), 2.62-2.72 (1H, t), 3.0-3.1 (1H, t), 3.44-3.52 (2H, m), 3.77-3.82 (1H, br), 3.85-3.9 (6H, d), 3.93-4.02 (1H, br), 4.08-4.25 (2H, br), 6.0-6.4 (1H, br), 7.09-7.2 (4H, m), 8.07-8.14 (4H, m).

Compound A-61:

¹H-NMR, 400 MHz, δ(CDCl₃) ppm: 0.80-1.87 (18H, m), 1.89-1.99 (1H, m), 2.13-2.27 (1H, m), 2.43-2.42 (3H, d), 2.61-2.73 (4H, m), 3.0-3.1 (1H, t), 3.77-3.82 (1H, br), 3.96-4.02 (1H, br), 4.12-4.22 (2H, m), 5.79-5.87 (1H, br), 7.13-7.22 (2H, d), 7.42-7.52 (2H, m), 8.18-8.22 (2H, d).

### Synthetic Example 2

### Synthesis of Resin (3)

In a nitrogen gas stream, 11.5 g of cyclohexanone was placed in a three-necked flask and heated at 85° C.

A solution obtained by dissolving the following compounds (monomers) amounting in order from the left side to 1.98 g, 3.05 g, 0.95 g, 2.19 g and 2.76 g and further 0.453 g of polymerization initiator V601 (produced by Wako Pure Chemical Industries, Ltd.) in 21.0 g of cyclohexanone was dropped thereinto over a period of 6 hours. After the completion of the dropping, reaction was continued at 85° C. for 2 hours. The thus obtained reaction liquid was allowed to stand still to cool and was dropped into a mixed liquid consisting of 420 g of hexane and 180 g of ethyl acetate over a period of 20 minutes. The thus precipitated powder was collected by filtration and dried, thereby obtaining 9.1 g of resin (3) being an acid-decomposable resin to be identified hereinafter. The polymer component ratio determined by NMR was 20/25/10/30/15. The standard-polystyrene-equivalent weight average molecular weight of the obtained resin (3) was 10,400, and the polydispersity index (Mw/Mn) thereof was 1.56.

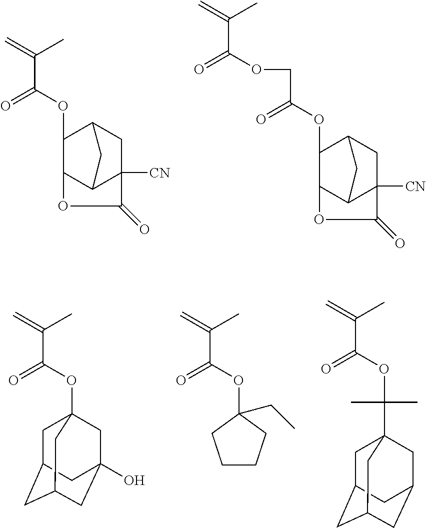 [SMILES: C=C(C)C(=O)OC1C2CC3C1OC(=O)C3(C#N)C2 ; C=C(C)C(=O)OCC(=O)OC1C2CC3C1OC(=O)C3(C#N)C2 ; C=C(C)C(=O)OC12CC3CC(CC(O)(C3)C1)C2 ; C=C(C)C(=O)OC1(CC)CCCC1 ; C=C(C)C(=O)OC(C)(C)C12CC3CC(CC(C3)C1)C2]

The resins (1), (2) and (4) to (6) as acid-decomposable resins to be identified hereinafter were synthesized through the same procedure as in Synthetic Example 2.

<Preparation of Resist>

Dissolution of individual components in solvents as indicated in Table 2 below was carried out, thereby obtaining solutions each of 4 mass % solid content. The solutions were each passed through a polyethylene filter of 0.05 μm pore size, thereby obtaining actinic-ray- or radiation-sensitive resin compositions (positive resist compositions). The thus obtained actinic-ray- or radiation-sensitive resin compositions were evaluated by the following methods, and the results are given in Table 2.

With respect to each of the individual components of the table, the ratio indicated when multiple types are used is a mass ratio.

In Table 2, when the actinic-ray- or radiation-sensitive resin composition did not contain any hydrophobic resin (HR) and when after the formation of a film, a top coat protective film containing a hydrophobic resin (HR) was formed on an upper layer of the film, “TC” is noted as the form of usage of the hydrophobic resin.

### Evaluation of Resist

### Exposure Condition 1: ArF Liquid Immersion Exposure

### Examples 1 to 4 and 7 to 25, and Comparative Examples 1 to 6

An organic antireflection film ARC29SR (produced by Nissan Chemical Industries, Ltd.) was applied onto a 12-inch silicon wafer and baked at 205° C. for 60 seconds, thereby forming a 98 nm-thick antireflection film. Each of the above prepared actinic-ray- or radiation-sensitive resin compositions was applied thereonto and baked at 130° C. for 60 seconds, thereby forming a 120 nm-thick resist film. When use was made of a top coat, a 3 mass % solution obtained by dissolving a top coat resin in decane/octanol (mass ratio 9/1) was applied onto the resist film and baked at 85° C. for 60 seconds, thereby forming a 50 nm-thick top coat layer. The resultant wafer was exposed through a 6% half-tone mask of 48 nm line width 1:1 line and space pattern to light by means of an ArF excimer laser liquid immersion scanner (manufactured by ASML, XT-1700i, NA 1.20, C-Quad, outer sigma 0.981, inner sigma 0.895, XY deflection). Ultrapure water was used as the immersion liquid. Thereafter, the exposed wafer was baked at 100° C. for 60 seconds, developed by puddling with an aqueous solution of tetramethylammonium hydroxide (2.38 mass %) for 30 seconds, rinsed by puddling with pure water and spin dried, thereby obtaining a resist pattern.

### Exposure Condition 2: ArF Dry Exposure

### Examples 5 and 6

An organic antireflection film ARC29A (produced by Nissan Chemical Industries, Ltd.) was applied onto a 12-inch silicon wafer and baked at 205° C. for 60 seconds, thereby forming a 78 nm-thick antireflection film. Each of the prepared positive resist compositions was applied thereonto and baked at 130° C. for 60 seconds, thereby forming a 120 nm-thick resist film. The resultant wafer was exposed through a 6% half-tone mask of 75 nm line width 1:1 line and space pattern to light by means of an ArF excimer laser scanner (manufactured by ASML, PAS5500/1100, NA0.75, dipole, σo/σi=0.89/0.65). Thereafter, the exposed wafer was baked at 100° C. for 60 seconds, developed with an aqueous solution of tetramethylammonium hydroxide (2.38 mass %) for 30 seconds, rinsed with pure water and spin dried, thereby obtaining a resist pattern.

(Evaluation of Exposure Latitude)

In exposure condition 1, the optimum exposure amount was defined as the exposure amount in which a line-and-space mask pattern of 48 nm line width was reproduced. The exposure amount range in which when the exposure amount was varied, the pattern size allowed 48 nm±10% was measured. The exposure latitude is the quotient of the value of the exposure amount range divided by the optimum exposure amount, the quotient expressed by a percentage. In exposure condition 2, the optimum exposure amount was defined as the exposure amount in which a line-and-space mask pattern of 75 nm line width was reproduced. The exposure amount range in which when the exposure amount was varied, the pattern size allowed 75 nm±10% was measured. The exposure latitude is the quotient of the value of the exposure amount range divided by the optimum exposure amount, the quotient expressed by a percentage. The greater the value of the exposure latitude, the less the change of performance by exposure amount changes and the better the exposure latitude.

(Evaluation of LWR)

The obtained line pattern of line/space=1/1 (75 nm line width in ArF dry exposure, 48 nm line width in ArF liquid-immersion exposure) was observed by means of a scanning electron microscope (model 59380 manufactured by Hitachi, Ltd.). In an edge 2 μm region along the longitudinal direction of the line pattern, the line width was measured at 50 points. With respect to the dispersion of measurements, the standard deviation was determined, and 3σ was computed therefrom. The smaller the value thereof, the more favorable the performance exhibited.

(Temporal Stability of Resist)

The temporal stability of resist was judged on the basis of a period guaranteeing no change of resist performance. The temporal stability was evaluated by the following (1) temporal stability test for contact angle and (2) temporal stability test for line width.

[Change of Line Width Over Time: Exposure Condition (1)]

The line widths from the resists respectively aged at 40° C., 50° C. and 60° C. for 30 days were compared with that from the resist (reference resist) aged at 0° C. for 30 days, and the stability was evaluated by any line width differences therebetween.

In particular, first, with respect to the resist aged at 0° C. for 30 days, the exposure amount (E₁) that reproduced a mask pattern of 45 nm line width (line/space:1/1) was determined. Subsequently, E₁ exposure was performed on each of three types of resist films aged at raised temperatures for 30 days. The line widths of thus obtained patterns were measured by means of a scanning electron microscope (model S-9260 manufactured by Hitachi, Ltd.), and pattern line width variations from the line width (45 nm) obtained from the reference resist were calculated.

On the basis of thus obtained 3-point data, plotting was performed on a semilogarithmic graph wherein the X-axis indicated the reciprocal of aging temperature (Celsius converted to Kelvin) while the Y-axis indicated the reciprocal of line width variation per day (namely, quotient of the determined line width variation divided by 30), and a collinear approximation was applied. On the thus obtained line, the Y-coordinate value at the X-coordinate corresponding to the aging temperature 25° C. was read. The thus read Y-coordinate value was denoted as the 1 nm-line-width guaranteed days in room temperature condition (25° C.)

[Temporal Stability of Contact Angle: Exposure Condition (1)]

The 1°-contact-angle guaranteed days (reciprocal of dynamic receding contact angle variation per day) in room temperature condition (25° C.) was determined by evaluating and plotting the contact angle variation over time in the same manner as described above with respect to [Temporal stability of line width: exposure condition (1)]. In the measurement of contact angle, the dynamic receding contact angle before exposure with respect to pure water was measured by means of a fully automated contact angle meter (DropMaster 700 manufactured by Kyowa Interface Science Co., Ltd.).

[Temporal Stability of Line Width: Exposure Condition (2)]

The line widths from the resists respectively aged at 40° C., 50° C. and 60° C. for 30 days were compared with that from the resist (reference resist) aged at 0° C. for 30 days, and the stability was evaluated by any line width differences therebetween.

In particular, first, with respect to the resist aged at 0° C. for 30 days, the exposure amount (E₁) that reproduced a mask pattern of 75 nm line width (line/space:1/1) was determined. Subsequently, E₁ exposure was performed on each of three types of resist films aged at raised temperatures for 30 days. The line widths of thus obtained patterns were measured by means of a scanning electron microscope (model S-9260 manufactured by Hitachi, Ltd.), and pattern line width variations from the line width (75 nm) obtained from the reference resist were calculated.

On the basis of thus obtained 3-point data, plotting was performed on a semilogarithmic graph wherein the X-axis indicated the reciprocal of aging temperature (Celsius converted to Kelvin) while the Y-axis indicated the reciprocal of line width variation per day (namely, quotient of the determined line width variation divided by 30), and a collinear approximation was applied. On the thus obtained line, the Y-coordinate value at the X-coordinate corresponding to the aging temperature 25° C. was read. The thus read Y-coordinate value was denoted as the 1 nm-line-width guaranteed days in room temperature condition (25° C.)

TABLE 2

| | | | Basic compound | | Hydrophobic | | | |
|---|---|---|---|---|---|---|---|---|
| | Compound(A) | Resin(B) | or compound(D) | | resin(HR) | Solvent | Surfactant | Exposure |
| | (g) | (10 g) | (g) | | (35 mg) | (mass ratio) | (10 mg) | condition |
| Ex. 1 | A-1 (1.5) | Resin (1) | D-13 | (0.29) | B-10 | A1 | w-1 | 1 |
| Ex. 2 | A-2 (1.6) | Resin (2) | PEA | (0.29) | B-26 | A1/B2 = 80/20 | w-3 | 1 |
| Ex. 3 | A-3 (1.9) | Resin (3) | D-13 | (0.31) | B-29 | A1/A2 = 90/10 | w-1 | 1 |
| Ex. 4 | A-4 (2.2) | Resin (1) | D-52 | (0.30) | TC | A1 | w-2 | 1 |
| Ex. 5 | A-5 (1.6) | Resin (4) | TEA | (0.33) | B-30 | A1/A2 = 70/30 | w-4 | 2 |
| Ex. 6 | A-6 (2.2) | Resin (2) | D-52 | (0.41) | B-39 | A1/A2 = 90/10 | w-1 | 2 |
| Ex. 7 | A-7 (1.7) | Resin (3) | DIA | (0.29) | B-10 | A1/A2 = 80/20 | w-1 | 1 |
| Ex. 8 | A-8 (1.7) | Resin (6) | PBI | (0.30) | B-47 | A1 | w-1 | 1 |
| Ex. 9 | A-9 (2.2) | Resin (1) | DBA | (0.31) | B-26 | A1 | w-1 | 1 |
| Ex. 10 | A-10 (2.1) | Resin (3) | D-52 | (0.42) | B-2 | A1/A2 = 90/10 | w-1 | 1 |
| Ex. 11 | A-11 (1.8) | Resin (5) | D-13 | (0.28) | B-30 | A1 | w-1 | 1 |
| Ex. 12 | A-12 (1.7) | Resin (4) | PBI | (0.33) | B-10 | A1/A3 = 95/5 | w-2 | 1 |
| Ex. 13 | A-13 (2.1) | Resin (1) | DIA | (0.30) | B-47 | A1/A2 = 60/40 | w-1 | 1 |
| Ex. 14 | A-14 (2.2) | Resin (3) | D-52 | (0.31) | B-2 | A1/A2 = 90/10 | w-1 | 1 |
| Ex. 15 | A-15 (2.3) | Resin (2) | D-13 | (0.29) | B-29 | A1/B2 = 90/10 | w-1 | 1 |
| Ex. 16 | A-16 (2.3) | Resin (1) | D-13/DIA | (0.2/0.15) | TC | A1 | w-1 | 1 |
| Ex. 17 | A-33( 1.7)/z104 (0.2) | Resin (2) | DIA | (0.29) | B-26 | A1/A2/A3 = 90/5/5 | w-2 | 1 |
| Ex. 18 | A-34 (2.0) | Resin (3) | PBI | (0.31) | B-47 | A1 | w-1 | 1 |
| Ex. 19 | A-35 (2.0)/z100 (0.2) | Resin (4) | D-52 | (0.30) | B-29 | A1/A2/B1 = 95/4/1 | w-1 | 1 |
| Ex. 20 | A-36 (1.7)/z2 (0.2) | Resin (5) | D-13 | (0.29) | B-30 | A1/A2/A3 = 90/5/5 | w-1 | 1 |
| Ex. 21 | A-37 (1.9)/z73 (0.1) | Resin (6) | D-13/DIA | (0.2/0.15) | B-10 | A1 | w-1 | 1 |
| Ex. 22 | A-58 (1.8) | Resin (2) | D-52 | (0.32) | B-2 | A1 | w-1 | 1 |
| Ex. 23 | A-61 (1.9) | Resin (5) | D-130.28) | | B-39 | A1/B2 = 80/20 | w-2 | 1 |
| Ex. 24 | A-65 (2.0) | Resin (4) | D-52/DBA | (0.15/0.1) | B-26 | A1/A2/B1 = 95/3/2 | w-1 | 1 |
| Ex. 25 | A-69 (1.6)/z104 (0.2) | Resin (6) | D-13/DIA | (0.2/0.15) | B-10 | A1 | w-1 | 1 |
| Comp. Ex. 1 | RA-1 (1.7) | Resin (1) | DIA | (0.28) | B-10 | A1 | w-1 | 1 |
| Comp. Ex. 2 | RA-2 (1.8) | Resin (1) | D-13 | (0.3) | B-29 | A1/A2 = 90/10 | w-1 | 1 |
| Comp. Ex. 3 | RA-3 (1.9) | Resin (1) | D-13 | (0.28) | B-10 | A1 | w-1 | 1 |
| Comp. Ex. 4 | RA-4 (2.1) | Resin (1) | D-13 | (0.33) | B-2 | A1 | w-1 | 1 |
| Comp. Ex. 5 | RA-5 (2.0) | Resin (2) | DIA | (0.40) | B-10 | A1/B2 = 90/10 | w-1 | 1 |
| Comp. Ex. 6 | RA-6 (2.1) | Resin (1) | D-52 | (0.31) | TC | A1 | w-1 | 1 |

Temporal stability of resist

| | | | Temporal | Temporal |
|---|---|---|---|---|
| | Exposure | | stability of | stability of |
| | latitude | LWR | contact angle | line width |
| | (%) | (nm) | (day) | (day) |
| Ex. 1 | 17.2 | 5.5 | 478 | 463 |
| Ex. 2 | 18.1 | 5.3 | 512 | 538 |
| Ex. 3 | 18 | 5.4 | 319 | 323 |
| Ex. 4 | 19 | 4.8 | 347 | 316 |
| Ex. 5 | 17.9 | 5.4 | — | 438 |
| Ex. 6 | 18.1 | 5.5 | — | 431 |
| Ex. 7 | 18.3 | 5.3 | 527 | 538 |
| Ex. 8 | 18.2 | 5.2 | 477 | 469 |
| Ex. 9 | 18.8 | 4.5 | 347 | 336 |
| Ex. 10 | 18.8 | 4.6 | 301 | 349 |
| Ex. 11 | 18.2 | 5.2 | 611 | 636 |
| Ex. 12 | 17.9 | 5.2 | 557 | 587 |
| Ex. 13 | 18.9 | 4.8 | 529 | 522 |
| Ex. 14 | 19 | 4.5 | 475 | 460 |
| Ex. 15 | 18.8 | 4.7 | 637 | 645 |
| Ex. 16 | 19.1 | 4.5 | 552 | 561 |
| Ex. 17 | 19.1 | 4.6 | 581 | 593 |
| Ex. 18 | 18.2 | 5.1 | 540 | 525 |
| Ex. 19 | 18.1 | 5.5 | 401 | 428 |
| Ex. 20 | 17.7 | 5.3 | 543 | 522 |
| Ex. 21 | 17.9 | 5.7 | 419 | 439 |
| Ex. 22 | 19.1 | 4.5 | 605 | 621 |
| Ex. 23 | 19 | 4.6 | 661 | 673 |
| Ex. 24 | 19 | 4.6 | 653 | 659 |
| Ex. 25 | 18.9 | 4.7 | 651 | 664 |
| Comp. Ex. 1 | 15 | 7.8 | 14 | 14 |
| Comp. Ex. 2 | 14.6 | 7.1 | 14 | 14 |
| Comp. Ex. 3 | 15.3 | 7.7 | 7 | 7 |
| Comp. Ex. 4 | 14.9 | 7.6 | 29 | 29 |
| Comp. Ex. 5 | 15 | 7.9 | 29 | 29 |
| Comp. Ex. 6 | 14.8 | 7.8 | 29 | 29 |

The designations appearing in the table correspond to those mentioned above as particular examples or are as follows.

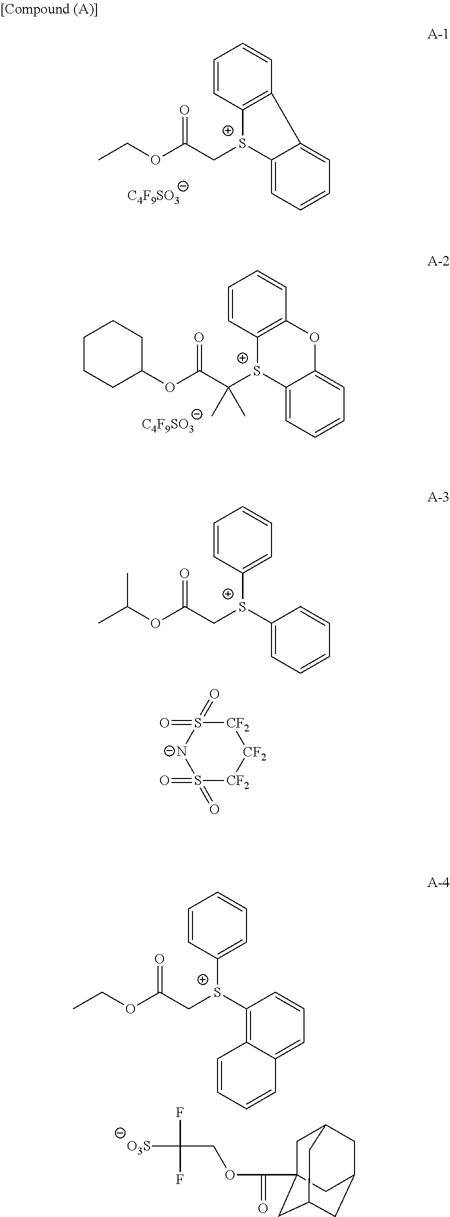

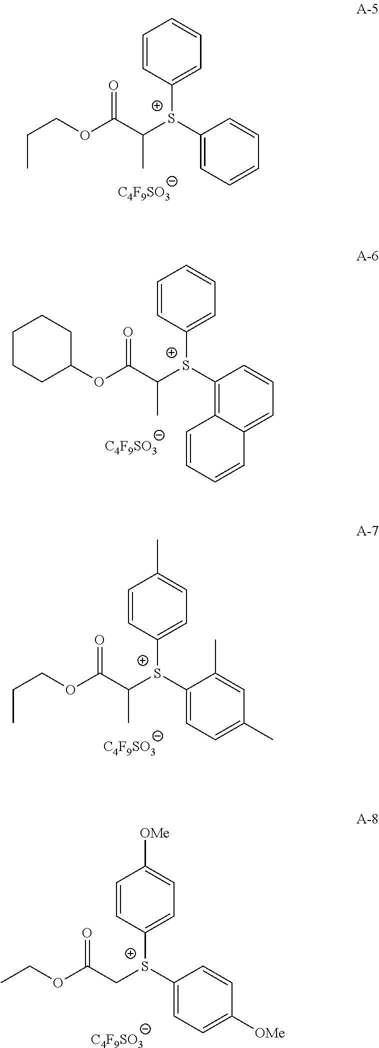

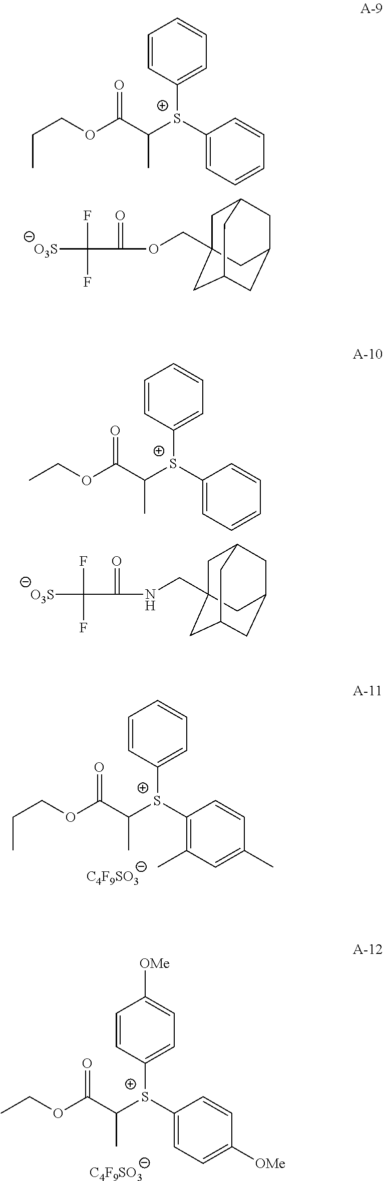

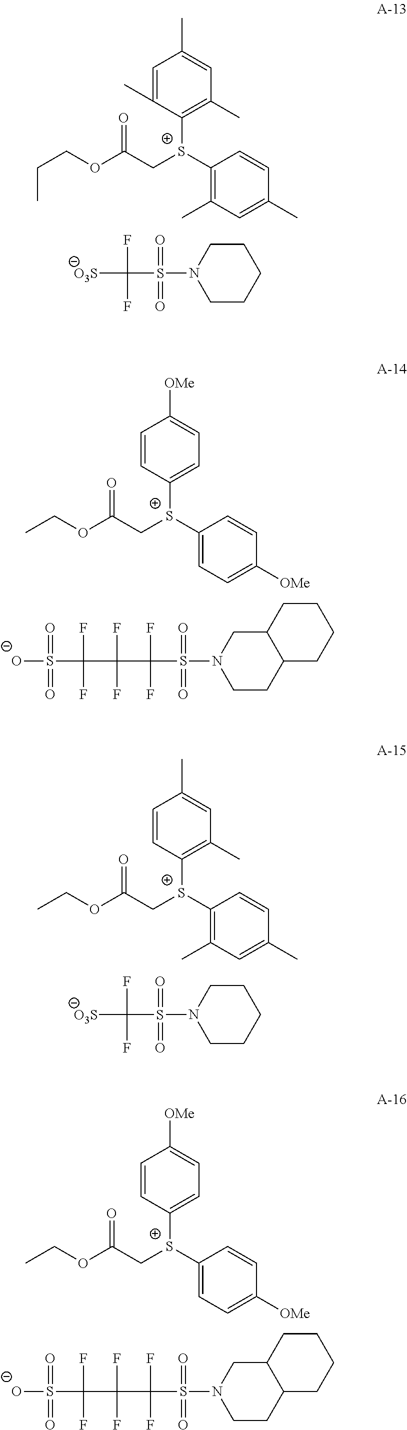

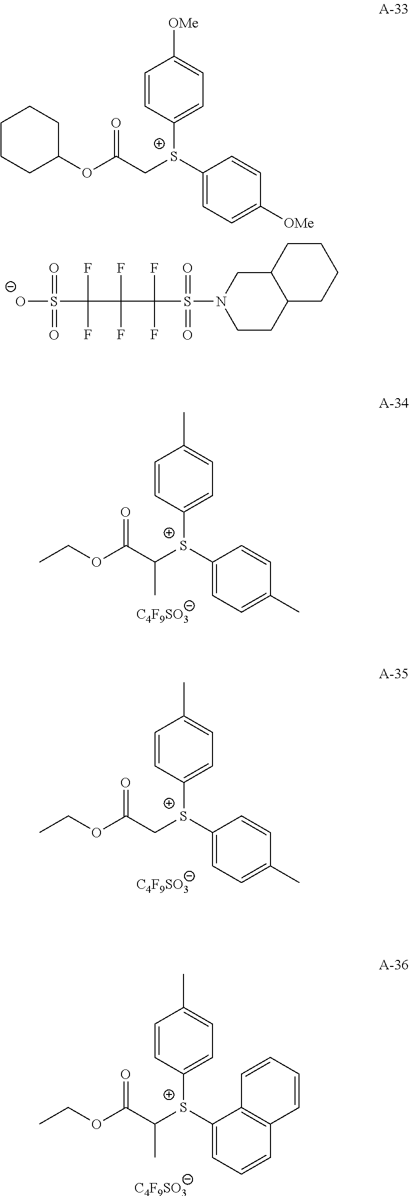

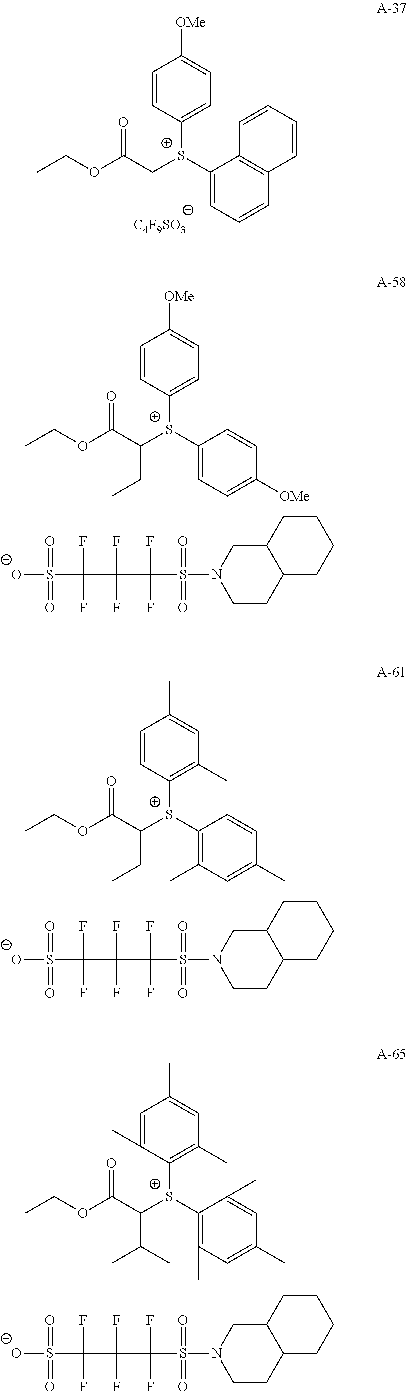

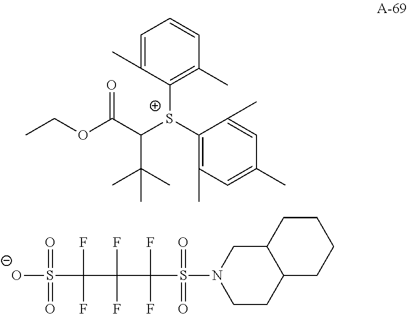 [SMILES: CCOC(=O)C([S+](c1c(C)cccc1C)c1c(C)cc(C)cc1C)C(C)(C)C ; O=S(=O)([O-])C(F)(F)C(F)(F)C(F)(F)S(=O)(=O)N1CCC2CCCCC2C1]

### Other Acid Generator

### Comparative Examples

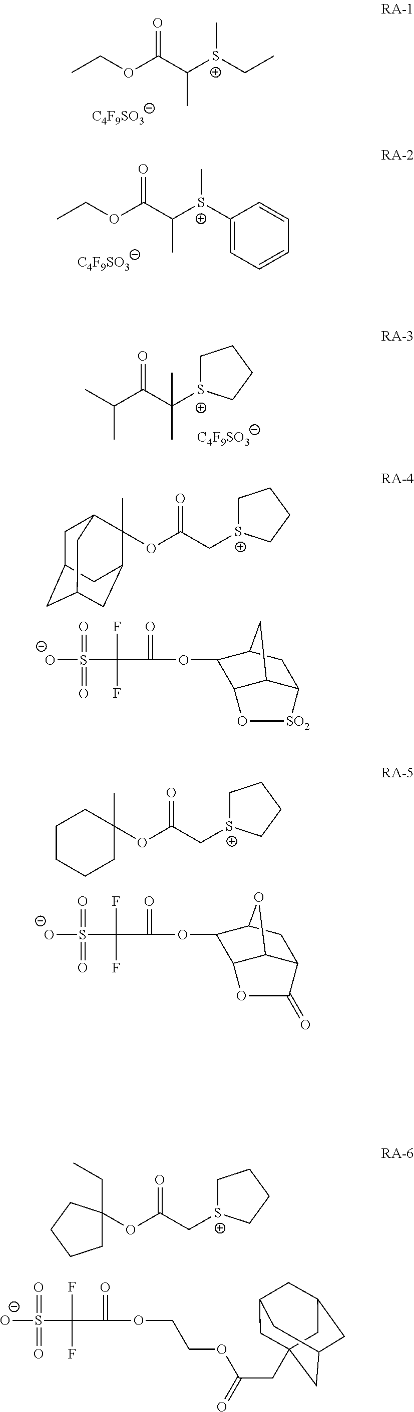

[Resin (B)]

With respect to each of the following resins, the repeating unit ratio is a molar ratio.

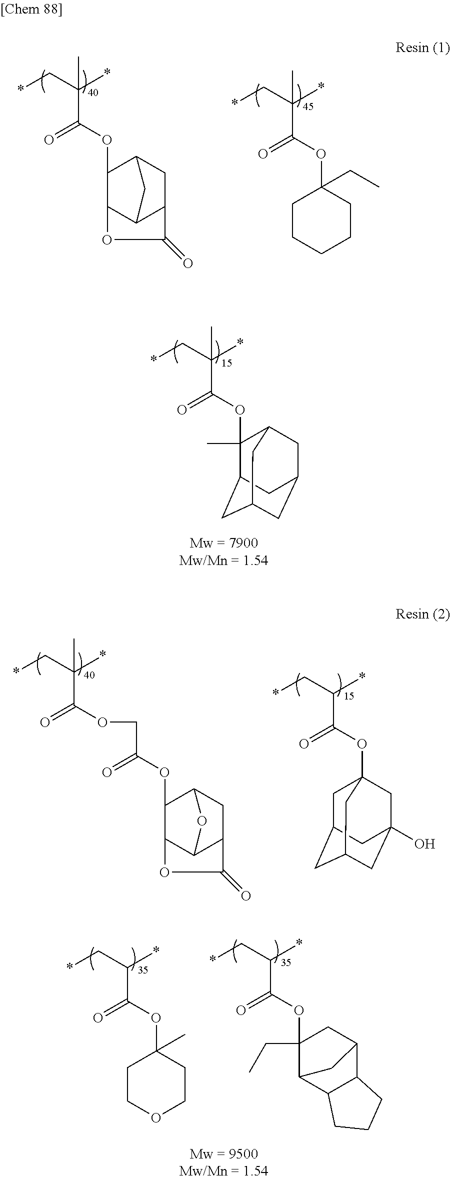

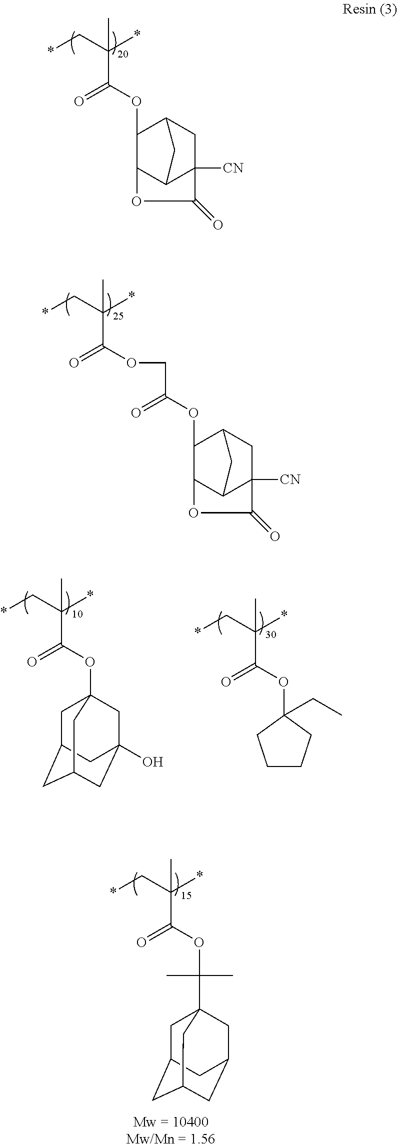

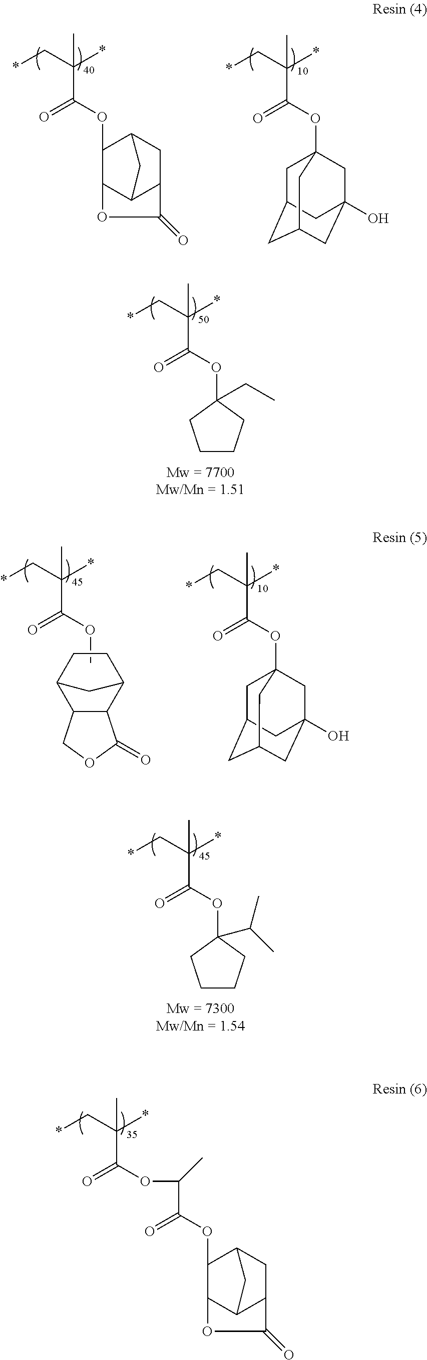

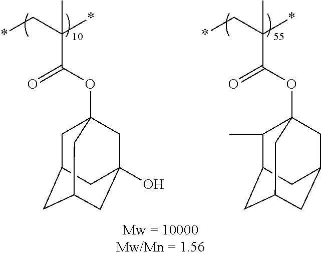

[Basic Compound]
DIA: 2,6-diisopropylaniline,
TEA: triethanolamine,
DBA: N,N-dibutylaniline,
PBI: 2-phenylbenzimidazole, and
PEA: N-phenyldiethanolamine.

[Low-Molecular Compound Containing a Group Cleaved Under the Action of an Acid (D) (Compound (D))]

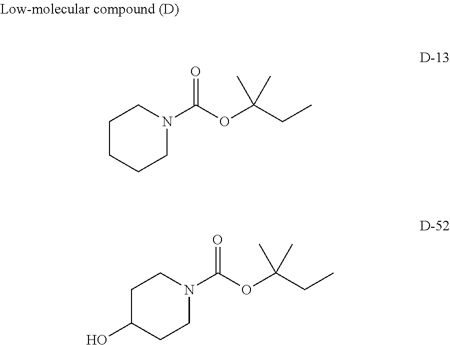

[Surfactant]

W-1: Megafac F176 (produced by DIC Corporation, fluorinated),

W-2: Megafac R08 (produced by DIC Corporation, fluorinated and siliconized),

W-3: PF6320 (produced by OMNOVA SOLUTIONS, INC., fluorinated), and

W-4: Troy Sol S-366 (produced by Troy Chemical Co., Ltd., fluorinated).

[Solvent]

A1: propylene glycol monomethyl ether acetate (PGMEA),

A2: cyclohexanone,

A3: γ-butyrolactone,

B1: propylene glycol monomethyl ether (PGME), and

B2: ethyl lactate.

As apparent from the results of Table 2, in Comparative Examples 1 to 6 in which use was made of acid generators not satisfying general formula (1), the exposure latitude was small and the LWR was large, thereby being inferior in both the exposure latitude and LWR, and the amount of acid leached was large.

By contrast, in Examples 1 to 25 in which compounds (A) satisfying general formula (1) were used as acid generators, it is apparent that the exposure latitude was large and the LWR was small, thereby excelling in both the exposure latitude and LWR, and the temporal stability of resist was excellent.

Accordingly, the composition of the present invention can find appropriate application in the lithography process employed in the manufacturing of various electronic devices, such as a semiconductor element and a recording medium.

What is claimed is:

1. An actinic-ray- or radiation-sensitive resin composition comprising any of compounds of general formula (1) below that when exposed to actinic rays or radiation, is decomposed to thereby generate an acid and a resin that when acted on by an acid, is decomposed to thereby increase its solubility in an alkali developer, 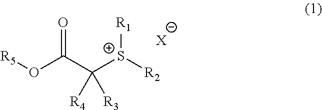
in which
each of R₁ and R₂ independently represents an aryl group, provided that R₁ and R₂ may be connected to each other;
each of R₃ and R₄ independently represents a hydrogen atom, an alkyl group, a cycloalkyl group, an alkenyl group or an aryl group, provided that R₃ and R₄ may be connected to each other;
R₅ represents an alkyl group, a cycloalkyl group, an alkenyl group, an aryl group, an aralkyl group or an alkylcarbonyl group, provided that R₅ may be connected to R₃ or R₄; and
X⁻ represents a nonnucleophilic anion.

2. The actinic-ray- or radiation-sensitive resin composition according to claim 1, wherein X⁻ in general formula (1) is expressed by general formula (2) below, 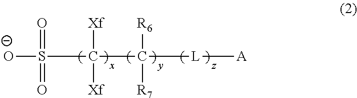
in which
each of Xf's independently represents a fluorine atom or an alkyl group substituted with at least one fluorine atom;
each of R₆ and R₇ independently represents a hydrogen atom, a fluorine atom, an alkyl group or an alkyl group substituted with at least one fluorine atom, provided that two or more R₆s, and R₇s may be identical to or different from each other;
L represents a bivalent connecting group, provided that two or more L's may be identical to or different from each other;
A represents an organic group containing a cyclic structure; and
x is an integer of 1 to 20, y an integer of 0 to 10, and z an integer of 0 to 10.

3. The actinic-ray- or radiation-sensitive resin composition according to claim 1, wherein at least either R₃ or R₄ in general formula (1) is an alkyl group or an aryl group.

4. The actinic-ray- or radiation-sensitive resin composition according to claim 1, wherein in general formula (1), an alkyl group, a cycloalkyl group, an alkoxy group, a hydroxyl group, a fluorine atom, a cyano group, an amino group, an alkylamino group, a dialkylamino group or an alkoxycarbonylamino group is introduced in at least one of the aryl groups represented by R₁ and R₂.

5. The actinic-ray- or radiation-sensitive resin composition according to claim 1, further comprising a low-molecular compound containing a nitrogen atom and a group cleaved by the action of an acid, or a basic compound.

6. An actinic-ray- or radiation-sensitive film formed from the actinic-ray- or radiation-sensitive resin composition according to claim 1.

7. A method of forming a pattern, comprising:
exposing the actinic-ray- or radiation-sensitive film of claim 6 to light, and
developing the exposed film.

8. The method according to claim 7, wherein the exposure is performed through an immersion liquid.

9. A process for manufacturing an electronic device, comprising the method of claim 7.
